(19) United States
(12) Patent Application Publication
(10) Pub. No.: US 2026/0089973 A1
(43) Pub. Date: Mar. 26, 2026

(54) SEMICONDUCTOR DEVICES

(71) Applicant: SAMSUNG ELECTRONICS CO., LTD., Suwon-si (KR)

(72) Inventors: KYUNGHWAN LEE, Suwon-si (KR); Daewon HA, Suwon-si (KR)

(73) Assignee: SAMSUNG ELECTRONICS CO., LTD., Suwon-si (KR)

(21) Appl. No.: 19/096,011

(22) Filed: Mar. 31, 2025

(30) Foreign Application Priority Data
Sep. 23, 2024 (KR) 10-2024-0128458

(51) Int. Cl. H10B 53/30; H10B 53/20

(52) U.S. Cl. CPC H10B 53/30; H10B 53/20

(57) ABSTRACT

A semiconductor device may include a selection element layer on a substrate, a stack including interlayer insulating layers and horizontal electrodes, which are alternately stacked on the selection element layer in a vertical direction, a top electrode penetrating the stack, and a dielectric layer interposed between the stack and the top electrode. Each of the horizontal electrodes may include first and second bottom electrodes, and the first bottom electrode may include first and second protruding portions spaced apart from each other in the vertical direction and a supporting portion connecting the first and second protruding portions to each other. The top electrode may include a horizontal protruding portion, an interlayer protruding portion, and a vertical portion connecting the horizontal protruding portion to the interlayer protruding portion.

### CROSS-REFERENCE TO RELATED APPLICATION

This U.S. non-provisional patent application claims priority under 35 U.S.C. § 119 to Korean Patent Application No. 10-2024-0128458, filed on Sep. 23, 2024, in the Korean Intellectual Property Office, the disclosure of which is hereby incorporated by reference in its entirety.

### BACKGROUND

### 1. Field

The disclosure relates to a semiconductor device and a method of fabricating the same, and in particular, to a semiconductor memory device including a ferroelectric field effect transistor and a method of fabricating the same.

### 2. Brief Description of Background Art

Semiconductor memory devices are generally categorized into volatile memory devices and nonvolatile memory devices. The volatile memory devices lose their stored data when their power supplies are interrupted, and for example, include a dynamic random access memory (DRAM) device and a static random access memory (SRAM) device. The nonvolatile memory devices maintain their stored data even when their power supplies are interrupted and, for example, include a programmable read only memory (PROM), an erasable PROM (EPROM), an electrically-erasable PROM (EEPROM), a FLASH memory device. In addition, to meet an increasing demand for a semiconductor memory device with high performance and low power consumption, next-generation nonvolatile semiconductor memory devices, such as magnetic random access memory (MRAM), phase-change random access memory (PRAM), and ferroelectric random access memory (FeRAM) devices, are being developed, and various studies are being conducted to develop next-generation semiconductor memory devices with high density and high performance.

### SUMMARY

According to an aspect of the disclosure, a highly-integrated semiconductor device and a method of fabricating the same are provided.

According to an aspect of the disclosure, a semiconductor device may include: a substrate; a selection element layer on the substrate in a vertical direction perpendicular to a top surface of the substrate; a stack including interlayer insulating layers and horizontal electrodes, wherein the interlayer insulating layers and the horizontal electrodes are alternately stacked on the selection element layer in the vertical direction; a top electrode penetrating the stack; and a dielectric layer between the stack and the top electrode, wherein each of the horizontal electrodes includes a first bottom electrode and a second bottom electrode, wherein the first bottom electrode includes: a first protruding portion; a second protruding portion; and a supporting portion that connects the first protruding portion and the second protruding portion, wherein the first protruding portion and the second protruding portion extend toward a center of the top electrode, and the first protruding portion and the second protruding are spaced apart from each other in the vertical direction, wherein the top electrode includes: a horizontal protruding portion extending between the first protruding portion and the second protruding portion of the first bottom electrode of one of the horizontal electrodes; an interlayer protruding portion extending between the first bottom electrode of the one of the horizontal electrodes and the first bottom electrode of another one of the horizontal electrodes, wherein the first bottom electrode of the one of the horizontal electrodes and the first bottom electrode of the another one of the horizontal electrodes are adjacent to each other in the vertical direction; and a vertical portion connecting the horizontal protruding portion to the interlayer protruding portion.

According to an aspect of the disclosure, a semiconductor device may include: a substrate; a selection element layer on the substrate in a vertical direction perpendicular to a top surface of the substrate; a stack including interlayer insulating layers and horizontal electrodes, wherein the interlayer insulating layers and the horizontal electrodes are alternately stacked on the selection element layer in the vertical direction; an insulating separation pattern penetrating the stack in the vertical direction; a top electrode penetrating the insulating separation pattern in the vertical direction; and a dielectric layer between the stack and the insulating separation pattern and between the stack and the top electrode, wherein each of the horizontal electrodes includes a first horizontal electrode and a second horizontal electrode, wherein the first horizontal electrode and the second horizontal electrode are spaced apart from each other in a first direction parallel to the top surface of the substrate, with the insulating separation pattern and the top electrode being between the first horizontal electrode and the second horizontal electrode in the first direction, wherein the insulating separation pattern crosses the stack in a second direction parallel to the top surface of the substrate, the second direction crossing the first direction; wherein each of the first horizontal electrode and the second horizontal electrode includes: a first bottom electrode including: a first protruding portion; a second protruding portion, wherein the first protruding portion and the second protruding portion extend in the first direction and are spaced apart from each other in the vertical direction, and a supporting portion that connects the first protruding portion and the second protruding portion; and a second bottom electrode spaced apart from the top electrode, wherein the first bottom electrode is between the second bottom electrode and the top electrode, and wherein the top electrode includes: a horizontal protruding portion extending between the first protruding portion and the second protruding portion of the first bottom electrode of the first horizontal electrode of one of the horizontal electrodes; an interlayer protruding portion extending between the first bottom electrode of the first horizontal electrode of the one of the horizontal electrodes and the first bottom electrode of the first horizontal electrode of another one of the horizontal electrodes, wherein the first bottom electrode of the first horizontal electrode of the one of the horizontal electrodes and the first bottom electrode of the first horizontal electrode of the another one of the horizontal electrodes are adjacent to each other in the vertical direction; and a vertical portion connecting the horizontal protruding portion to the interlayer protruding portion.

According to an aspect of the disclosure, a semiconductor device may include: a substrate; a selection element layer on the substrate in a vertical direction perpendicular to a top surface of the substrate; a stack including interlayer insulating layers and horizontal electrodes, wherein the interlayer insulating layers and the horizontal electrodes are alternately stacked on the selection element layer in the vertical direction; a top electrode penetrating the stack; and a dielectric layer between the stack and the top electrode, wherein the selection element layer includes: a bit line extending in a first direction parallel to the top surface of the substrate; a semiconductor pattern on the bit line; a word line on a side surface of the semiconductor pattern, the word line extending in a second direction that is parallel to the top surface of the substrate and that crosses the first direction; and a gate insulating pattern between the word line and the semiconductor pattern, wherein each of the horizontal electrodes includes a first bottom electrode and a second bottom electrode, wherein the first bottom electrode includes: a first protruding portion; a second protruding portion; and a supporting portion that connects the first protruding portion and the second protruding portion to each other, wherein the first protruding portion and the second protruding portion extend toward a center of the top electrode, and the first protruding portion and the second protruding portion are spaced apart from each other in the vertical direction, wherein the top electrode includes: a horizontal protruding portion that extends between the first protruding portion and the second protruding portion of the first bottom electrode of one of the horizontal electrodes; an interlayer protruding portion extending between the first bottom electrode of the one of the horizontal electrodes and the first bottom electrode of another one of the horizontal electrodes, wherein the first bottom electrode of the one of the horizontal electrodes and the first bottom electrode of the another one of the horizontal electrodes are adjacent to each other in the vertical direction; and a vertical portion connecting the horizontal protruding portion to the interlayer protruding portion.

According to an aspect of the disclosure, a semiconductor device with improved operational and reliability characteristics and a method of fabricating the same are provided.

### BRIEF DESCRIPTION OF DRAWINGS

FIG. 1 is a plan view illustrating a semiconductor device according to an embodiment of the disclosure.

FIGS. 2A to 2C are sectional views, which are respectively taken along lines A-A′, B-B′, and C-C′ of FIG. 1 to illustrate a semiconductor device according to an embodiment of the disclosure.

FIGS. 2D to 2H are enlarged sectional views illustrating a portion A of FIG. 2A according to some embodiments of the disclosure.

FIGS. 3 to 22C are diagrams illustrating a method of fabricating a semiconductor device, according to an embodiment of the disclosure.

FIG. 23 is a plan view illustrating a semiconductor device according to an embodiment of the disclosure.

FIGS. 24A to 24C are sectional views, which are respectively taken along lines A-A′, B-B′, and C-C′ of FIG. 23 to illustrate a semiconductor device according to an embodiment of the disclosure.

FIGS. 25 to 28C are diagrams illustrating a method of fabricating a semiconductor device, according to an embodiment of the disclosure.

FIG. 29 is a plan view illustrating a semiconductor device according to an embodiment of the disclosure.

FIGS. 30A to 30C are sectional views, which are respectively taken along lines A-A′, B-B′, and C-C′ of FIG. 29 to illustrate a semiconductor device according to an embodiment of the disclosure.

FIGS. 31 to 37C are diagrams illustrating a method of fabricating a semiconductor device, according to an embodiment of the disclosure.

### DETAILED DESCRIPTION

Non-limiting example embodiments of the disclosure will now be described more fully with reference to the accompanying drawings, in which example embodiments are shown.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

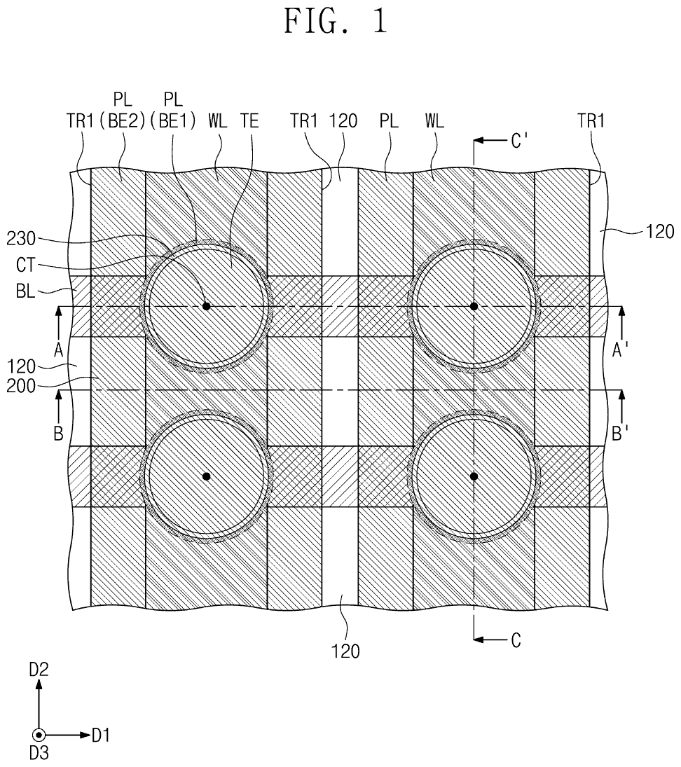

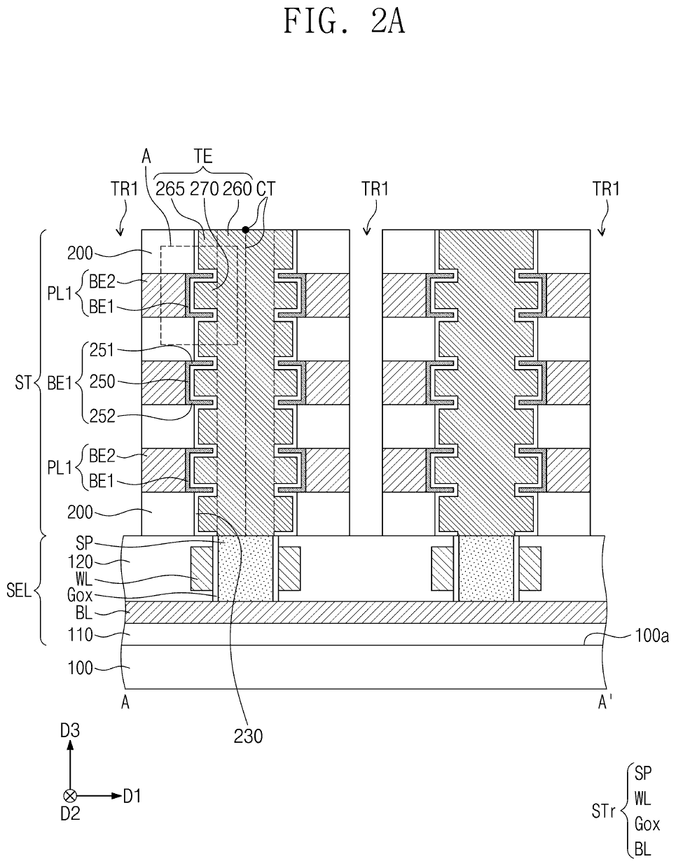

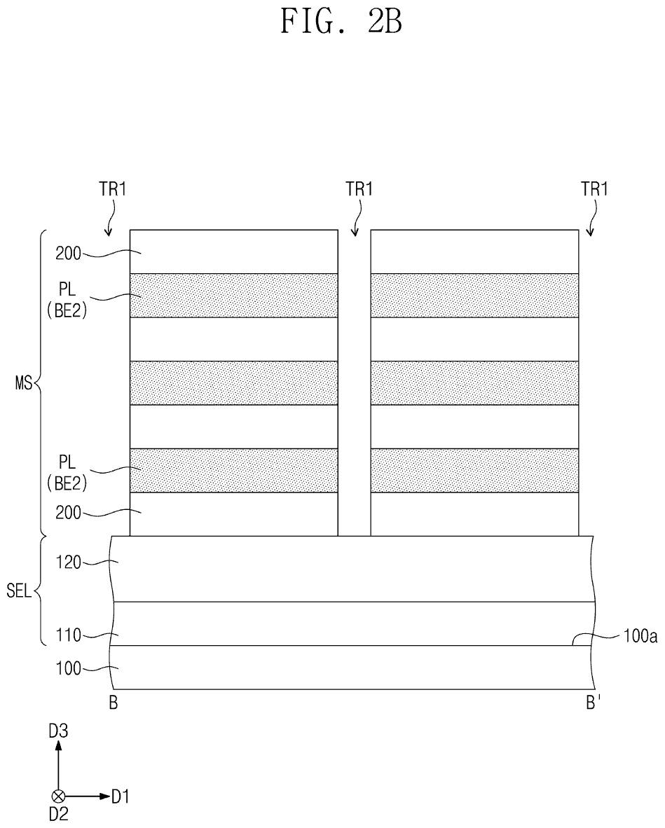

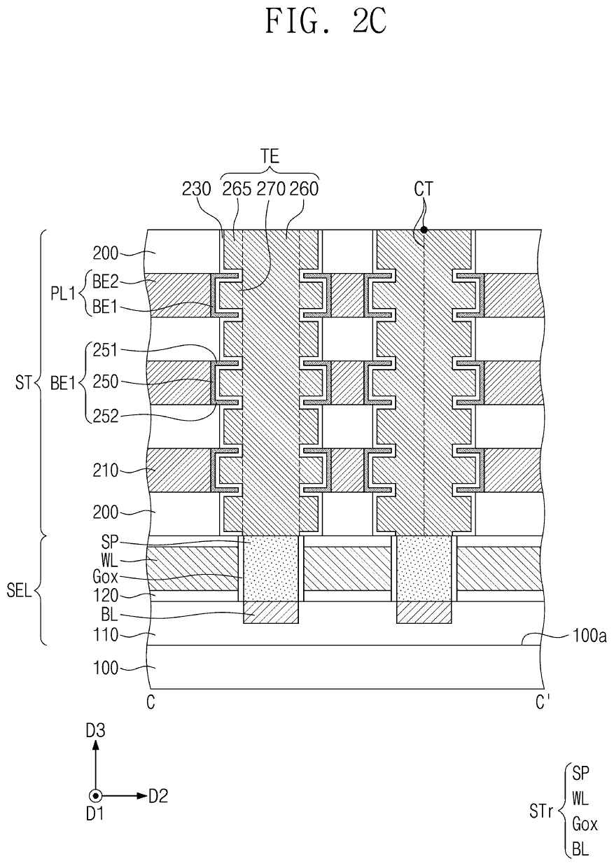

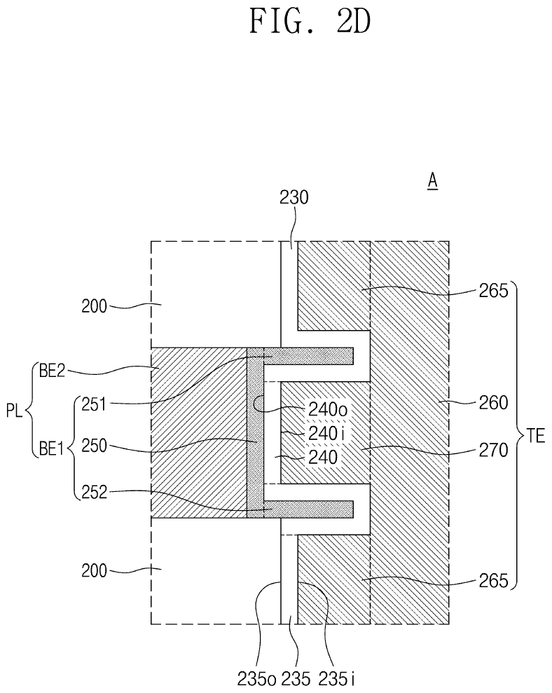

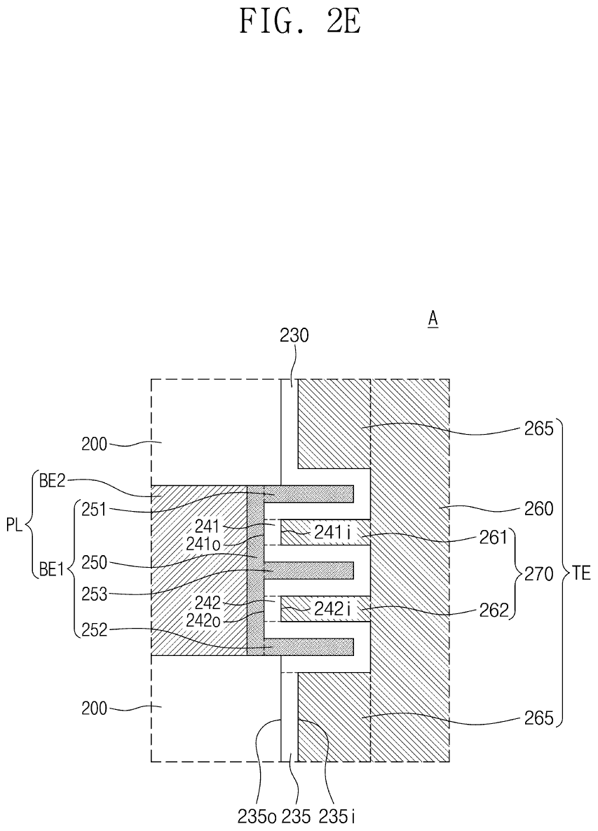

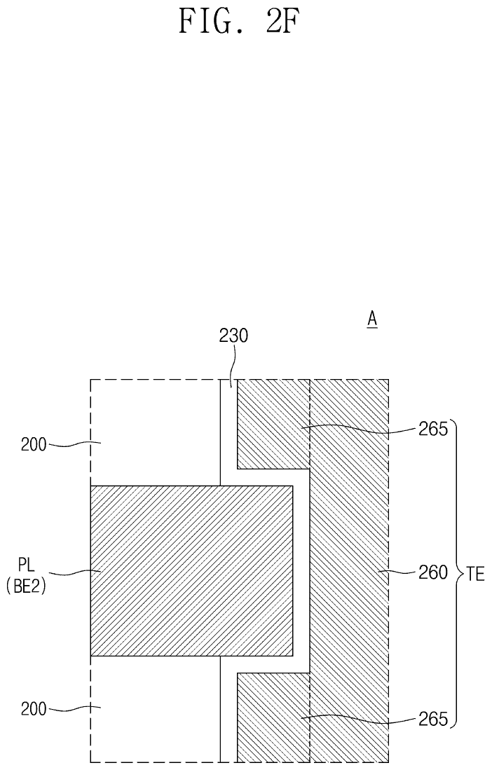

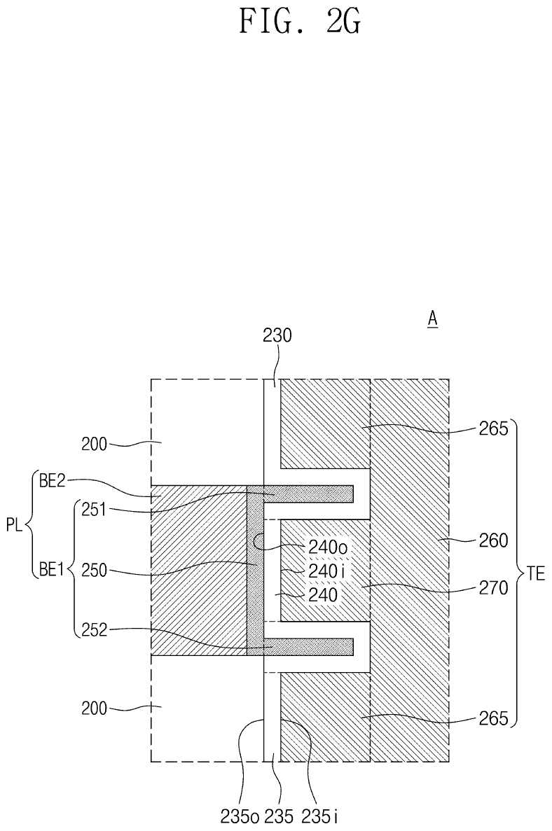

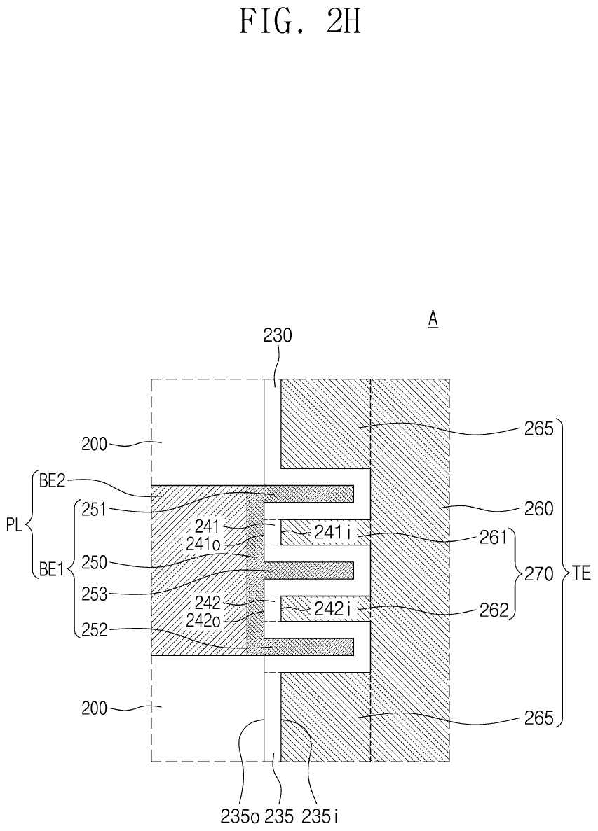

FIG. 1 is a plan view illustrating a semiconductor device according to an embodiment of the disclosure. FIGS. 2A to 2C are sectional views, which are respectively taken along lines A-A′, B-B′, and C-C′ of FIG. 1 to illustrate a semiconductor device according to an embodiment of the disclosure. FIGS. 2D to 2H are enlarged sectional views illustrating a portion ‘A’ of FIG. 2A according to some embodiments of the disclosure.

Referring to FIGS. 1 and 2A to 2C, a selection element layer SEL may be disposed on a substrate 100. The substrate 100 may be a semiconductor substrate (e.g., a silicon substrate, a germanium substrate, or a silicon-germanium substrate).

The selection element layer SEL may include a lower insulating layer 110, selection transistors STr, and a selection insulating layer 120. The lower insulating layer 110 may be disposed on the substrate 100, and the selection transistors STr and the selection insulating layer 120 may be disposed on the lower insulating layer 110. The selection transistor STr may include a bit line BL, a semiconductor pattern SP, a word line WL, and a gate insulating pattern Gox. In an embodiment, a plurality of selection transistors STr may be provided.

The bit line BL may be disposed in an upper portion of the lower insulating layer 110. A top surface of the bit line BL may be exposed from the lower insulating layer 110. In an embodiment, a top surface of the lower insulating layer 110 may be coplanar with the top surface of the bit line BL. In an embodiment, a plurality of bit lines BL may be provided. The bit lines BL may extend in a first direction D1 and may be spaced apart from each other in a second direction D2. In the present specification, the first direction D1 and the second direction D2 may be parallel to a top surface 100a of the substrate 100 and may not be parallel to each other. A third direction D3 may be perpendicular to the top surface 100a of the substrate 100. The third direction D3 may be referred to as a vertical direction. In an embodiment, the first direction D1, the second direction D2, and the third direction D3 may be orthogonal to each other.

The bit lines BL may include a conductive material. In an embodiment, the bit lines BL may include at least one from among doped polysilicon, metallic materials, conductive metal nitride materials, conductive metal silicide materials, conductive metal oxide materials, and combinations thereof. For example, the bit lines BL may be formed of or include at least one from among doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, and combinations thereof, but embodiments of the disclosure are not limited to these examples.

The semiconductor patterns SP may be disposed on the bit lines BL, respectively. The semiconductor patterns SP may be spaced apart from each other in the first direction D1 and the second direction D2. A bottom surface of each of the semiconductor patterns SP may be in direct contact with a top surface of a corresponding one of the bit lines BL. The semiconductor patterns SP may have a shape extending in the third direction D3.

Upper and lower portions of each of the semiconductor patterns SP may include source/drain regions. Each of the semiconductor patterns SP may further include a channel region, which is provided between the source/drain regions at its upper and lower levels. In each of the semiconductor patterns SP, a lower one of the source/drain regions may be electrically connected to a corresponding one of the bit lines BL.

The semiconductor patterns SP may be formed of or include at least one from among silicon (e.g., polycrystalline silicon, single-crystalline silicon, or doped silicon), germanium, silicon-germanium, and oxide semiconductor materials. The oxide semiconductor materials may include InGaZnO (IGZO), Sn—InGaZnO, InWO (IWO), CuS₂, CuSe₂, WSe₂, InGaSiO, InSnZnO, InZnO (IZO), ZnO, ZnTiO (ZTO), YZnO (YZO), ZnSnO, ZnON, ZrZnSnO, SnO, HfInZnO, GaZnSnO, AlZnSnO, YbGaZnO, InGaO, or combinations thereof. The semiconductor patterns SP may include a two-dimensional semiconductor material, and here, the two-dimensional semiconductor material may include MoS₂, MoSe₂, WS₂, graphene, carbon nanotube, or combinations thereof.

The word line WL may be disposed to surround (e.g., enclose) side surfaces of the semiconductor patterns SP, which are adjacent to each other in the second direction D2, and may extend in the second direction D2. For example, the semiconductor pattern SP may be provided to penetrate a corresponding one of the word lines WL. In an embodiment, a top surface of the word line WL may be located at a level lower than a top surface of the semiconductor pattern SP. A bottom surface of the word line WL may be located at a level higher than the bottom surface of the semiconductor pattern SP. In an embodiment, a plurality of word lines WL may be provided. The word lines WL may be spaced apart from each other in the first direction D1.

The word lines WL may include a conductive material. In an embodiment, the word lines WL may include doped polysilicon, metallic materials, conductive metal nitride materials, conductive metal silicide materials, conductive metal oxide materials, or combinations thereof. For example, the word lines WL may be formed of or include at least one from among doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, and combinations thereof, but embodiments of the disclosure are not limited to these examples.

The gate insulating pattern Gox may be interposed between a corresponding pair of the semiconductor patterns SP and the word line WL. The gate insulating pattern Gox may extend in the third direction D3 and the opposite direction thereof to surround (e.g., enclose) a side surface of a corresponding one of the semiconductor patterns SP. In an embodiment, a top surface of the gate insulating pattern Gox may be coplanar with the top surface of the semiconductor pattern SP. A bottom surface of the gate insulating pattern Gox may be coplanar with the bottom surface of the semiconductor pattern SP. The gate insulating pattern Gox may cover the side surface of the semiconductor pattern SP with a uniform thickness. The word line WL may be spaced apart from a corresponding one of the semiconductor patterns SP with the gate insulating pattern Gox interposed therebetween.

The gate insulating patterns Gox may be formed of or include at least one from among silicon oxide, silicon oxynitride, and a high-k dielectric material having a higher dielectric constant than a dielectric constant of silicon oxide. The high-k dielectric material may include metal oxide materials or metal oxynitride materials. For example, the high-k dielectric material, which may be used for the gate insulating pattern Gox, may include at least one from among HfO₂, HfSiO, HfSiON, HfTaO, HfTiO, HfZrO, ZrO₂, and Al₂O₃, but embodiments of the disclosure are not limited to these examples.

The selection insulating layer 120 may be disposed on the lower insulating layer 110. The selection insulating layer 120 may cover the selection transistors STr. In an embodiment, a top surface of the selection insulating layer 120 may be coplanar with the top surface of the gate insulating pattern Gox and the top surface of the semiconductor pattern SP. The top surface of the semiconductor pattern SP may be exposed from the selection insulating layer 120.

The lower insulating layer 110 and the selection insulating layer 120 may be formed of or include at least one from among silicon oxide, silicon nitride, and silicon oxynitride, and may be provided to have a single-or multi-layered structure.

The selection transistors STr in the selection element layer SEL may include a vertical channel transistor (VCT) having a vertical channel structure. The vertical channel transistor may have a channel structure that is extended in a direction (e.g., the third direction D3) perpendicular to the top surface 100a of the substrate 100. However, embodiments of the disclosure are not limited to this example, and the vertical channel transistor may include a device having a typical selection function.

A stack ST may be disposed on the selection element layer SEL. In an embodiment, a plurality of stacks ST may be provided. In this case, first trenches TR1 may be provided between the stacks ST in the first direction D1, and may extend in the second direction D2. The first trenches TR1 may be spaced apart from each other in the first direction D1. The stacks ST may be spaced apart from each other in the first direction D1 with the first trench TR1 interposed therebetween. Hereinafter, just one stack ST will be described, for brevity's sake, but the others of the stacks ST may also have substantially the same features as described below.

The stack ST may include interlayer insulating layers 200 and horizontal electrodes PL, which are alternately stacked in the third direction D3. The horizontal electrodes PL may be spaced apart from each other in the third direction D3 with the interlayer insulating layers 200 interposed therebetween. The interlayer insulating layers 200 may be formed of or include at least one from among silicon oxide, silicon nitride, and silicon oxynitride.

A top electrode TE may be formed to penetrate the stack ST. In an embodiment, a plurality of top electrodes TE may be provided. The top electrodes TE may be spaced apart from each other in the second direction D2. The top electrodes TE may be disposed on the semiconductor patterns SP, respectively. Each of the top electrodes TE may be in direct contact with a corresponding one of the semiconductor patterns SP. In an embodiment, a bottom surface of the top electrode TE may be in direct contact with and be electrically connected to a top surface of a corresponding one of the semiconductor patterns SP.

A dielectric layer 230 may be interposed between the stack ST and the top electrode TE. The dielectric layer 230 may be provided to surround (e.g., enclose) a side surface of the top electrode TE with a uniform thickness. The interlayer insulating layers 200 and the horizontal electrodes PL of the stack ST may be spaced apart from the top electrode TE with the dielectric layer 230 interposed therebetween.

The dielectric layer 230 may be formed of or include at least one from among ferroelectric and anti-ferroelectric materials. The dielectric layer 230 may include hafnium oxide exhibiting a ferroelectric property. The dielectric layer 230 may further include dopants, and in an embodiment, the dopants may include at least one from among Zr, Si, Al, Y, Gd, La, Sc, and Sr. In an embodiment, the dielectric layer 230 may include HfO₂, HfZnO, HfSiO, HfSiON, HfTaO, HfTiO, HfZrO, or combinations thereof. The dielectric layer 230 may be provided to have a laminated structure, in which ferroelectric layers of two or more types are stacked, or a laminated structure, in which a ferroelectric layer and an insulating layer are stacked. The insulating layer may be formed of or include at least one from among silicon oxide, silicon oxynitride, and high-k dielectric materials whose dielectric constants are higher than a dielectric constant of silicon oxide. In an embodiment, the dielectric layer 230 may have a structure including a ferroelectric layer and a semiconductor layer. The semiconductor layer may include at least one of oxide semiconductor materials (e.g., InGaZnO (IGZO), Sn—InGaZnO, InWO (IWO), CuS₂, CuSe₂, WSe₂, InGaSiO, InSnZnO, InZnO (IZO), ZnO, ZnTiO (ZTO), YZnO (YZO), ZnSnO, ZnON, ZrZnSnO, SnO, HfInZnO, GaZnSnO, AlZnSnO, YbGaZnO, InGaO, or combinations thereof).

Hereinafter, various embodiments of the disclosure will be described with reference to FIGS. 2D to 2H. For concise description, a previously described element may be identified by the same reference number without repeating an overlapping description thereof.

Referring to FIGS. 1, 2A to 2D, and 2G, each of the horizontal electrodes PL may include a first bottom electrode BE1 and a second bottom electrode BE2. The first bottom electrode BE1 may include a first protruding portion 251 and a second protruding portion 252, which are provided to protrude toward a center CT of the top electrode TE, and a supporting portion 250, which is provided to connect the first protruding portion 251 and the second protruding portion 252 to each other. The first protruding portion 251 and the second protruding portion 252 may be spaced apart from each other in the third direction D3, and the supporting portion 250 may extend in the third direction D3 to connect the first protruding portion 251 and the second protruding portion 252 to each other. The first bottom electrode BE1 may be disposed between the second bottom electrode BE2 and the top electrode TE. The second bottom electrode BE2 may be connected to the supporting portion 250 of the first bottom electrode BE1. When viewed in a plan view, the first protruding portion 251 and the second protruding portion 252 may have a ring shape, which has a center axis passing through the center CT of the top electrode TE. The first protruding portion 251 and the second protruding portion 252 may be vertically overlapped with each other. When viewed in a plan view, the supporting portion 250 may also have a ring shape, which has a center axis passing through the center CT of the top electrode TE.

The top electrode TE may include horizontal protruding portions 270, which extend into regions between the first protruding portion 251 and the second protruding portion 252 of each of the first bottom electrodes BE1. The top electrode TE may include interlayer protruding portions 265, which extend into regions between the horizontal electrodes PL that are adjacent to each other in the third direction D3. In detail, the top electrode TE may include the interlayer protruding portions 265, which extend into regions between the first bottom electrodes BE1 that are adjacent to each other in the third direction D3. In addition, the top electrode TE may include a vertical portion 260 connecting the horizontal protruding portions 270 to the interlayer protruding portions 265. When viewed in a plan view, the vertical portion 260 may have a circular pillar shape, which has a center axis passing through the center CT of the top electrode TE and is extended in the third direction D3. A bottom surface of the vertical portion 260 may be in contact with a top surface of a corresponding one of the semiconductor patterns SP. When viewed in a plan view, the horizontal protruding portions 270 and the interlayer protruding portions 265 may have a ring shape, which has a center axis passing through the center CT of the top electrode TE. The horizontal protruding portions 270 may be spaced apart from the interlayer protruding portions 265, which are adjacent thereto in the third direction D3, in the third direction D3 with the first protruding portion 251 and the second protruding portion 252 of each of the first bottom electrode BE1 interposed therebetween.

The dielectric layer 230 may be interposed between the stack ST and the top electrode TE. The dielectric layer 230 may conformally cover the side surface of the top electrode TE. The first protruding portion 251 and the second protruding portion 252 of each of the first bottom electrodes BE1 may be spaced apart from the top electrode TE with the dielectric layer 230 interposed therebetween.

When viewed in a plan view, at least a portion of the first protruding portion 251 and the second protruding portion 252 of each of the first bottom electrodes BE1 may be vertically overlapped with the interlayer protruding portions 265 of the top electrode TE. At least a portion of the first protruding portion 251 and the second protruding portion 252 of each of the first bottom electrodes BE1 may be vertically overlapped with the horizontal protruding portions 270 of the top electrode TE. In detail, a top surface of the first protruding portion 251 may be vertically overlapped with the interlayer protruding portion 265, which is provided thereon, and the dielectric layer 230, which is provided to surround (e.g., enclose) the interlayer protruding portion 265. A bottom surface of the second protruding portion 252 may be vertically overlapped with the interlayer protruding portion 265, which is provided therebelow, and the dielectric layer 230, which is provided to surround (e.g., enclose) the interlayer protruding portion 265.

In an embodiment, as shown in FIG. 2D, a portion of the top surface of the first protruding portion 251 may be vertically overlapped with the interlayer protruding portion 265, which is provided thereon, and the dielectric layer 230, which is provided to surround (e.g., enclose) the interlayer protruding portion 265. In addition, a portion of the bottom surface of the second protruding portion 252 may be vertically overlapped with the interlayer protruding portion 265, which is provided therebelow, and the dielectric layer 230, which is provided to surround (e.g., enclose) the interlayer protruding portion 265. A bottom surface of the first protruding portion 251 and a top surface of the second protruding portion 252 may be vertically overlapped with the horizontal protruding portion 270, which is provided therebetween, and the dielectric layer 230, which is provided to surround (e.g., enclose) the horizontal protruding portion 270. A portion of the dielectric layer 230 interposed between the supporting portion 250 and the horizontal protruding portion 270 may be referred to as a horizontal dielectric layer 240, and a portion of the dielectric layer 230 interposed between the interlayer insulating layer 200 and the interlayer protruding portion 265 may be referred to as an interlayer dielectric layer 235. The horizontal dielectric layer 240 may have an inner side surface 240i facing the center CT of the top electrode TE, and an outer side surface 240o facing the supporting portion 250. The interlayer dielectric layer 235 may have an inner side surface 235i facing the center CT of the top electrode TE, and an outer side surface 235o facing the interlayer insulating layer 200. The outer side surface 240o of the horizontal dielectric layer 240 may not be vertically aligned to (e.g., coplanar with) the outer side surface 235o of the interlayer dielectric layer 235. That is, the outer side surface 240o of the horizontal dielectric layer 240 may be horizontally separated or offset from the outer side surface 235o of the interlayer dielectric layer 235.

In an embodiment, as shown in FIG. 2G, the entire top surface of the first protruding portion 251 may be vertically overlapped with the interlayer protruding portion 265, which is provided thereon, and the dielectric layer 230, which is provided to surround (e.g., enclose) the interlayer protruding portion 265. In this case, the outer side surface 240o of the horizontal dielectric layer 240 may be vertically aligned to (e.g., coplanar with) the outer side surface 235o of the interlayer dielectric layer 235. However, embodiments of the disclosure are not limited to this example. In an embodiment, the interlayer protruding portions 265 may be vertically overlapped with the first bottom electrode BE1 as well as a portion of the second bottom electrode BE2. Thus, the outer side surface 240o of the horizontal dielectric layer 240 may be horizontally separated or offset from the outer side surface 235o of the interlayer dielectric layer 235.

The first protruding portion 251 and the second protruding portion 252 of each of the first bottom electrodes BE1 may be horizontally overlapped with a portion of the vertical portion 260 of the top electrode TE. The supporting portion 250 of each of the first bottom electrodes BE1 may be horizontally overlapped with the horizontal protruding portion 270 of the top electrode TE.

Referring to FIGS. 1, 2A to 2C, 2E, and 2H, each of the horizontal electrodes PL may include the first bottom electrode BE1 and the second bottom electrode BE2. In an embodiment, the first bottom electrode BE1 may include a first protruding portion 251, a second protruding portion 252, and a third protruding portion 253, which extend toward the center CT of the top electrode TE, and the supporting portion 250, which is provided to connect the first protruding portion 251, the second protruding portion 252, and the third protruding portion 253 to each other. The first protruding portion 251, the second protruding portion 252, and the third protruding portion 253 may be spaced apart from each other in the third direction D3. In an embodiment, the first protruding portion 251 may be connected to the uppermost portion of the supporting portion 250, and the second protruding portion 252 may be connected to the lowermost portion of the supporting portion 250. The third protruding portion 253 may be connected to the supporting portion 250, between the first protruding portion 251 and the second protruding portion 252. That is, the third protruding portion 253 may be connected to an intermediate portion of the supporting portion 250. The first bottom electrode BE1 may include the second protruding portion 252, the third protruding portion 253, and the first protruding portion 251, which are sequentially arranged in the third direction D3. The first bottom electrode BE1 may be disposed between the second bottom electrode BE2 and the top electrode TE. The second bottom electrode BE2 may be connected to the supporting portion 250 of the first bottom electrode BE1. When viewed in a plan view, the first protruding portion 251, the second protruding portion 252, and the third protruding portion 253 may have a ring shape, which has a center axis passing through the center CT of the top electrode TE. The first protruding portion 251, the second protruding portion 252, and the third protruding portion 253 may be vertically overlapped with each other. The supporting portion 250 may have a ring shape, which has a center axis passing through the center CT of the top electrode TE.

The top electrode TE may include the horizontal protruding portions 270, which extend into regions between the first protruding portion 251 and the third protruding portion 253 of each of the first bottom electrodes BE1 and between the second protruding portion 252 and the third protruding portion 253. In detail, each of the horizontal protruding portions 270 may include a first horizontal protruding portion 261, which is extended into a region between the first protruding portion 251 and the third protruding portion 253, and a second horizontal protruding portion 262, which extends into a region between the second protruding portion 252 and the third protruding portion 253. The top electrode TE may include the interlayer protruding portions 265, which extend into regions between the first bottom electrodes BE1 that are adjacent to each other in the third direction D3. In addition, the top electrode TE may include the vertical portion 260 connecting the horizontal protruding portions 270 to the interlayer protruding portions 265. When viewed in a plan view, the first horizontal protruding portion 261 and the second horizontal protruding portion 262 and the interlayer protruding portions 265 may have a ring shape, which has a center axis passing through the center CT of the top electrode TE.

The dielectric layer 230 may be interposed between the stack ST and the top electrode TE and may conformally cover the side surface of the top electrode TE. The first protruding portion 251, the second protruding portion 252, and the third protruding portion 253 of each of the first bottom electrodes BE1 may be spaced apart from the top electrode TE with the dielectric layer 230 interposed therebetween.

When viewed in a plan view, at least a portion of the first protruding portion 251, the second protruding portion 252, and the third protruding portion 253 of each of the first bottom electrodes BE1 may be vertically overlapped with the interlayer protruding portions 265 of the top electrode TE. At least a portion of the first protruding portion 251, the second protruding portion 252, and the third protruding portion 253 of each of the first bottom electrodes BE1 may be vertically overlapped with the first horizontal protruding portion 261 and the second horizontal protruding portion 262 of the top electrode TE. In detail, the top surface of the first protruding portion 251 may be vertically overlapped with the interlayer protruding portion 265, which is provided thereon, and the dielectric layer 230, which is provided to surround (e.g., enclose) the interlayer protruding portion 265. The bottom surface of the second protruding portion 252 may be vertically overlapped with the interlayer protruding portion 265, which is provided therebelow, and the dielectric layer 230, which is provided to surround (e.g., enclose) the interlayer protruding portion 265.

In an embodiment, as shown in FIG. 2E, a portion of the top surface of the first protruding portion 251 may be vertically overlapped with the interlayer protruding portion 265, which is provided thereon, and the dielectric layer 230, which is provided to surround (e.g., enclose) the interlayer protruding portion 265. In addition, a portion of the bottom surface of the second protruding portion 252 may be vertically overlapped with the interlayer protruding portion 265, which is provided therebelow, and the dielectric layer 230, which is provided to surround (e.g., enclose) the interlayer protruding portion 265. The bottom surface of the first protruding portion 251 may be vertically overlapped with the first horizontal protruding portion 261 and the dielectric layer 230 enclosing the first horizontal protruding portion 261. The top surface of the second protruding portion 252 may be vertically overlapped with the second horizontal protruding portion 262 and the dielectric layer 230 enclosing the second horizontal protruding portion 262. A portion of the dielectric layer 230 interposed between the supporting portion 250 and the first horizontal protruding portion 261 may be referred to as a first horizontal dielectric layer 241, and a portion of the dielectric layer 230 interposed between the supporting portion 250 and the second horizontal protruding portion 262 may be referred to as a second horizontal dielectric layer 242. A portion of the dielectric layer 230 interposed between the interlayer insulating layer 200 and the interlayer protruding portion 265 may be referred to as the interlayer dielectric layer 235. The first horizontal dielectric layer 241 may have an inner side surface 241i facing the center CT of the top electrode TE, and an outer side surface 241o facing the supporting portion 250. The second horizontal dielectric layer 242 may have an inner side surface 242i facing the center CT of the top electrode TE, and an outer side surface 242o facing the supporting portion 250. The interlayer dielectric layer 235 may have the inner side surface 235i facing the center CT of the top electrode TE, and the outer side surface 235o facing the interlayer insulating layer 200. The outer side surface 241o of the first horizontal dielectric layer 241 may not be vertically aligned to (e.g., coplanar with) the outer side surface 235o of the interlayer dielectric layer 235. The outer side surface 242o of the second horizontal dielectric layer 242 may not be vertically aligned to (e.g., coplanar with) the outer side surface 235o of the interlayer dielectric layer 235. In other words, the outer side surfaces 241o and 242o of the first horizontal dielectric layer 241 and the second horizontal dielectric layer 242 may be horizontally separated or offset from the outer side surface 235o of the interlayer dielectric layer 235.

In an embodiment, as shown in FIG. 2H, the entire top surface of the first protruding portion 251 may be vertically overlapped with the interlayer protruding portion 265, which is provided thereon, and the dielectric layer 230, which is provided to surround (e.g., enclose) the interlayer protruding portion 265. In addition, the entire bottom surface of the second protruding portion 252 may be vertically overlapped with the interlayer protruding portion 265, which is provided therebelow, and the dielectric layer 230, which is provided to surround (e.g., enclose) the interlayer protruding portion 265. In this case, the outer side surfaces 241o and 242o of the first horizontal dielectric layer 241 and the second horizontal dielectric layer 242 may be vertically aligned to (e.g., coplanar with) the outer side surface 235o of the interlayer dielectric layer 235. However, embodiments of the disclosure are not limited to this example. In an embodiment, the interlayer protruding portions 265 may be vertically overlapped with the first bottom electrode BE1 as well as a portion of the second bottom electrode BE2. Thus, the outer side surfaces 241o and 242o of the first horizontal dielectric layer 241 and the second horizontal dielectric layer 242 may be horizontally separated or offset from the outer side surface 235o of the interlayer dielectric layer 235.

A top surface of the third protruding portion 253 may be vertically overlapped with the first horizontal protruding portion 261 and the dielectric layer 230, which is provided to surround (e.g., enclose) the first horizontal protruding portion 261. A bottom surface of the third protruding portion 253 may be vertically overlapped with the second horizontal protruding portion 262 and the dielectric layer 230, which is provided to surround (e.g., enclose) the second horizontal protruding portion 262.

The first protruding portion 251, the second protruding portion 252, and the third protruding portion 253 of each of the first bottom electrodes BE1 may be horizontally overlapped with a portion of the vertical portion 260 of the top electrode TE. The supporting portion 250 of each of the first bottom electrodes BE1 may be horizontally overlapped with the first horizontal protruding portion 261 and the second horizontal protruding portion 262 of the top electrode TE.

Referring to FIGS. 1, 2A to 2C, and 2F, each of the horizontal electrodes PL may include only the second bottom electrode BE2. For example, each of the horizontal electrodes PL may not include the first bottom electrode BE1, unlike the features described with reference to FIGS. 2D and 2E. Each of the horizontal electrodes PL may have a shape protruding toward the center CT of the top electrode TE. That is, each of the horizontal electrodes PL may have a shape that is partially inserted into the top electrode TE through the side surface of the top electrode TE. When viewed in a plan view, each of the horizontal electrodes PL may have a ring shape, which has a center axis passing through the center CT of the top electrode TE.

The top electrode TE may have the interlayer protruding portions 265 and the vertical portion 260, which is provided to connect the interlayer protruding portions 265 to each other. For example, the top electrode TE may not include the horizontal protruding portions 270, unlike the features described with reference to FIGS. 2D and 2E.

When viewed in a plan view, at least a portion of each of the horizontal electrodes PL may be vertically overlapped with the interlayer protruding portions 265 of the top electrode TE. A portion of a top surface of each of the horizontal electrodes PL may be vertically overlapped with the interlayer protruding portion 265, which is provided thereon, and the dielectric layer 230, which is provided to surround (e.g., enclose) the interlayer protruding portion 265. A portion of a bottom surface of each of the horizontal electrodes PL may be vertically overlapped with the interlayer protruding portion 265, which is provided therebelow, and the dielectric layer 230, which is provided to surround (e.g., enclose) the interlayer protruding portion 265.

Each of the horizontal electrodes PL may be horizontally overlapped with a portion of the vertical portion 260 of the top electrode TE.

The horizontal electrodes PL and the top electrode TE may include a conductive material. In an embodiment, the horizontal electrodes PL and the top electrode TE may be formed of or include at least one from among doped silicon (Si), doped silicon germanium (SiGe), metallic materials (e.g., Ti, Mo, W, Cu, Al, Ta, Ru, Ir, Co, Pt, Au, and Ag), metal nitride materials (e.g., nitride materials containing Ti, Mo, W, Cu, Al, Ta, Ru, Ir, Co, Pt, Au, or Ag, titanium silicon nitride (TiSiN), titanium aluminum nitride (TiAlN), tantalum aluminum nitride (TaAlN)), conductive oxide materials (e.g., PtO, RuO₂, IrO₂, SRO (SrRuO₃), BSRO ((Ba,Sr)RuO₃), CRO (CaRuO₃), LSCo), and metal silicide materials. The horizontal electrodes PL and the top electrode TE may be a single layer, which is made of a single material, or a composite layer including two or more materials. In an embodiment, the horizontal electrodes PL and the top electrode TE may include materials having different work functions from each other.

According to an embodiment of the disclosure, the semiconductor device may include not only one horizontal capacitor but also a plurality of vertical capacitors, for each horizontal electrode PL. In detail, four vertical capacitors, which may be formed by the interlayer protruding portion 265 and the first protruding portion 251, by the first protruding portion 251 and the horizontal protruding portion 270, by the horizontal protruding portion 270 and the second protruding portion 252, and by the second protruding portion 252 and the interlayer protruding portion 265, may be provided for each horizontal electrode PL, as shown in FIGS. 2D and 2G. In addition, the supporting portion 250 and the second bottom electrode BE2 may be provided to face the horizontal protruding portion 270, thereby forming a single horizontal capacitor. In addition, six vertical capacitors, which may be formed by the interlayer protruding portion 265 and the first protruding portion 251, by the first protruding portion 251 and the first horizontal protruding portion 261, by the first horizontal protruding portion 261 and the third protruding portion 253, by the third protruding portion 253 and the second horizontal protruding portion 262, by the second horizontal protruding portion 262 and the second protruding portion 252, and by the second protruding portion 252 and the interlayer protruding portion 265, may be provided for each horizontal electrode PL, as shown in FIGS. 2E and 2H. That is, an area between each horizontal electrode PL and the top electrode TE facing each other may be increased, and this may make it possible to maximize the capacity of the capacitor of the semiconductor device.

In addition, since the dielectric layer 230 includes a ferroelectric layer and a semiconductor layer or the horizontal electrodes PL and the top electrode TE have different work functions, the hysteresis property may be asymmetrically designed, and this may make it possible to properly adjust the threshold voltage of the semiconductor device.

As a result, it may be possible to easily increase an integration density of the semiconductor device and to improve the electrical and reliability characteristics of the semiconductor device.

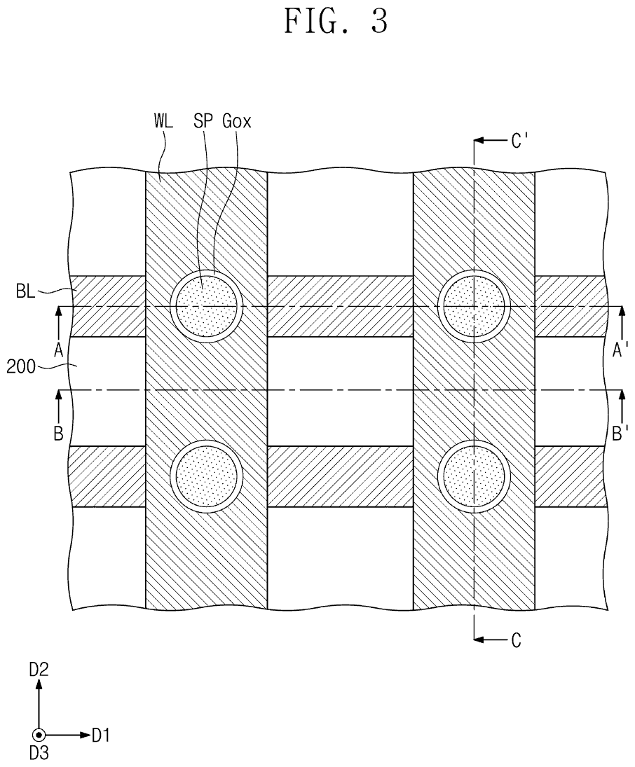

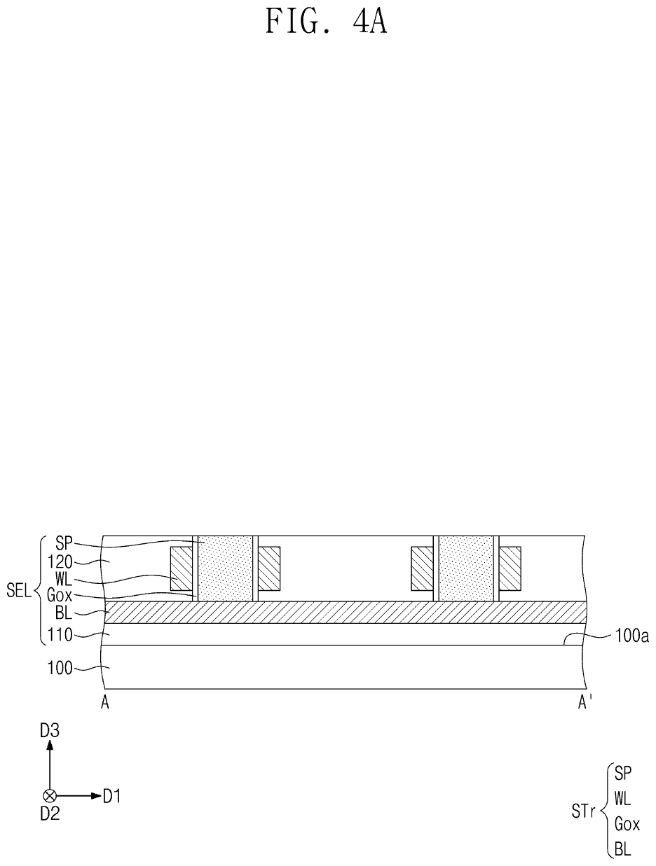

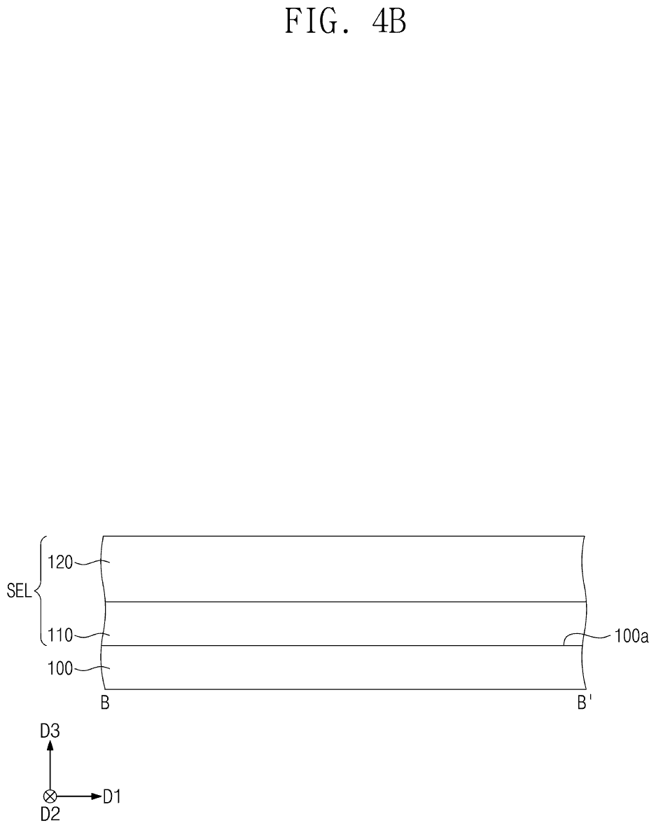

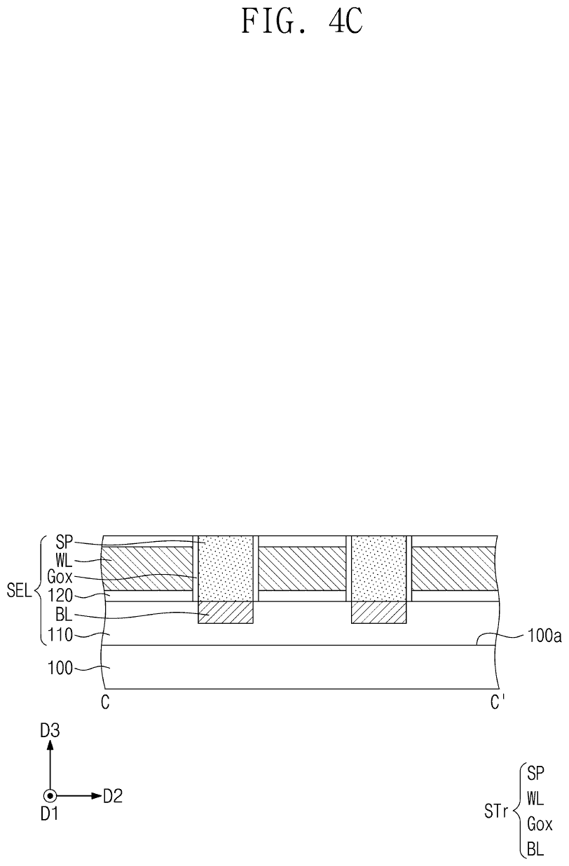

FIGS. 3 to 22C are diagrams illustrating a method of fabricating a semiconductor device, according to an embodiment of the disclosure. In detail, FIGS. 3, 7, 10, 12, 14, 18, and 20 are plan views illustrating a semiconductor device according to an embodiment of the disclosure. FIGS. 4A, 5A, 6A, 8A, 9A, 11A, 13A, 15A, 16A, 17A, 19A, 21A, and 22A are sectional views, which are respectively taken along lines A-A′ of the plan views to illustrate a semiconductor device according to an embodiment of the disclosure. FIGS. 4B, 5B, 6B, 8B, 9B, 11B, 13B, 15B, 16B, 17B, 19B, 21B, and 22B are sectional views, which are respectively taken along lines B-B′ of the plan views to illustrate a semiconductor device according to an embodiment of the disclosure. FIGS. 4C, 5C, 6C, 8C, 9C, 11C, 13C, 15C, 16C, 17C, 19C, 21C, and 22C are sectional views, which are respectively taken along lines C-C′ of the plan views to illustrate a semiconductor device according to an embodiment of the disclosure. For concise description, a previously described element may be identified by the same reference number without repeating an overlapping description thereof.

Referring to FIGS. 3 and 4A to 4C, the selection element layer SEL may be formed on the substrate 100. The selection element layer SEL may include the lower insulating layer 110, the selection transistors STr, and the selection insulating layer 120. Each of the selection transistors STr may include the bit line BL, the semiconductor pattern SP, the word line WL, and the gate insulating pattern Gox. In detail, the lower insulating layer 110 and the bit lines BL may be formed on the substrate 100. The bit lines BL may extend in the first direction D1 and may be spaced apart from each other in the second direction D2. In an embodiment, the formation of the bit lines BL may include forming a bit line layer and patterning the bit line layer.

The semiconductor patterns SP, the gate insulating patterns Gox, and the word lines WL may be formed on the bit lines BL. The word lines WL may extend in the second direction D2 and may be spaced apart from each other in the first direction D1. The semiconductor patterns SP may be formed to have a shape extending in the third direction D3 perpendicular to the top surface 100a of the substrate 100. Each of the gate insulating patterns Gox may be formed to conformally surround (e.g., enclose) a corresponding one of the semiconductor patterns SP. In an embodiment, the gate insulating pattern Gox may be formed using a deposition method (e.g., an atomic layer deposition (ALD) method) having a good step coverage property.

The selection insulating layer 120 may be formed on the lower insulating layer 110 to cover the selection transistors STr. In an embodiment, the selection insulating layer 120 may be formed using a deposition method (e.g., a physical vapor deposition (PVD) method or a chemical vapor deposition (CVD) method).

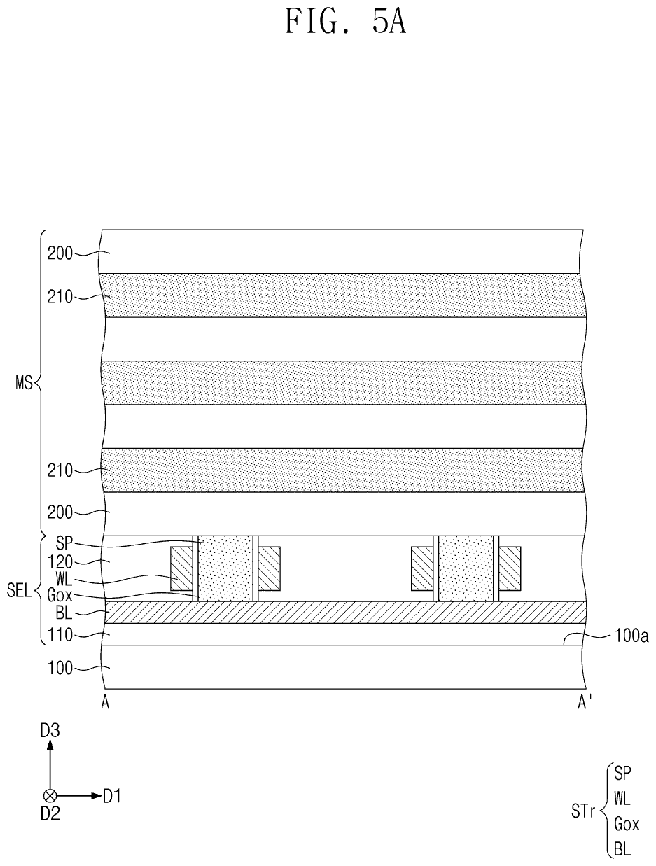

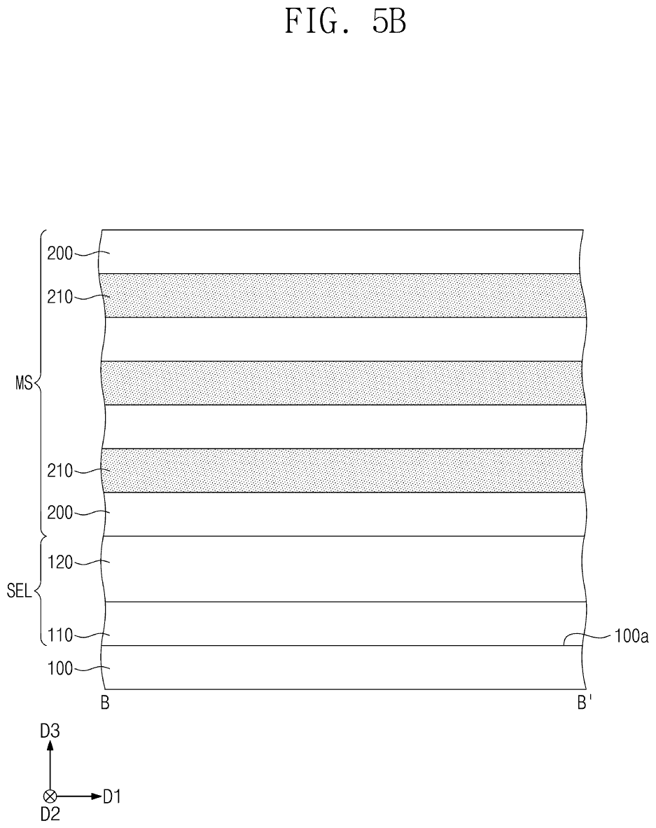

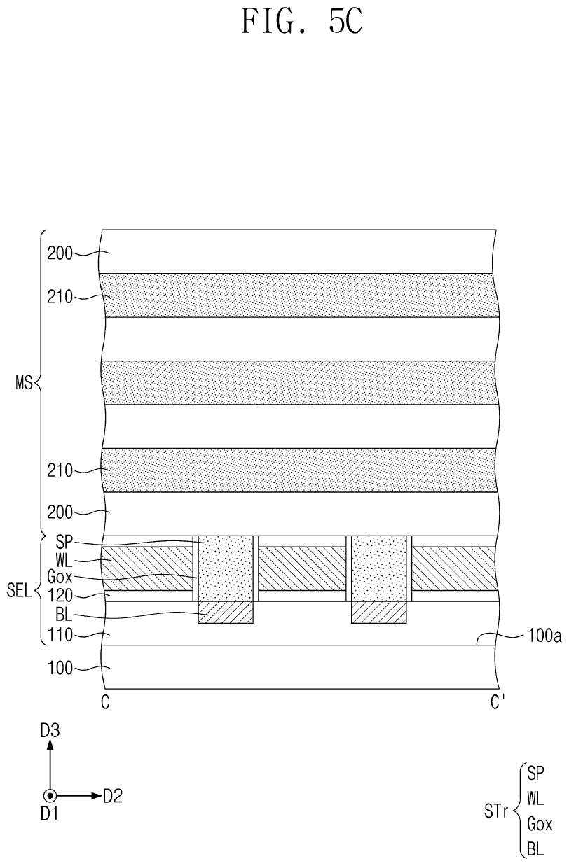

Referring to FIGS. 3 and 5A to 5C, a mold structure MS may be formed on the selection element layer SEL. The mold structure MS may include the interlayer insulating layers 200 and first sacrificial layers 210, which are alternately stacked in the third direction D3. The first sacrificial layers 210 may be provided to have a selectivity with respect to the interlayer insulating layers 200 and the selection insulating layer 120. For example, the first sacrificial layers 210 may be formed of silicon nitride, and the interlayer insulating layers 200 may be formed of silicon oxide.

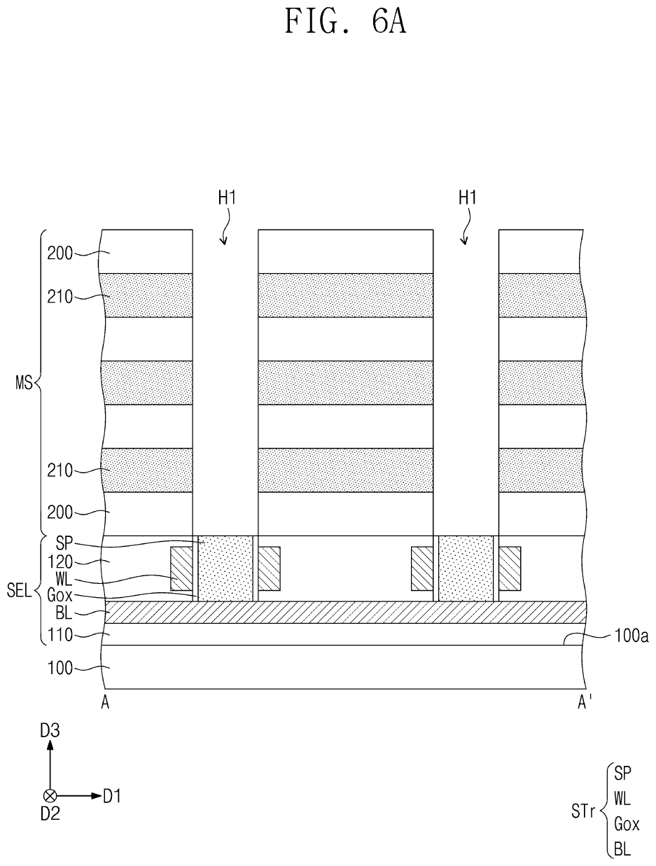

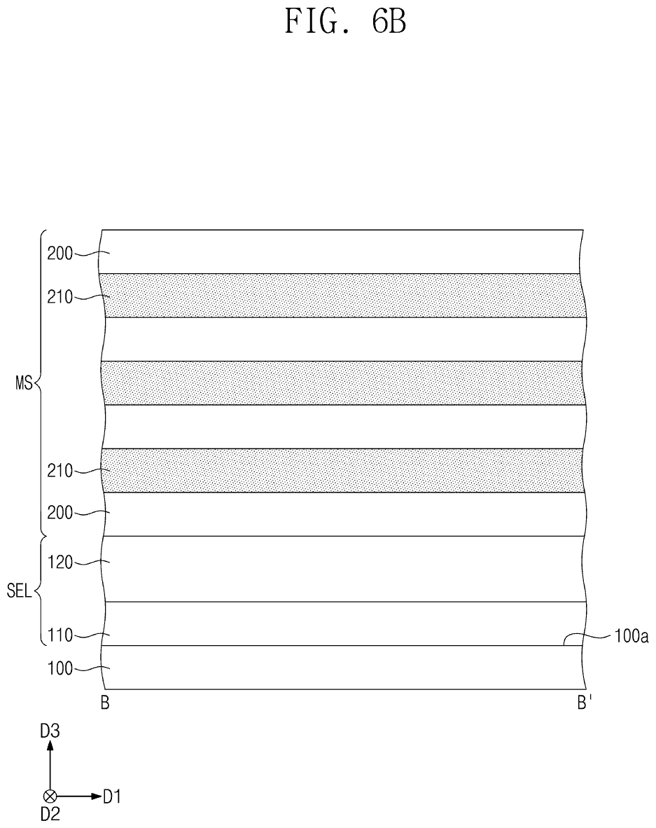

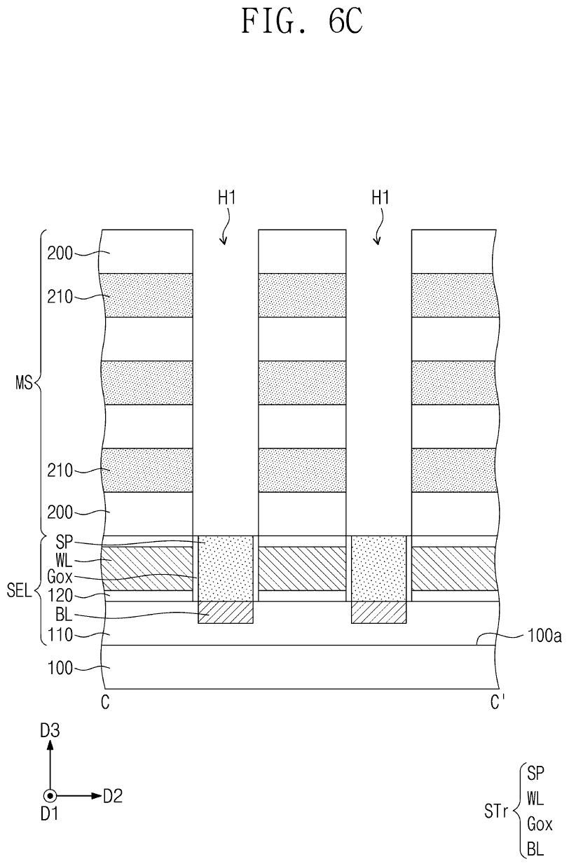

Referring to FIGS. 3 and 6A to 6C, a first hole H1 may be formed to penetrate the mold structure MS. In an embodiment, a plurality of first holes H1 may be formed. The first holes H1 may be formed to be spaced apart from each other in the first direction D1 and the second direction D2. The first holes H1 may be formed to expose the top surfaces of the semiconductor patterns SP, respectively. That is, each of the first holes H1 may be vertically overlapped with a corresponding one of the semiconductor patterns SP. In an embodiment, the first holes H1 may be formed to expose the top surfaces of the gate insulating patterns Gox, respectively. The first holes H1 may not penetrate the selection element layer SEL. In an embodiment, the formation of the first holes H1 may include performing an anisotropic etching process.

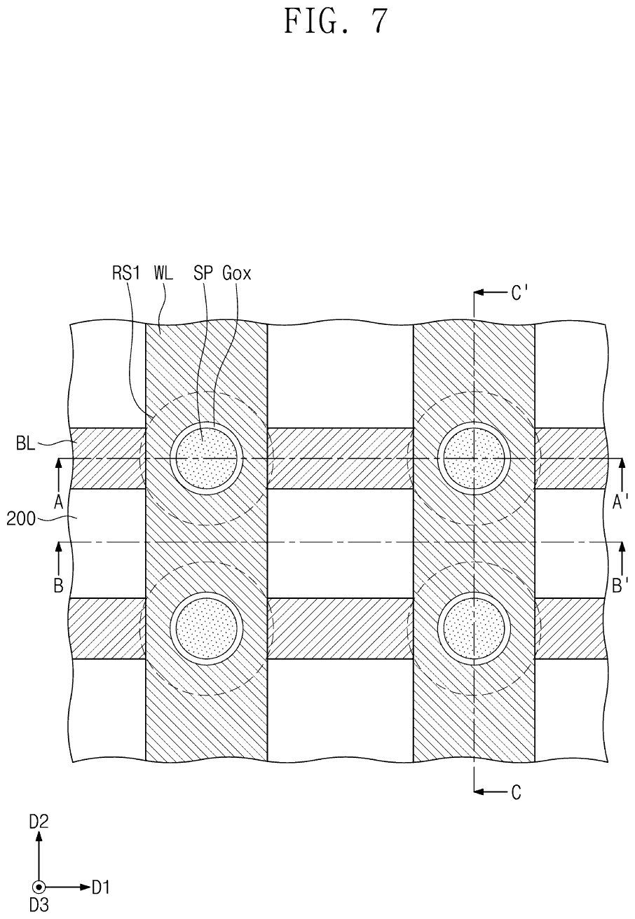

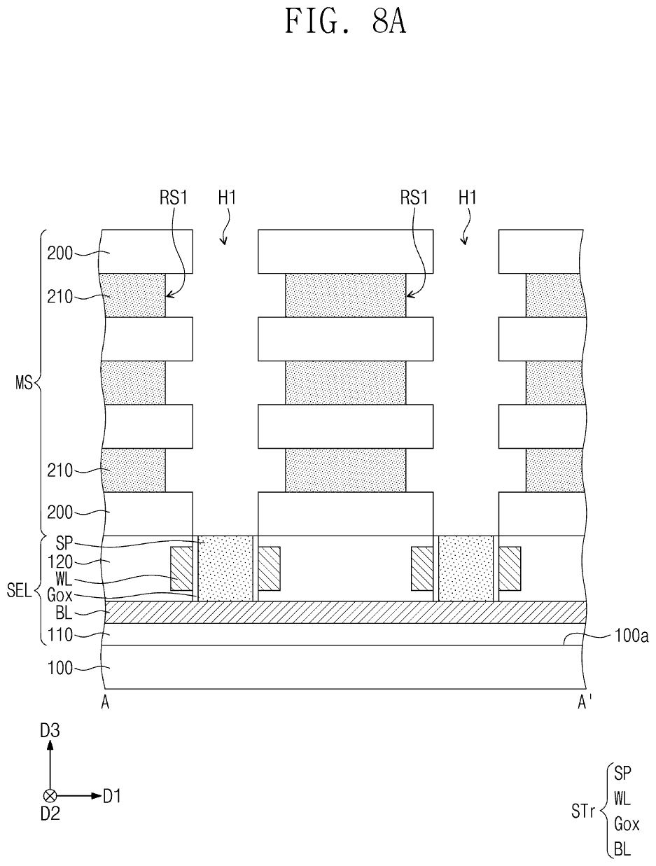

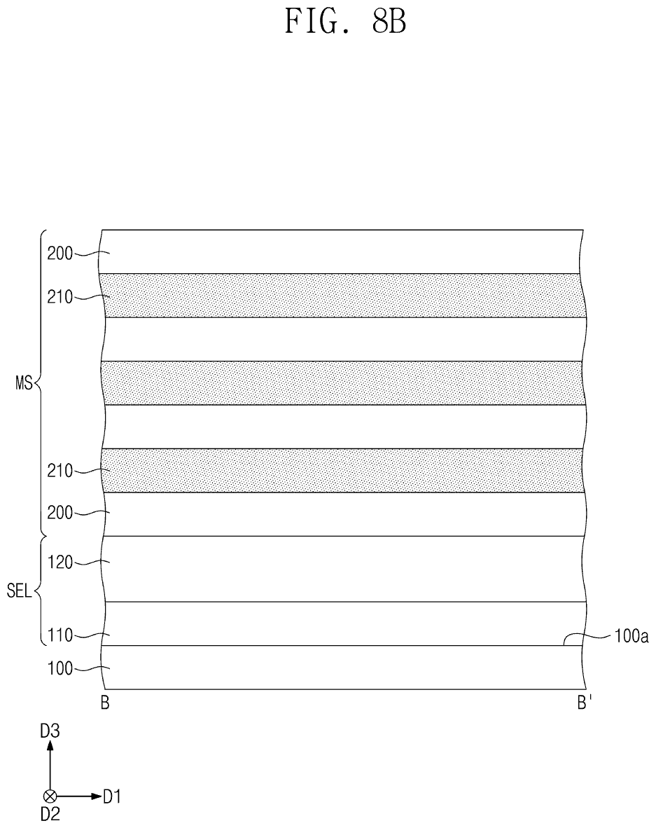

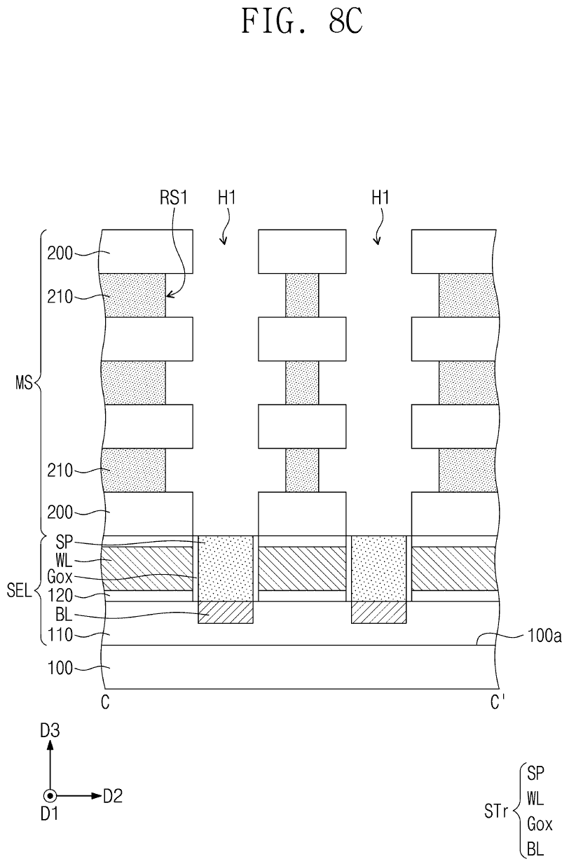

Referring to FIGS. 7 and 8A to 8C, the side surfaces of the first sacrificial layers 210 exposed by the first hole H1 may be partially etched to form first recess portions RS1. The process of partially etching the side surfaces of the first sacrificial layers 210 may include performing a wet etching process using an etching solution. During the wet etching process, the side surfaces of the first sacrificial layers 210 may be partially and selectively etched, but the interlayer insulating layers 200 and the semiconductor pattern SP may not be etched.

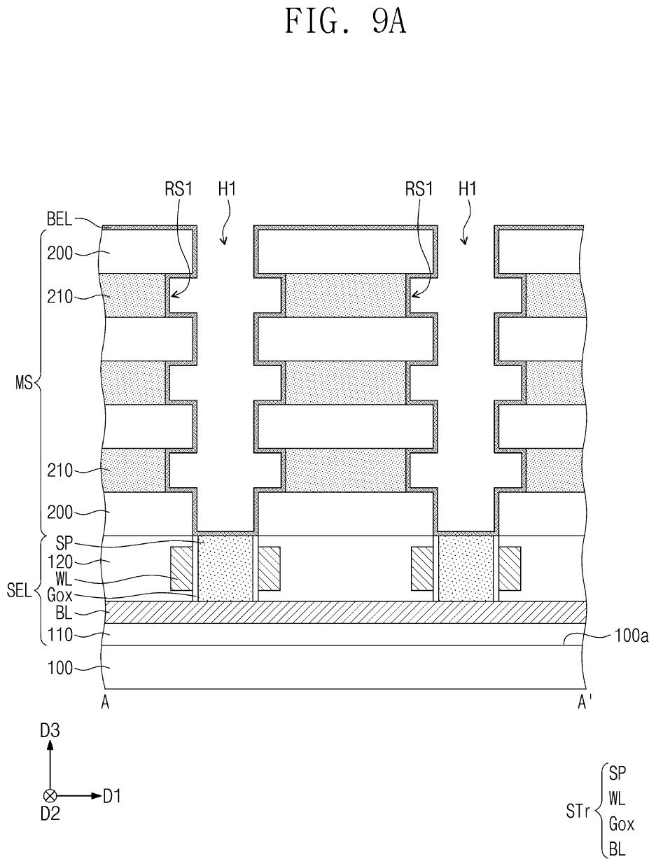

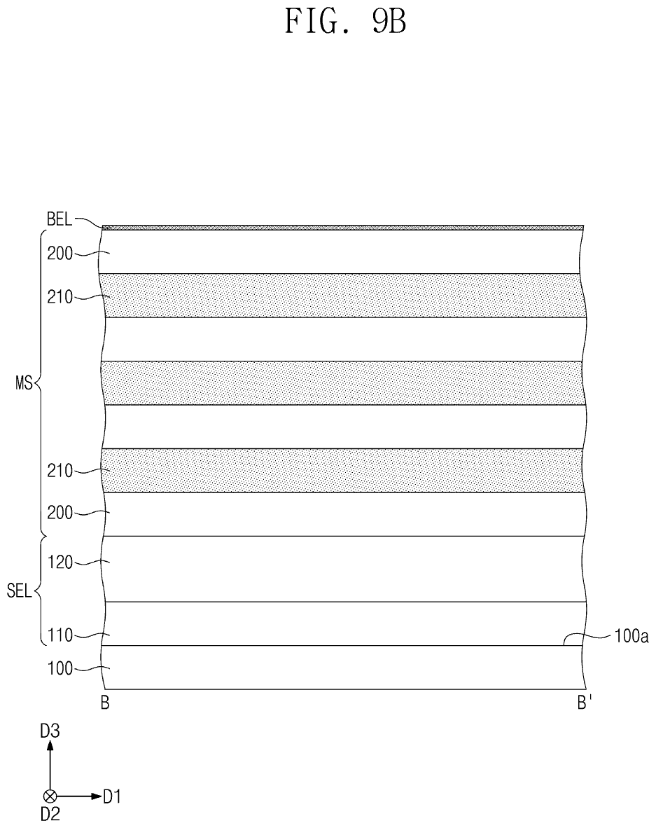

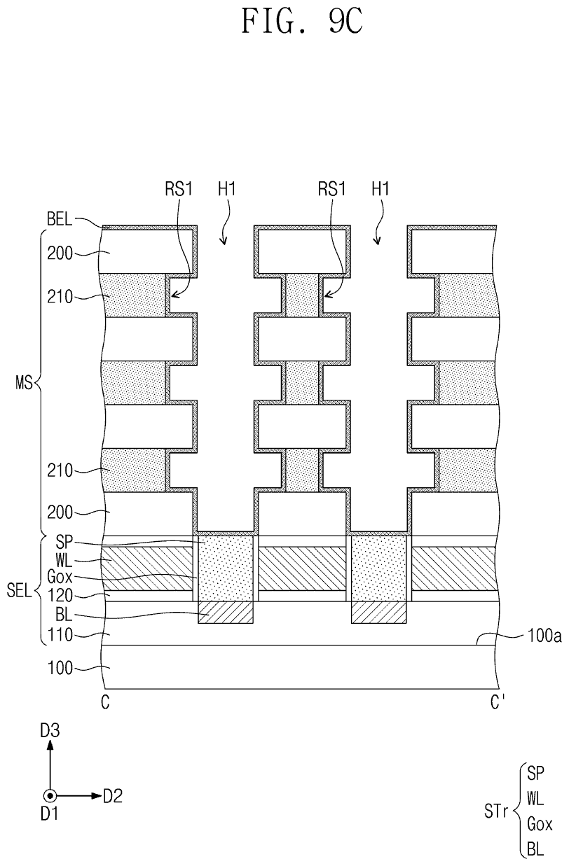

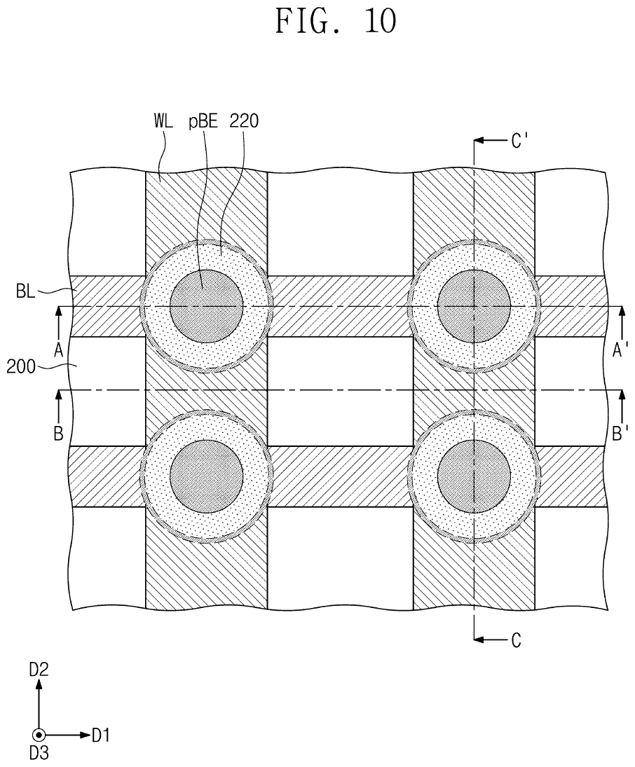

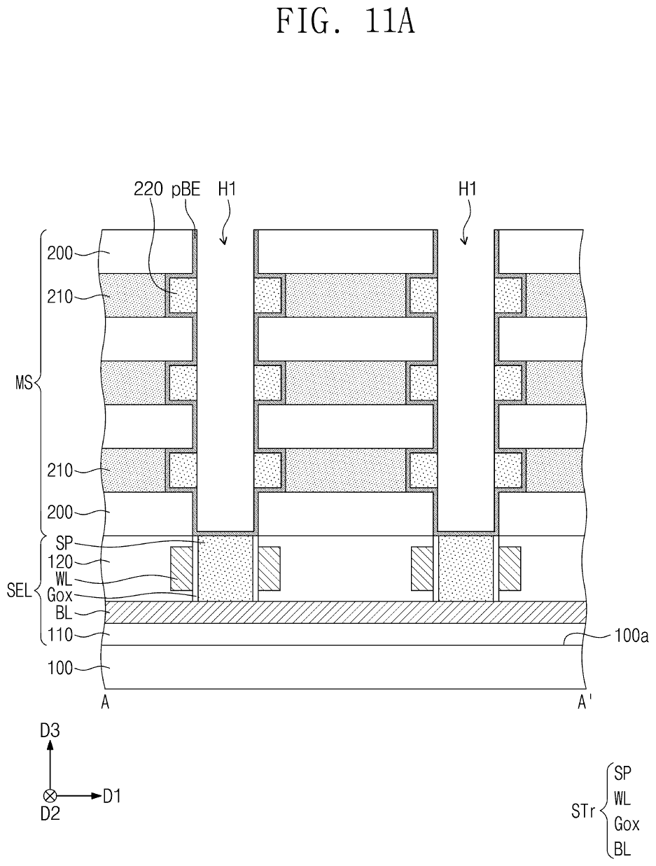

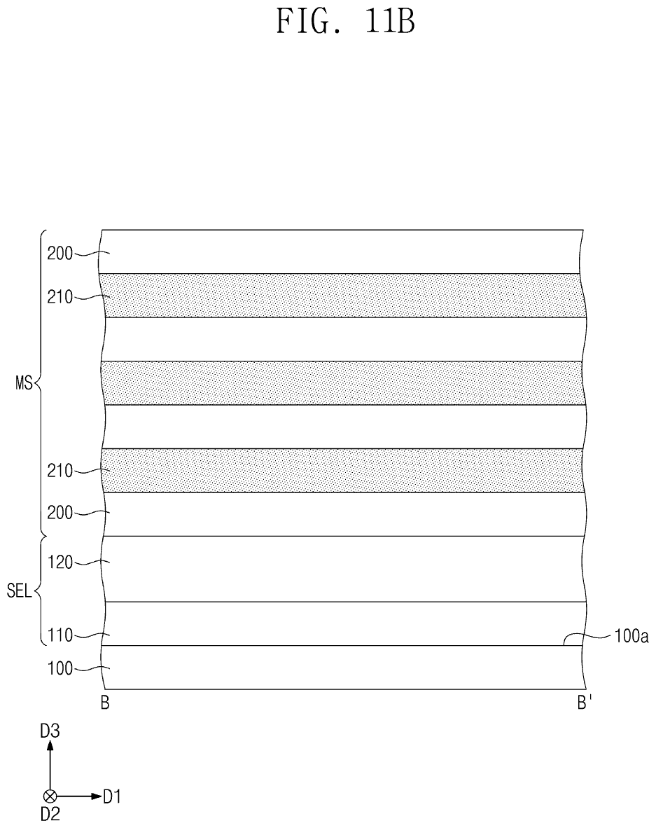

Referring to FIGS. 7 and 9A to 9C, a bottom electrode layer BEL may be formed on the structure of FIGS. 8A to 8C. The bottom electrode layer BEL may be formed to conformally cover the mold structure MS. That is, the bottom electrode layer BEL may conformally cover the side surfaces of the interlayer insulating layers 200 and the first sacrificial layers 210, which are exposed by the first hole H1 and the first recess portions RS1. In addition, the bottom electrode layer BEL may conformally cover the top surface of the selection element layer SEL exposed by the first hole H1. In an embodiment, the bottom electrode layer BEL may be formed using a deposition method (e.g., a chemical vapor deposition (CVD) method and an atomic layer deposition (ALD) method) having a good step coverage property.

The bottom electrode layer BEL may include a conductive material. In an embodiment, the bottom electrode layer BEL may be formed of or include at least one from among doped silicon (Si), doped silicon germanium (SiGe), metallic materials (e.g., Ti, Mo, W, Cu, Al, Ta, Ru, Ir, Co, Pt, Au, and Ag), metal nitride materials (e.g., nitride materials containing Ti, Mo, W, Cu, Al, Ta, Ru, Ir, Co, Pt, Au, or Ag, titanium silicon nitride (TiSiN), titanium aluminum nitride (TiAlN), tantalum aluminum nitride (TaAlN)), conductive oxide materials (e.g., PtO, RuO₂, IrO₂, SRO (SrRuO₃), BSRO ((Ba,Sr)RuO₃), CRO (CaRuO₃), LSCo), and metal silicide materials.

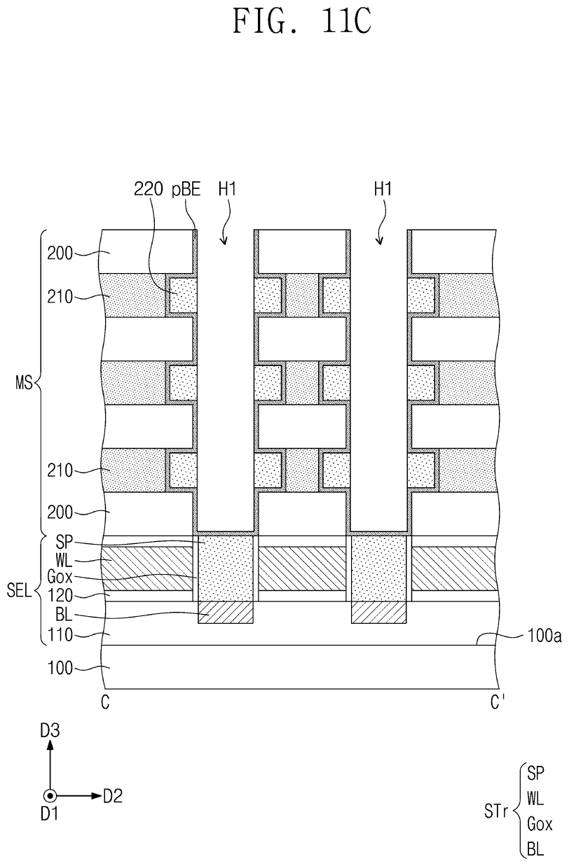

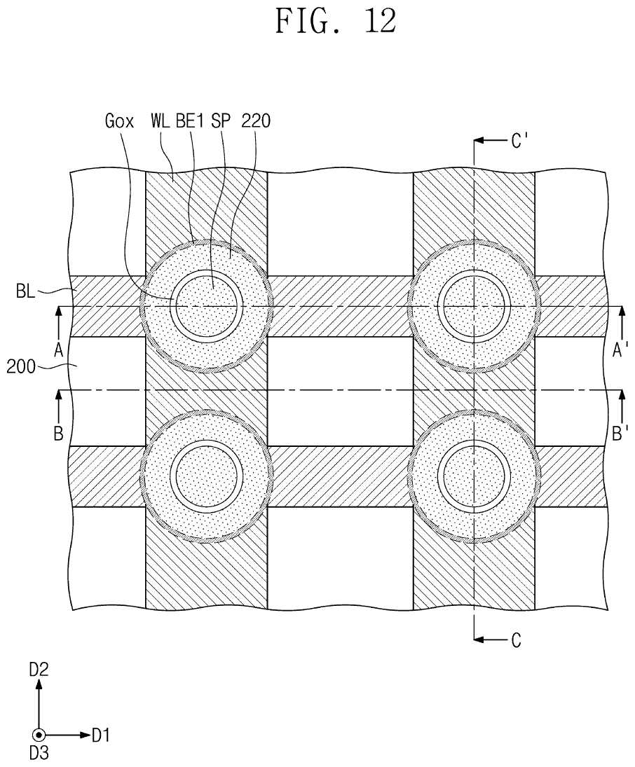

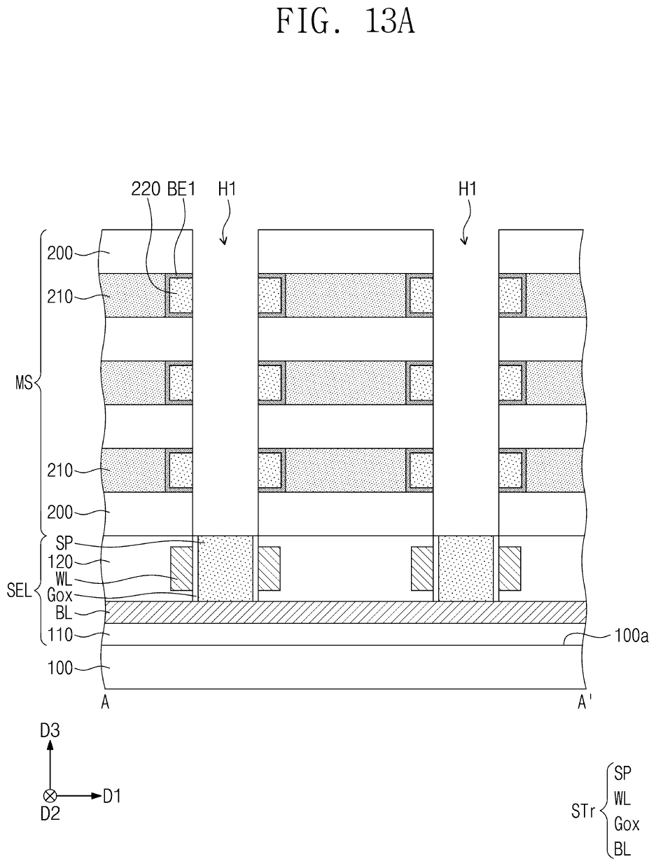

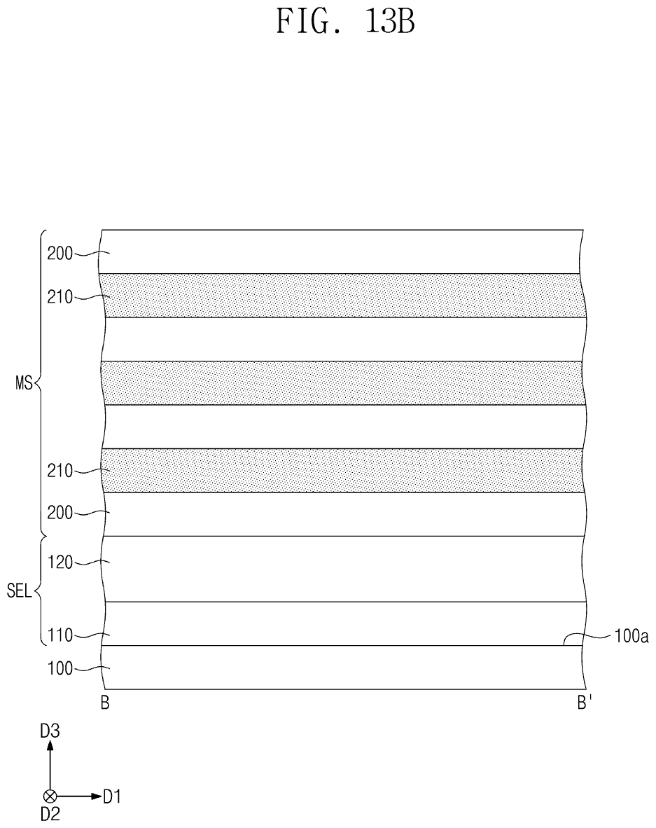

Referring to FIGS. 10 and 11A to 11C, a preliminary bottom electrode pBE may be formed. In addition, second sacrificial patterns 220 may be formed in remaining portions of the first recess portions RS1. In an embodiment, the formation of the preliminary bottom electrode pBE may include forming a second sacrificial layer to fill a remaining portion of the first hole H1 and the remaining portion of the first recess portions RS1 and planarizing an upper portion of the second sacrificial layer to expose the interlayer insulating layer 200, which is the uppermost layer of the mold structure MS. Next, the formation of the second sacrificial patterns 220 may include performing an anisotropic etching process to remove a portion of the second sacrificial layer and to form the remaining portion of the first hole H1 again. In an embodiment, the second sacrificial patterns 220 may have a selectivity with respect to the interlayer insulating layers 200.

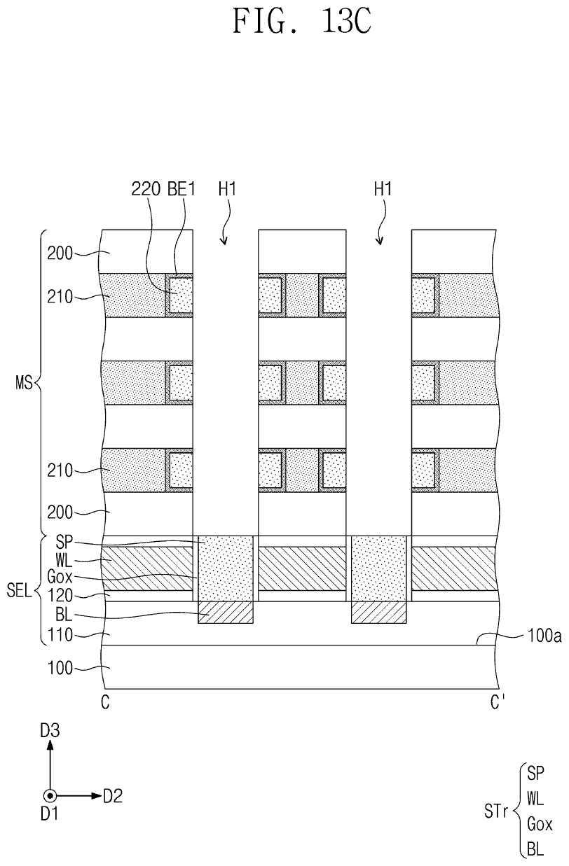

Referring to FIGS. 12 and 13A to 13C, the first bottom electrodes BE1 may be formed. In an embodiment, the formation of the first bottom electrodes BE1 may include performing an etching process to remove portions of the preliminary bottom electrode pBE formed on the side surfaces of the interlayer insulating layers 200 and the top surface of the selection element layer SEL. The second sacrificial patterns 220 may also be partially removed during the formation of the first bottom electrodes BE1. In addition, the first hole H1 may be formed again. Thus, a portion of the selection element layer SEL may be exposed again.

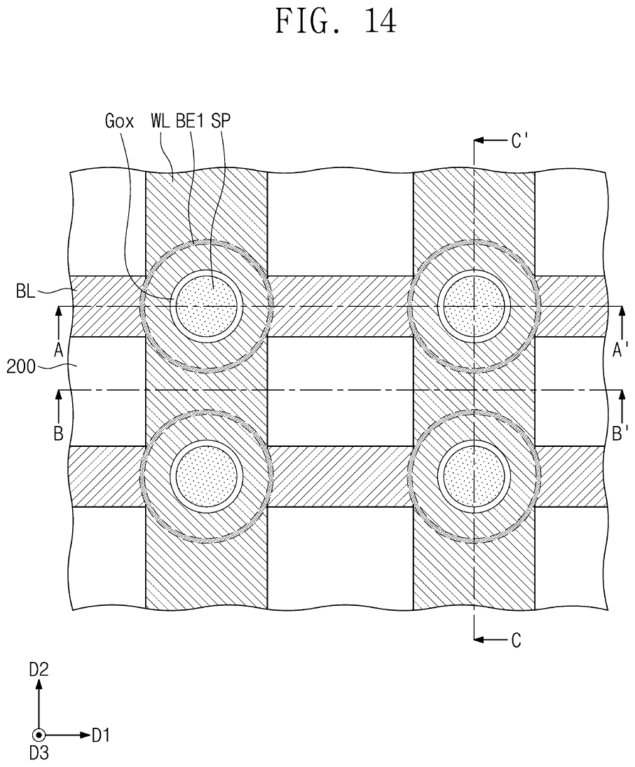

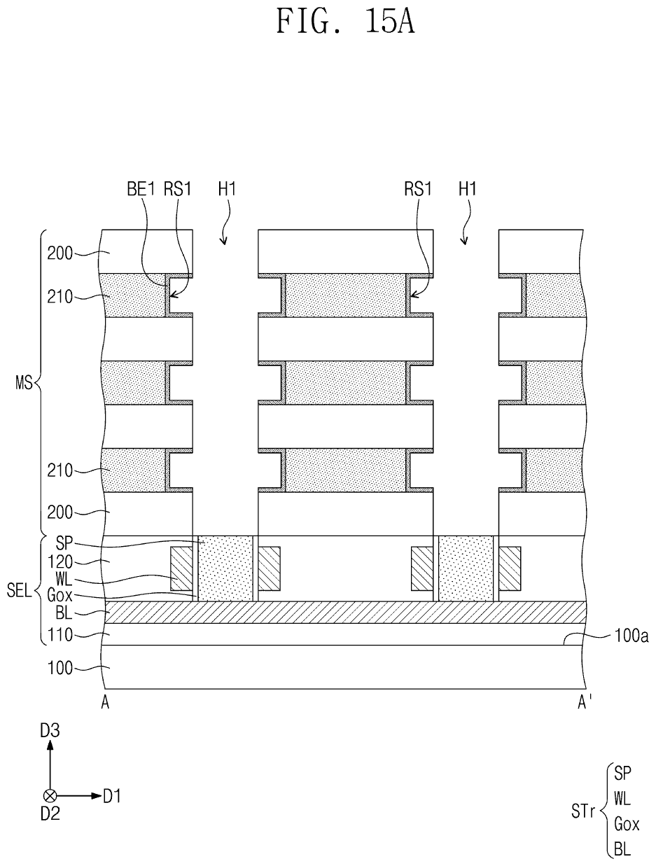

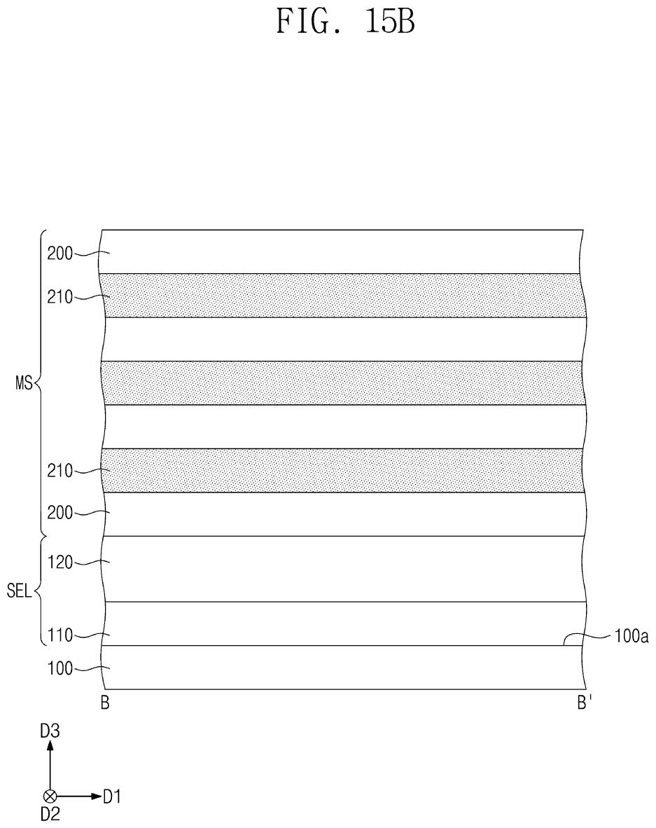

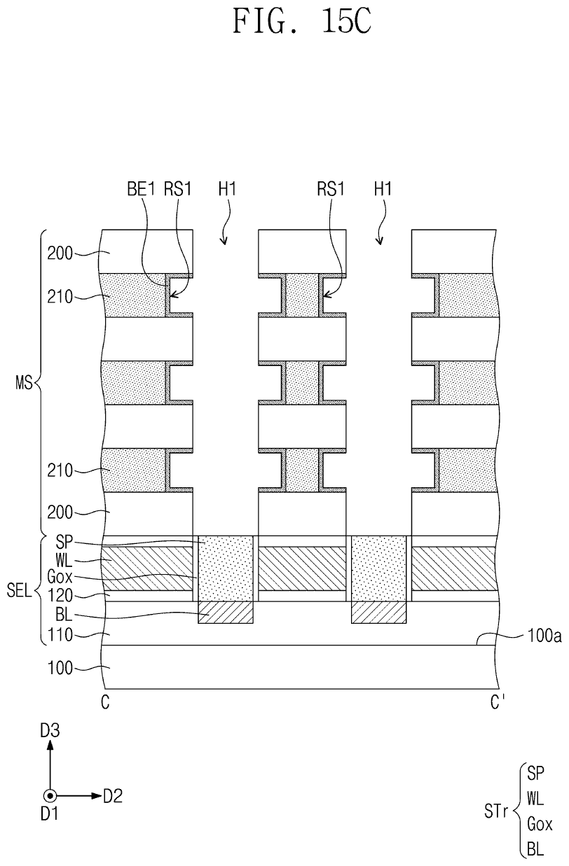

Referring to FIGS. 14 and 15A to 15C, the second sacrificial patterns 220 may be selectively removed. The selective removal of the second sacrificial patterns 220 may be performed by a wet etching process using an etching solution. The interlayer insulating layers 200 and the top surface of the selection element layer SEL exposed by the first hole H1 may not be etched during the wet etching process.

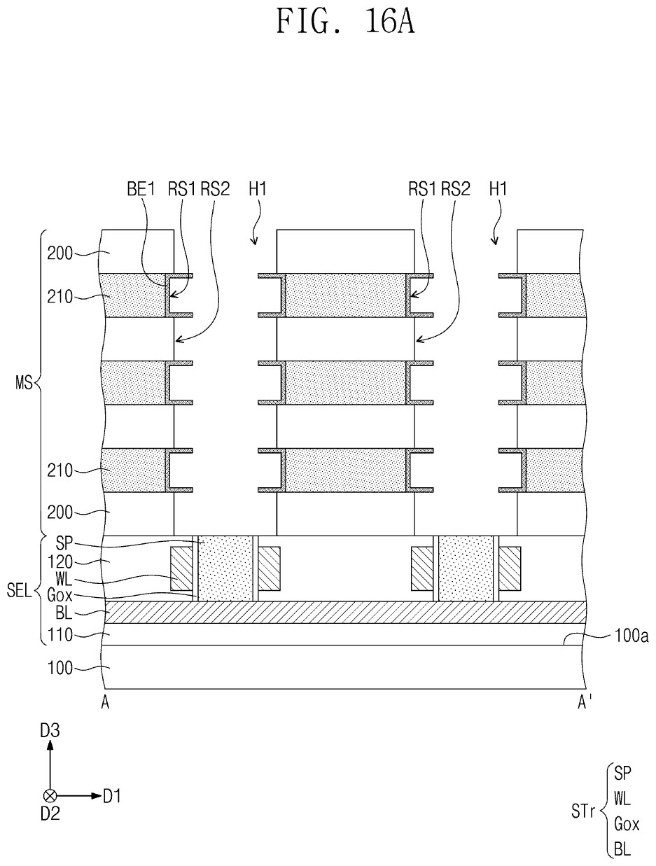

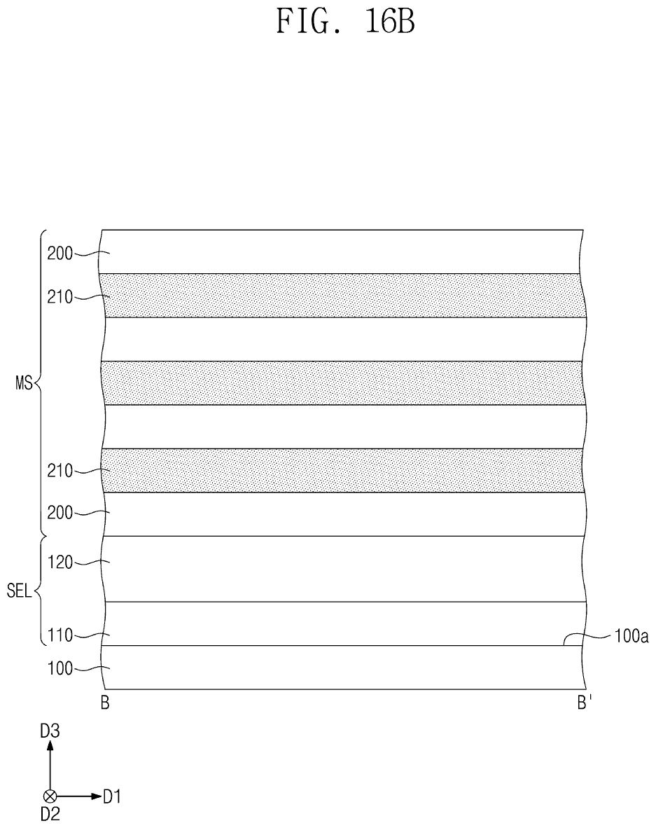

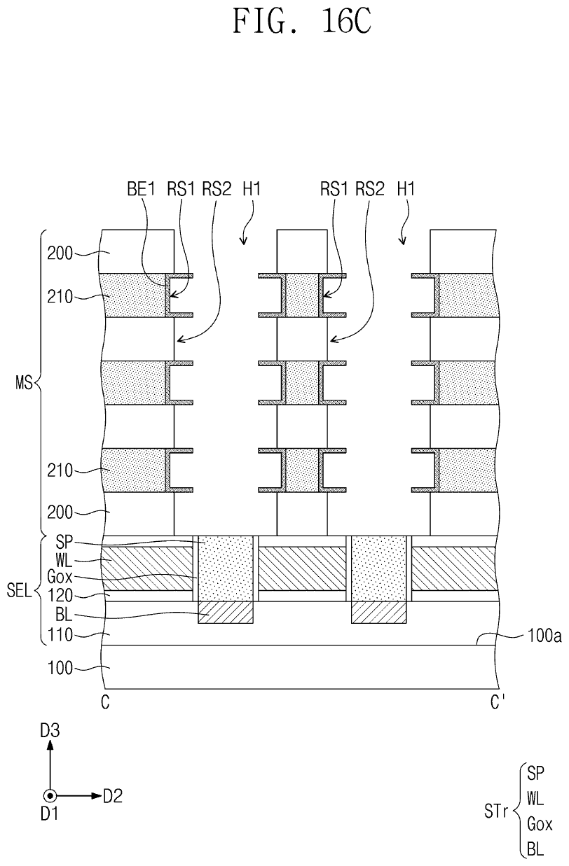

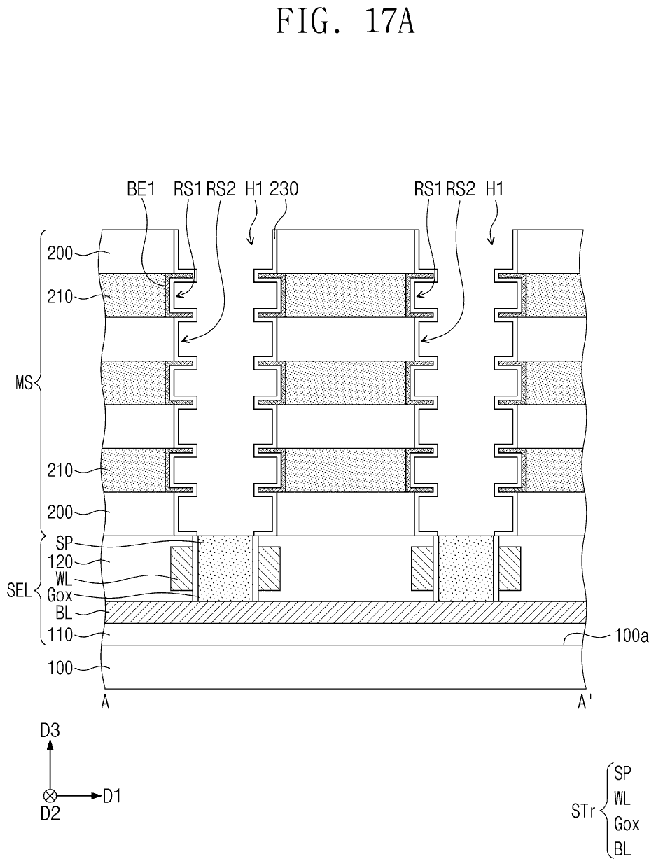

Referring to FIGS. 14 and 16A to 16C, the side surfaces of the interlayer insulating layers 200 exposed by the first hole H1 may be partially etched to form second recess portions RS2. The process of partially etching the side surfaces of the interlayer insulating layers 200 may be performed through a wet etching process using an etching solution. The top surface of the selection element layer SEL exposed by the first hole H1 may not be etched during the wet etching process.

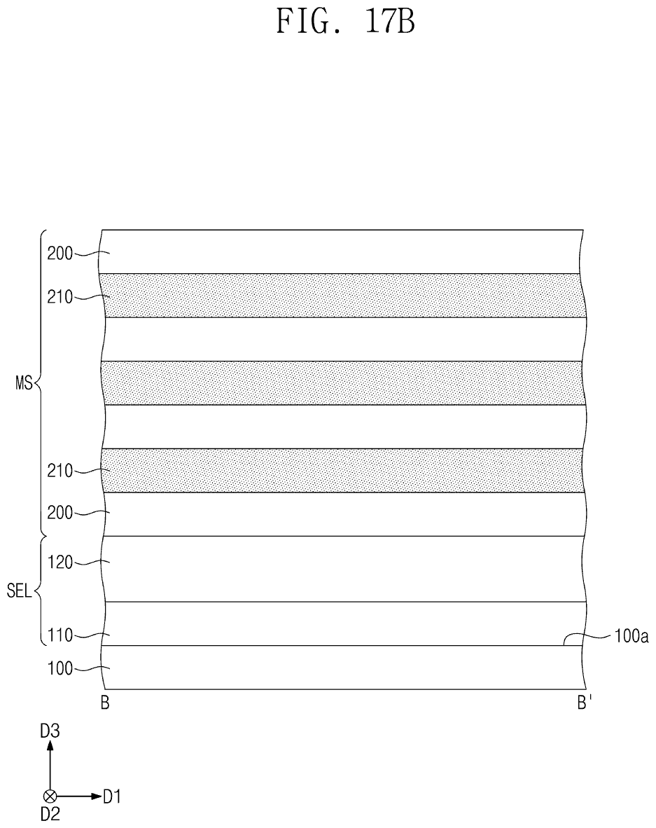

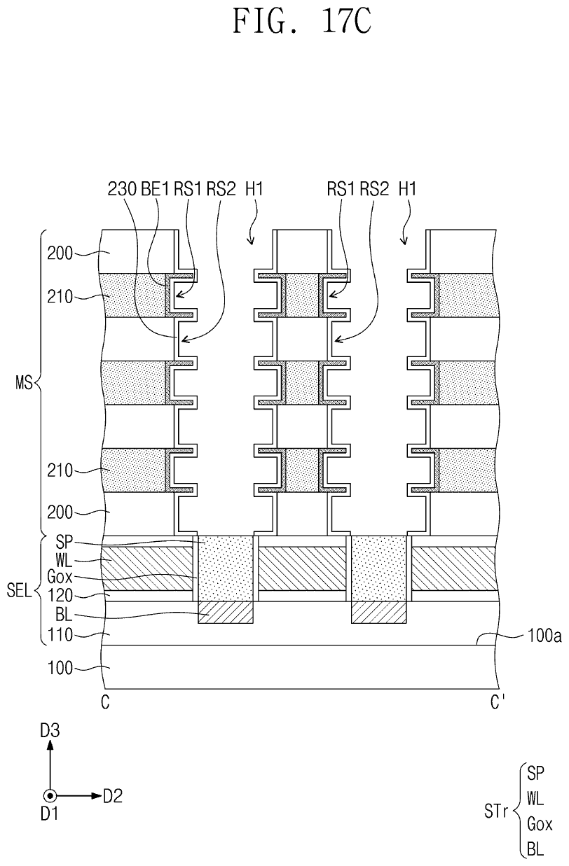

Referring to FIGS. 14 and 17A to 17C, the dielectric layer 230 may be formed to conformally cover the remaining portions of the first recess portions RS1 and the second recess portions RS2. For example, the dielectric layer 230 may conformally cover the side surfaces of the interlayer insulating layers 200 and the first bottom electrodes BE1, which are exposed by the remaining portions of the first recess portions RS1, the second recess portions RS2, and the first hole H1. The dielectric layer 230 may be formed to expose a portion of the top surface of the selection element layer SEL. In detail, the dielectric layer 230 may be formed to expose the top surface of the semiconductor pattern SP.

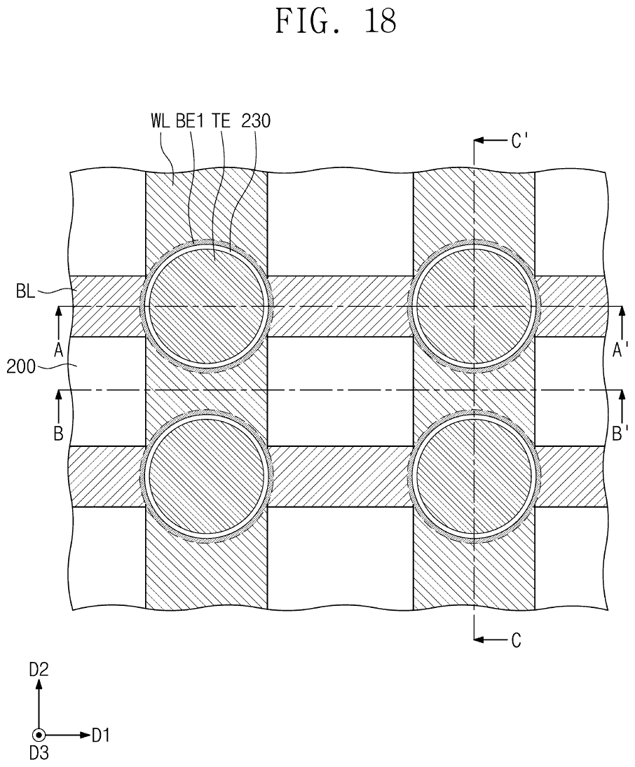

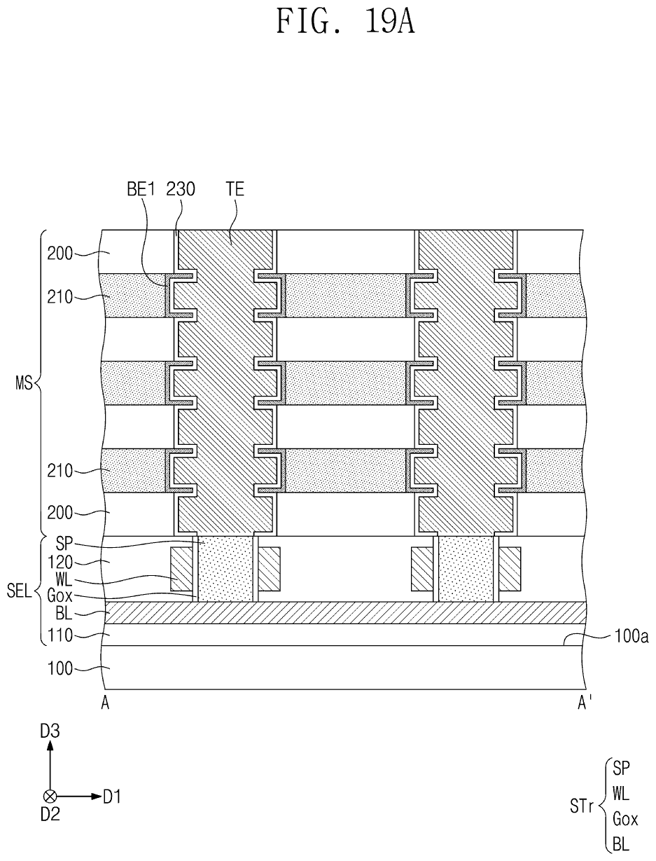

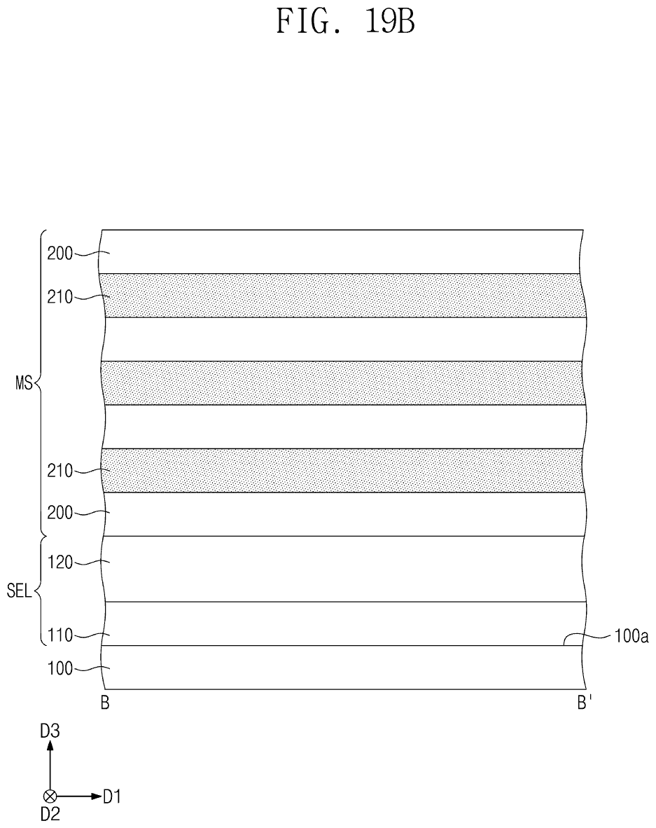

Referring to FIGS. 18 and 19A to 19C, the top electrode TE may be formed. The top electrode TE may be formed to fill remaining portions of the first recess portions RS1, remaining portions of the second recess portions RS2, and a remaining portion of the first hole H1. A bottom surface of the top electrode TE may be in contact with the top surface of the semiconductor pattern SP. A top surface of the top electrode TE may be coplanar with a top surface of the mold structure MS. The first bottom electrodes BE1 may be spaced apart from the top electrode TE with the dielectric layer 230 interposed therebetween.

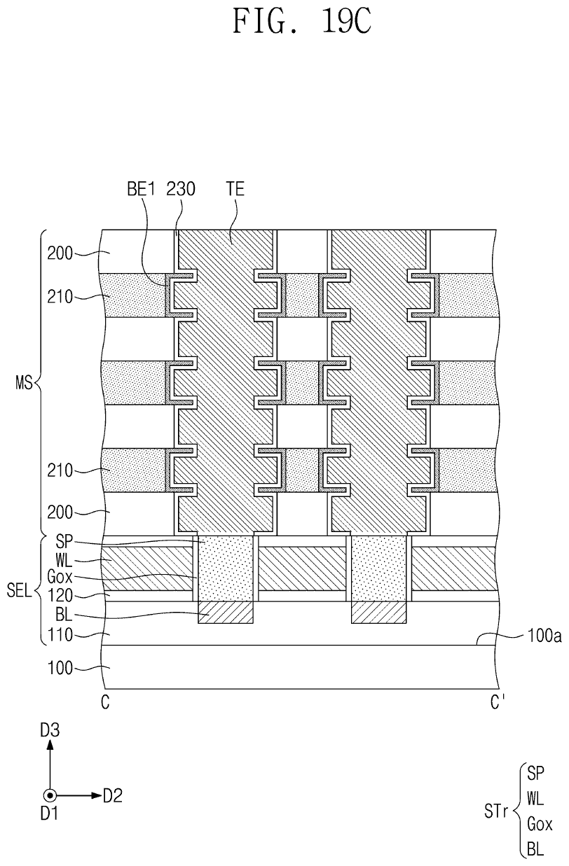

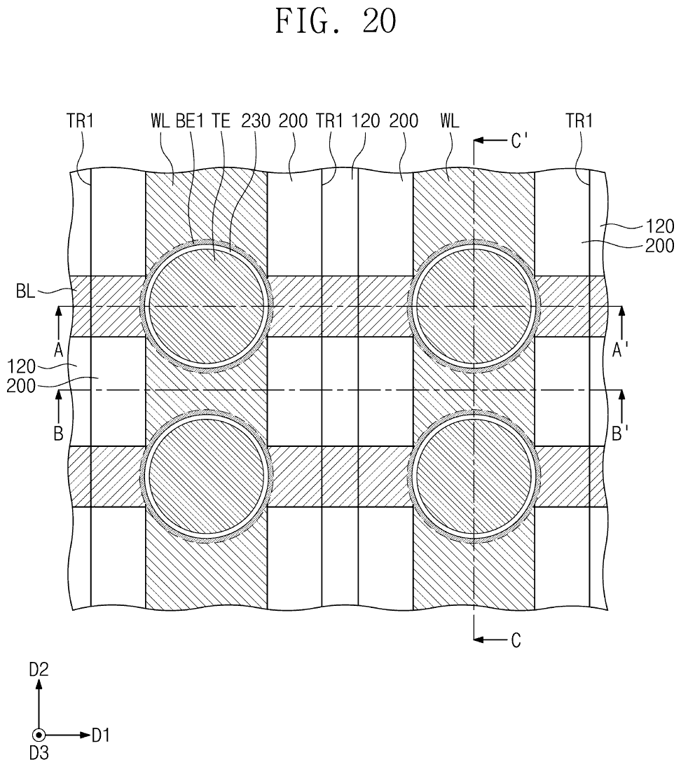

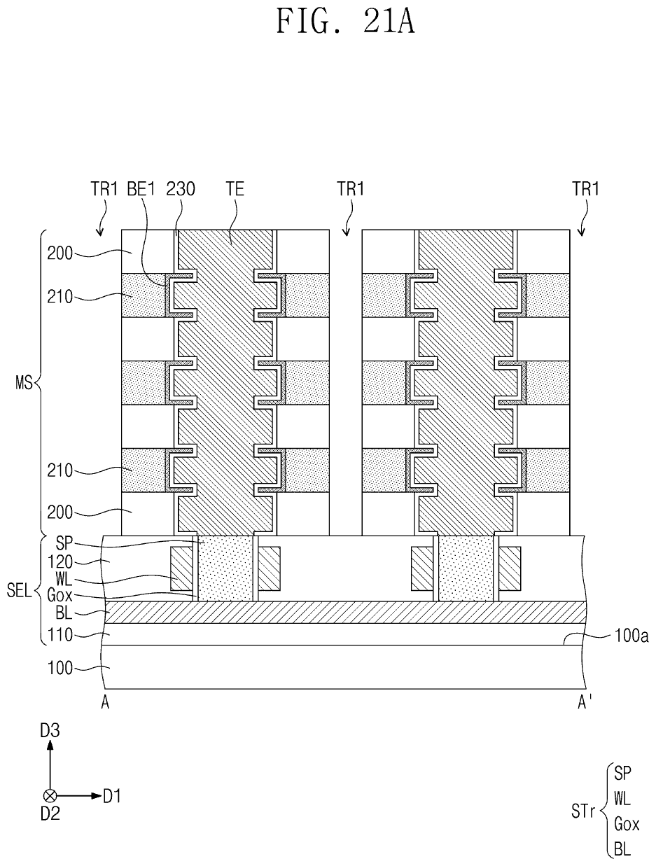

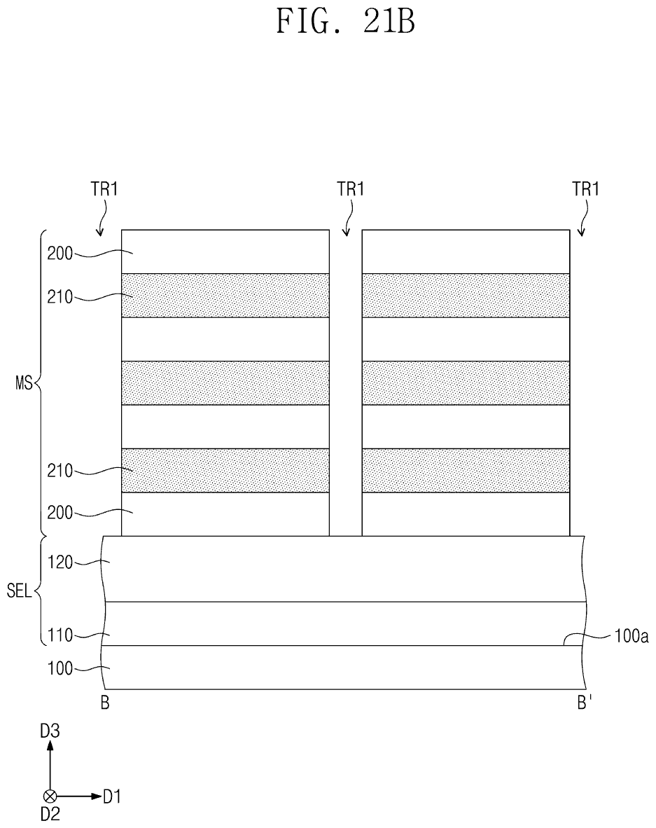

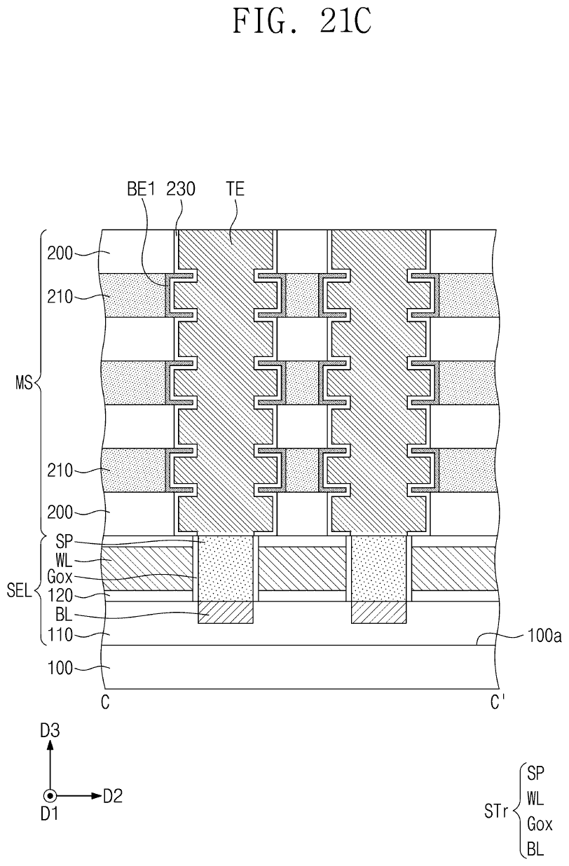

Referring to FIGS. 20 and 21A to 21C, the first trenches TR1 may be formed. The first trenches TR1 may be formed to penetrate the mold structure MS, and to cross the mold structure MS in the second direction D2. The first trenches TR1 may extend in the second direction D2 and may be spaced apart from each other in the first direction D1. The first trenches TR1 may be formed to expose the first sacrificial layers 210 and the side surfaces of the interlayer insulating layers 200.

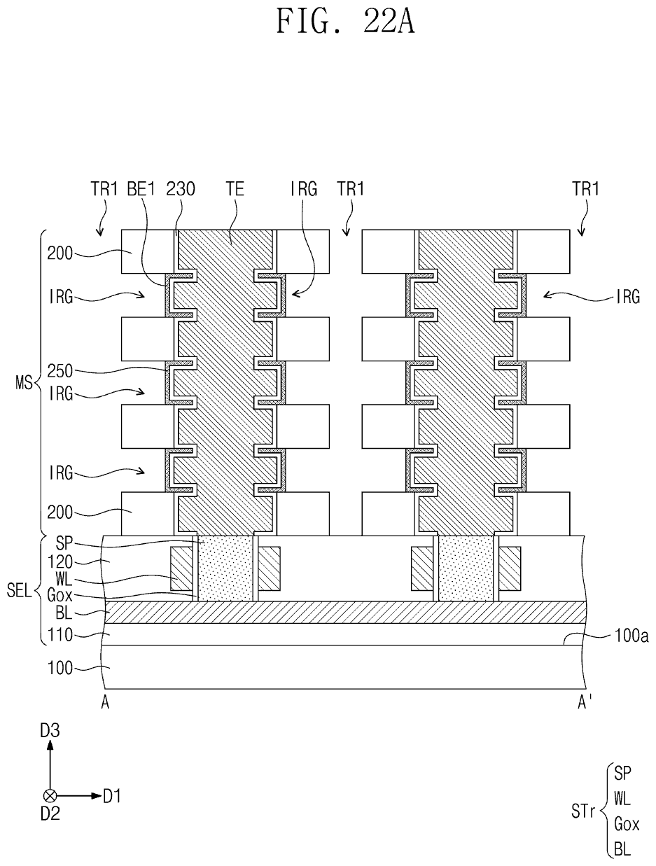

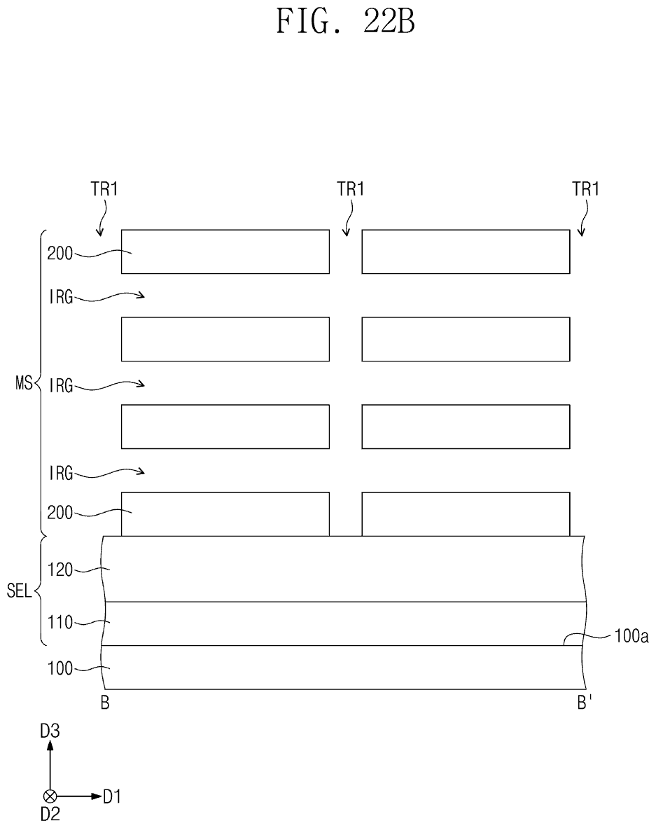

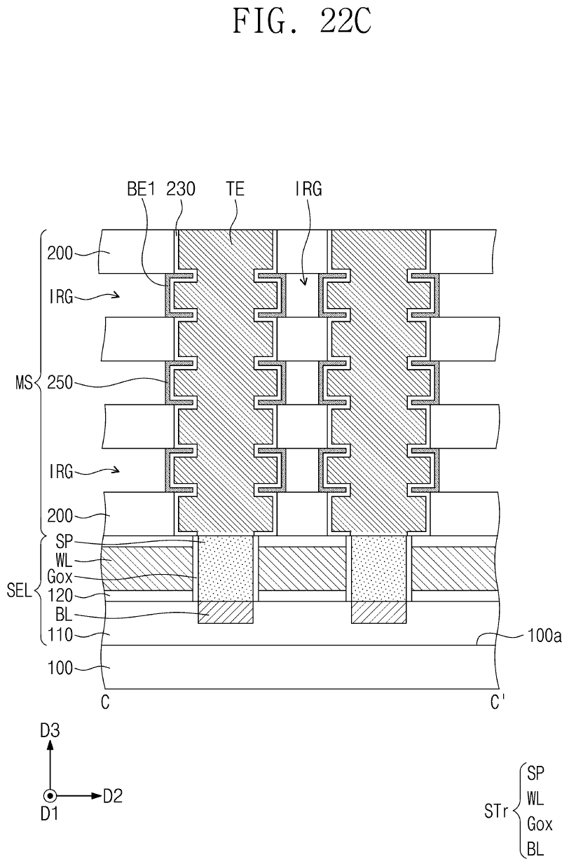

Referring to FIGS. 20 and 22A to 22C, inner regions IRG may be formed between the interlayer insulating layers 200, which are adjacent to each other in the third direction D3. In an embodiment, the formation of the inner regions IRG may include performing a wet etching process using an etching solution on the side surfaces of the first sacrificial layers 210 exposed by the first trenches TR1. During the wet etching process, the first sacrificial layers 210 may be selectively removed, but the interlayer insulating layers 200 may not be etched. The inner regions IRG may be formed to expose the supporting portions 250 of the first bottom electrodes BE1.

Referring back to FIGS. 1 and 2A to 2C, the second bottom electrodes BE2 may be formed to fill the inner regions IRG. The first electrode BE1 and the second bottom electrode BE2 may constitute the horizontal electrode PL.

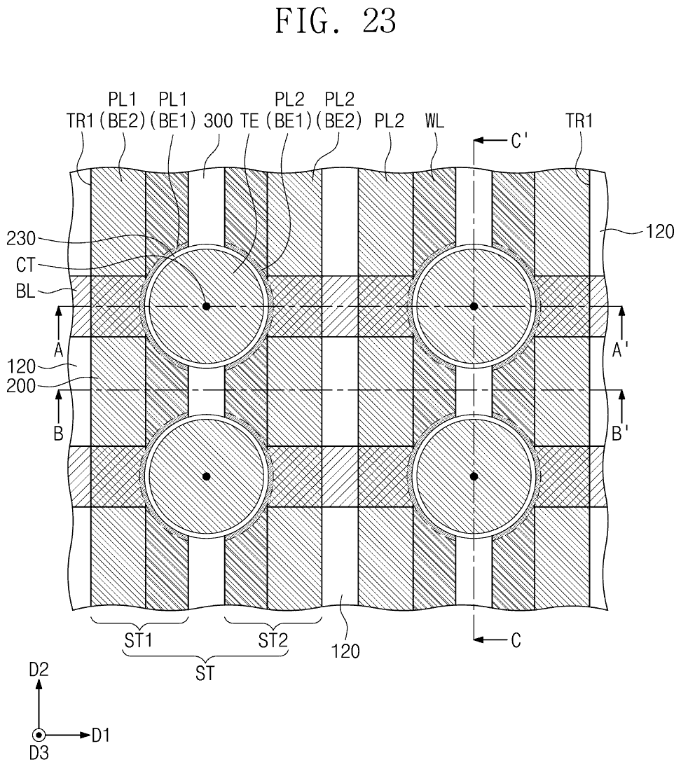

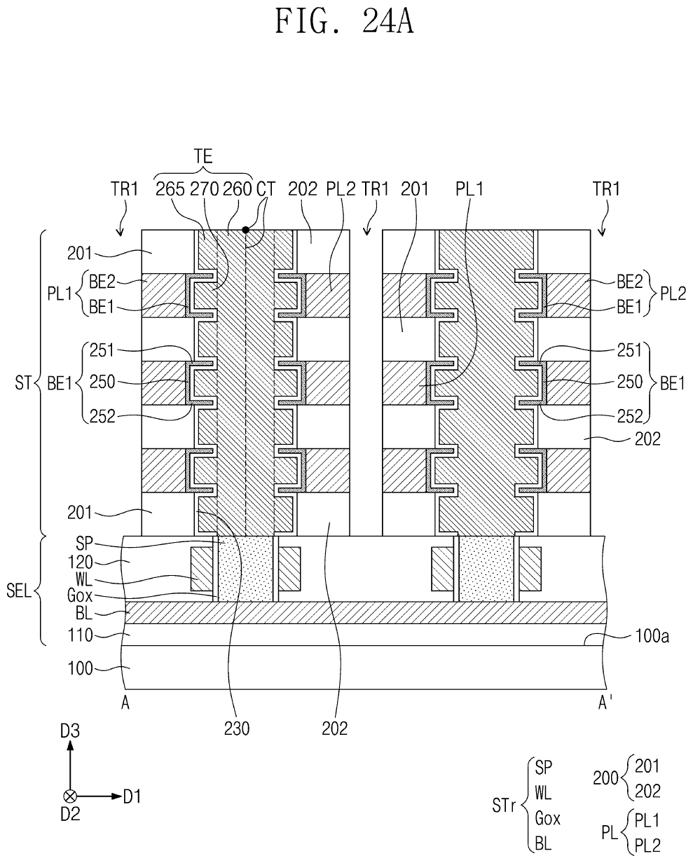

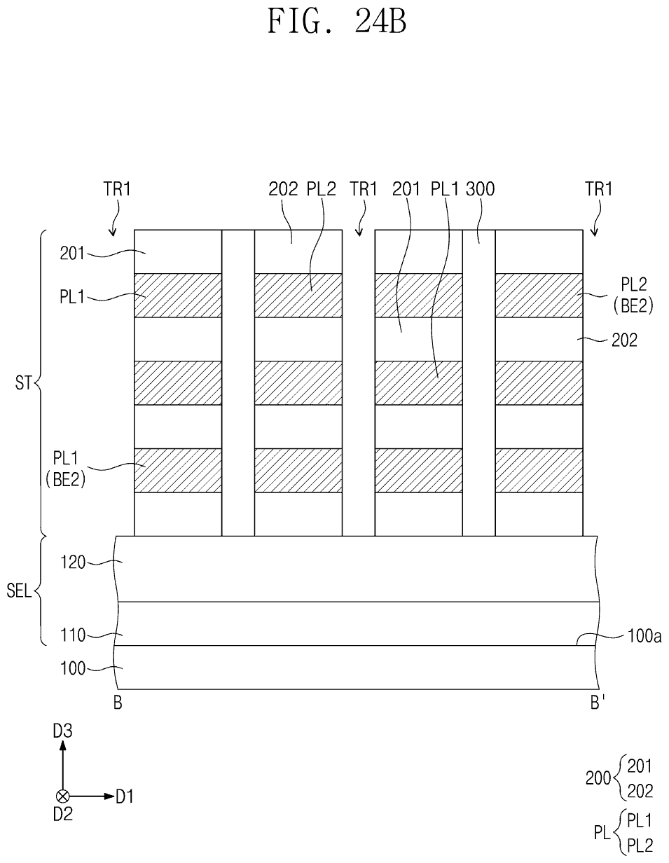

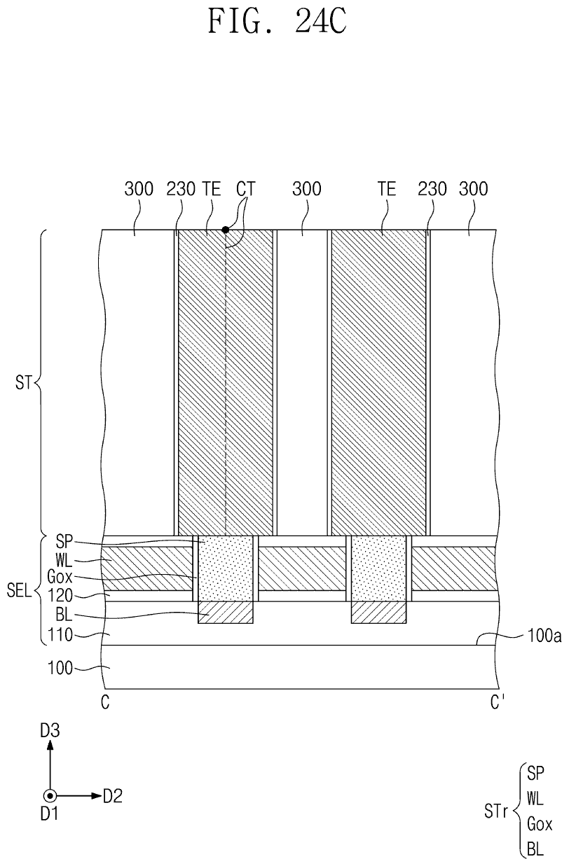

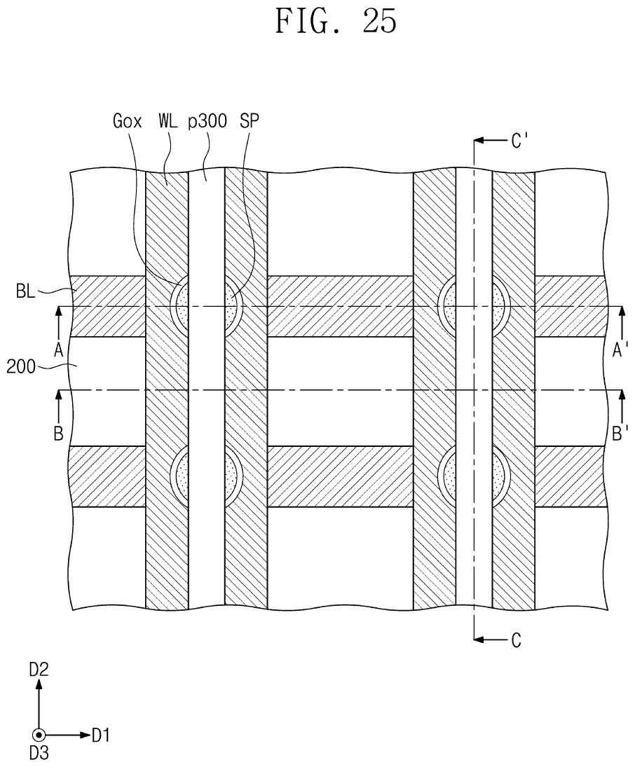

FIG. 23 is a plan view illustrating a semiconductor device according to an embodiment of the disclosure. FIGS. 24A to 24C are sectional views, which are taken along lines A-A′, B-B′, and C-C′ of FIG. 23 to illustrate a semiconductor device according to an embodiment of the disclosure. For concise description, an element described with reference to FIGS. 1 and 2A to 2C may be identified by the same reference number without repeating an overlapping description thereof.

Referring to FIGS. 23 and 24A to 24C, an insulating separation pattern 300 may be disposed to penetrate the stack ST. The insulating separation pattern 300 may be provided to penetrate the stack ST in the third direction D3 and may extend in the second direction D2. The insulating separation pattern 300 may be formed of or include at least one from among silicon oxide, silicon nitride, and silicon oxynitride and may be provided to have a single-or multi-layered structure.

Due to the insulating separation pattern 300, the stack ST may be divided into a first stack ST1 and a second stack ST2. The first stack ST1 and the second stack ST2 may be spaced apart from each other in the first direction D1 with the insulating separation pattern 300 interposed therebetween. Thus, the horizontal electrodes PL constituting the stack ST may be divided into first horizontal electrodes PL1 and second horizontal electrodes PL2. In addition, the interlayer insulating layers 200 may also be divided into first interlayer insulating layers 201 and second interlayer insulating layers 202. The first stack ST1 may include the first horizontal electrodes PL1 and the first interlayer insulating layers 201. The second stack ST2 may include the second horizontal electrodes PL2 and the second interlayer insulating layers 202. In other words, the first horizontal electrodes PL1 and the second horizontal electrodes PL2 may be spaced apart from each other in the first direction D1 with the insulating separation pattern 300 interposed therebetween. The first interlayer insulating layers 201 and the second interlayer insulating layers 202 may be spaced apart from each other in the first direction D1 with the insulating separation pattern 300 interposed therebetween.

Each of the first horizontal electrodes PL1 may include the first bottom electrode BE1 and the second bottom electrode BE2. The first bottom electrode BE1 may include the first protruding portion 251 and the second protruding portion 252, which extend toward the center CT of the top electrode TE, and the supporting portion 250, which is provided to connect the first protruding portion 251 and the second protruding portion 252 to each other. When viewed in a plan view, the first protruding portion 251 and the second protruding portion 252 may have an arc shape (e.g., an arch shape), which has a center axis passing through the center CT of the top electrode TE. The supporting portion 250 may also have an arc shape, which has a center axis passing through the center CT of the top electrode TE.

Each of the second horizontal electrodes PL2 may include the first bottom electrode BE1 and the second bottom electrode BE2. The first bottom electrode BE1 may include the first protruding portion 251 and the second protruding portion 252, which extend toward the center CT of the top electrode TE, and the supporting portion 250, which is provided to connect the first protruding portion 251 and the second protruding portion 252 to each other. When viewed in a plan view, the first protruding portion 251 and the second protruding portion 252 may have an arc shape, which has a center axis passing through the center CT of the top electrode TE. The supporting portion 250 may also have an arc shape (e.g., an arch shape), which has a center axis passing through the center CT of the top electrode TE. That is, the first horizontal electrodes PL1 and the second horizontal electrodes PL2 may be provided to have a mirror symmetry with respect to the insulating separation pattern 300 interposed therebetween.

The top electrode TE may include the horizontal protruding portions 270, which extend into regions between the first protruding portion 251 and the second protruding portion 252 of the first bottom electrode BE1 of the first horizontal electrode PL1. The top electrode TE may include the horizontal protruding portions 270, which extend into regions between the first protruding portion 251 and the second protruding portion 252 of the first bottom electrode BE1 of the second horizontal electrode PL2. The top electrode TE may further include the interlayer protruding portions 265. Each of the interlayer protruding portions 265 of the top electrode TE may extend into regions between the first horizontal electrodes PL1, which are adjacent to each other in the third direction D3, and between the second horizontal electrodes PL2, which are adjacent to each other in the third direction D3. In addition, the top electrode TE may include the vertical portion 260 connecting the horizontal protruding portions 270 to the interlayer protruding portions 265. The horizontal protruding portions 270 of the top electrode TE may have an arc shape, which has a center axis passing through the center CT of the top electrode TE. The interlayer protruding portions 265 of the top electrode TE may have a ring shape, which has a center axis passing through the center CT of the top electrode TE.

According to an embodiment of the disclosure, due to the insulating separation pattern 300, the horizontal electrodes PL may be divided into the first horizontal electrodes PL1 and the second horizontal electrodes PL2. In this case, it may be possible to separately or independently use the capacitors, which are formed by the first horizontal electrode PL1 and the second horizontal electrode PL2.

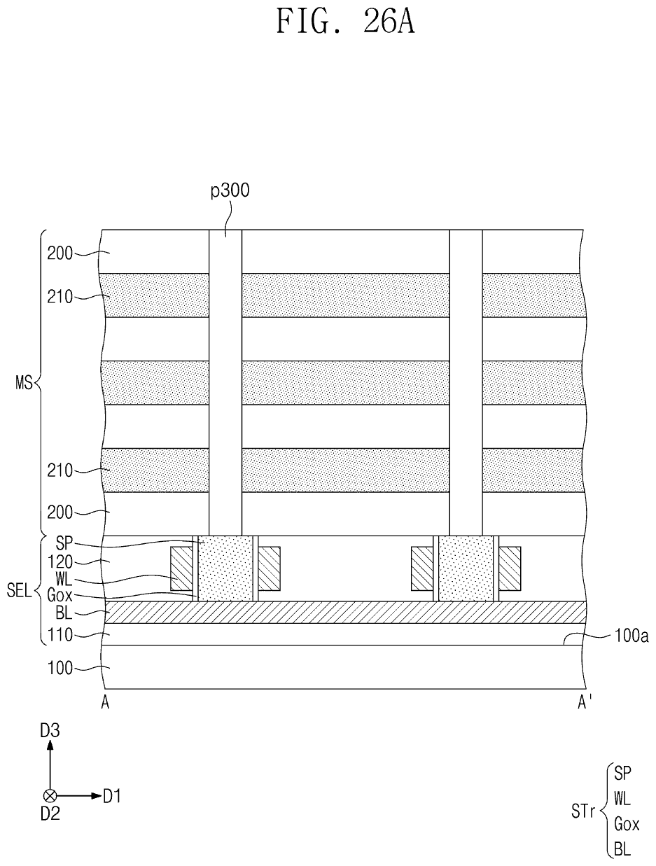

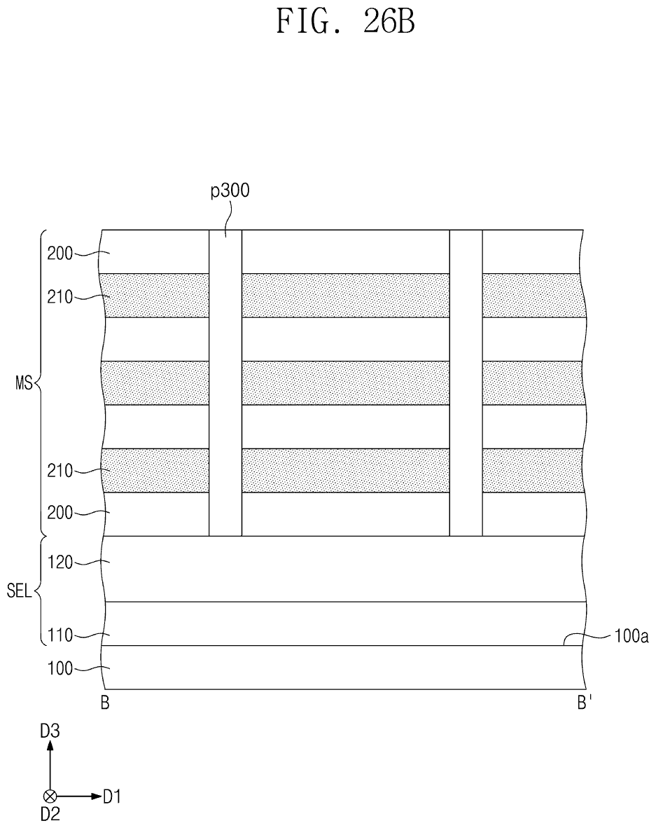

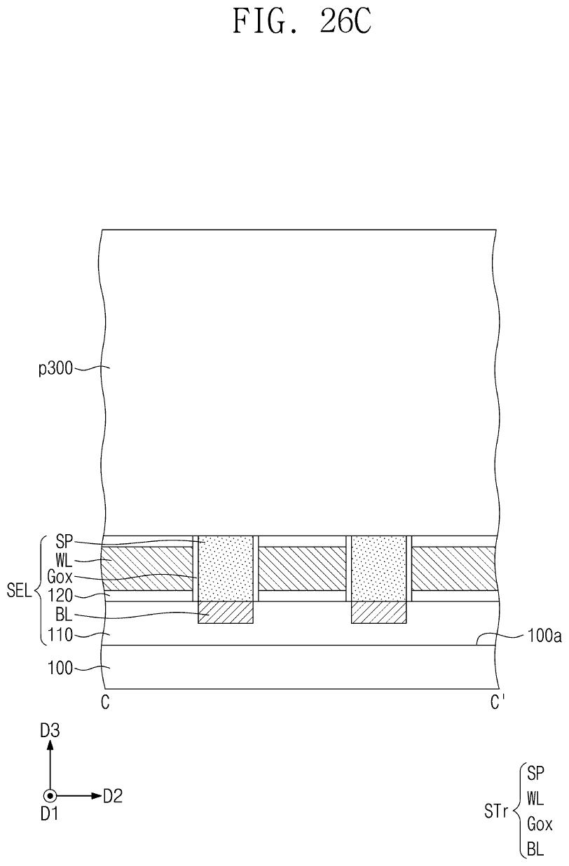

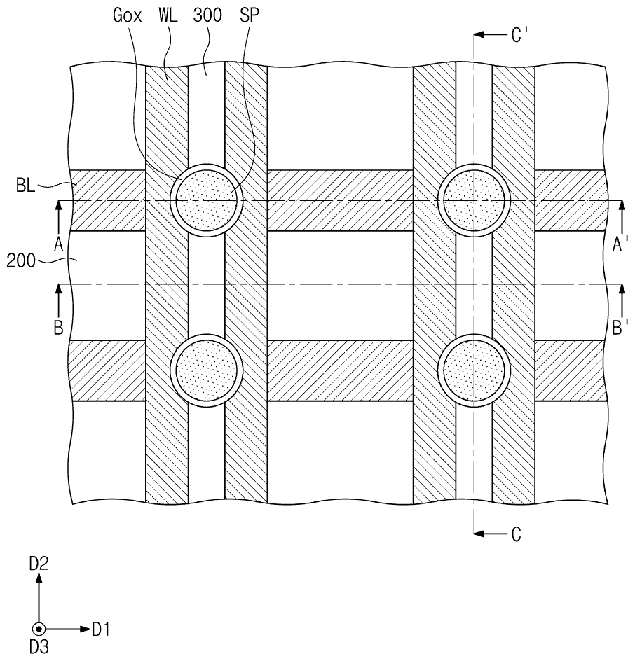

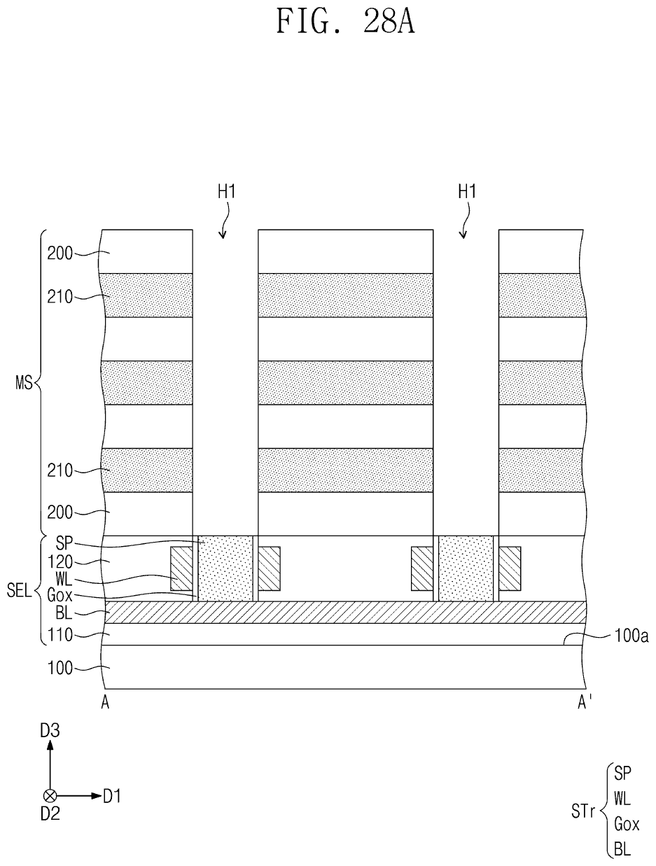

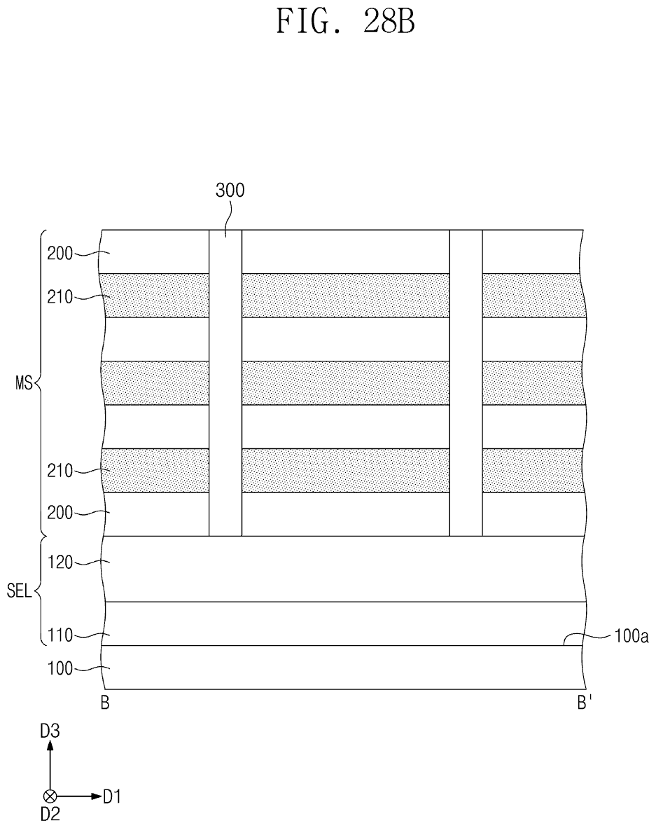

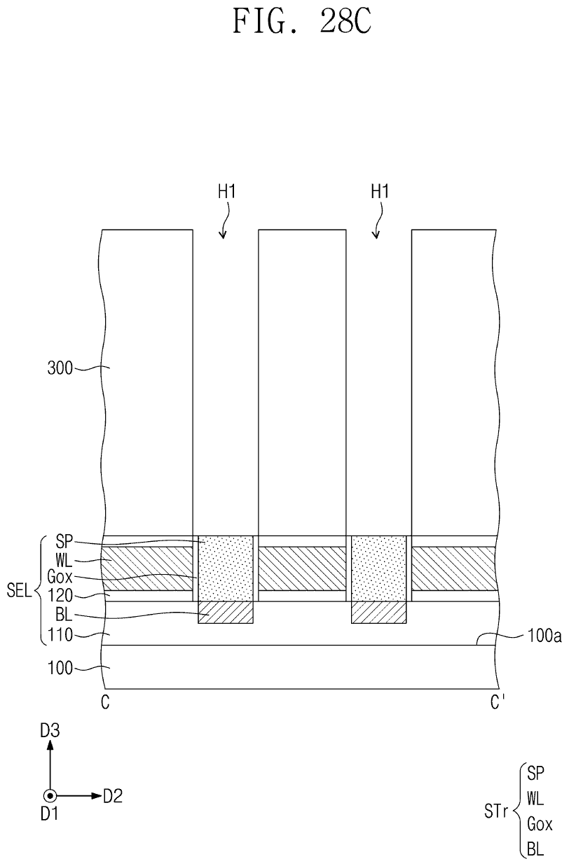

FIGS. 25 to 28C are diagrams illustrating a method of fabricating a semiconductor device, according to an embodiment of the disclosure. In detail, FIGS. 25 and 27 are sectional views illustrating a method of fabricating a semiconductor device, according to an embodiment of the disclosure. FIGS. 26A and 28A are sectional views, which are respectively taken along lines A-A′ of FIGS. 25 and 27 to illustrate a method of fabricating a semiconductor device, according to an embodiment of the disclosure. FIGS. 26B and 28B are sectional views, which are respectively taken along lines B-B′ of FIGS. 25 and 27 to illustrate a method of fabricating a semiconductor device, according to an embodiment of the disclosure. FIGS. 26C and 28C are sectional views, which are respectively taken along lines C-C′ of FIGS. 25 and 27 to illustrate a method of fabricating a semiconductor device, according to an embodiment of the disclosure. For concise description, a previously described element may be identified by the same reference number without repeating an overlapping description thereof.

Referring to FIGS. 25 and 26A to 26C, the mold structure MS may be formed on the selection element layer SEL. The mold structure MS may include the interlayer insulating layers 200 and the first sacrificial layers 210, which are alternately stacked in the third direction D3.

Next, a preliminary insulating separation pattern p300 may be formed to penetrate the mold structure MS. In an embodiment, a plurality of preliminary insulating separation patterns p300 may be formed. The preliminary insulating separation patterns p300 may be formed to cross the mold structure MS in the second direction D2 and may be spaced apart from each other in the first direction D1. In an embodiment, the formation of the preliminary insulating separation patterns p300 may include forming trenches to cross the mold structure MS in the second direction D2 and to be spaced apart from each other in the first direction D1 and depositing the preliminary insulating separation patterns p300 to fill the trenches.

Referring to FIGS. 27 and 28A to 28C, the first hole H1 may be formed to penetrate the mold structure MS and the preliminary insulating separation pattern p300. In an embodiment, a plurality of first holes H1 may be formed. The first holes H1 may be formed to be spaced apart from each other in the first direction D1 and the second direction D2. The first holes H1 may be formed to expose the top surfaces of the semiconductor patterns SP, respectively. That is, each of the first holes H1 may be vertically overlapped with a corresponding one of the semiconductor patterns SP. The preliminary insulating separation pattern p300 may be pierced by the first hole H1. Thus, the insulating separation pattern 300 may be formed.

Thereafter, the semiconductor device may be fabricated through substantially the same process as described with reference to FIGS. 7 to 22C.

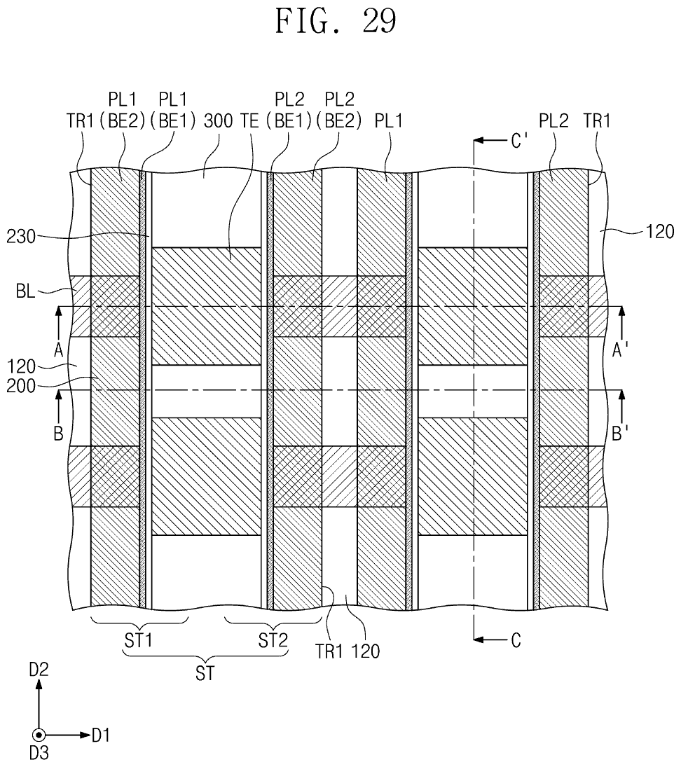

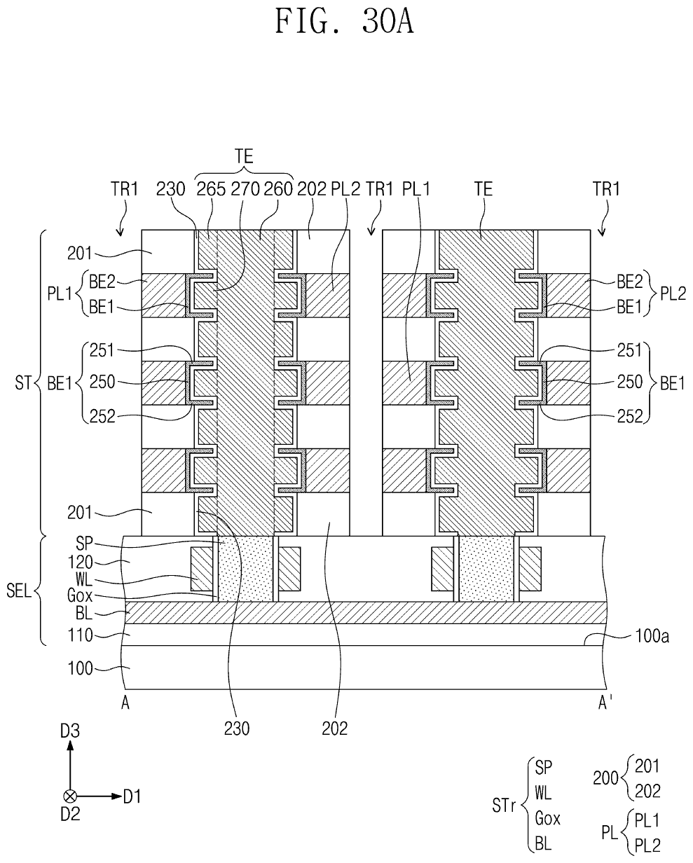

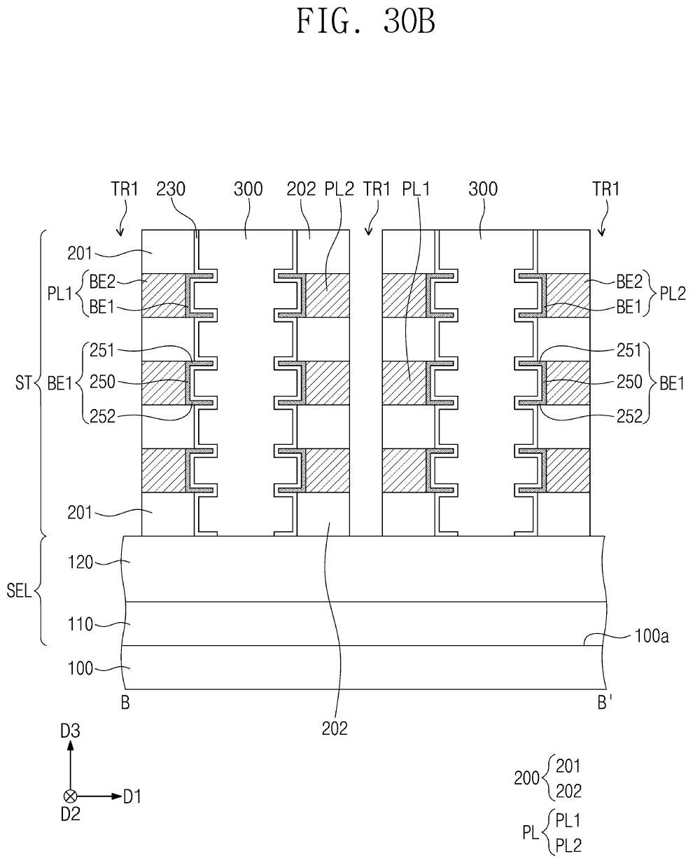

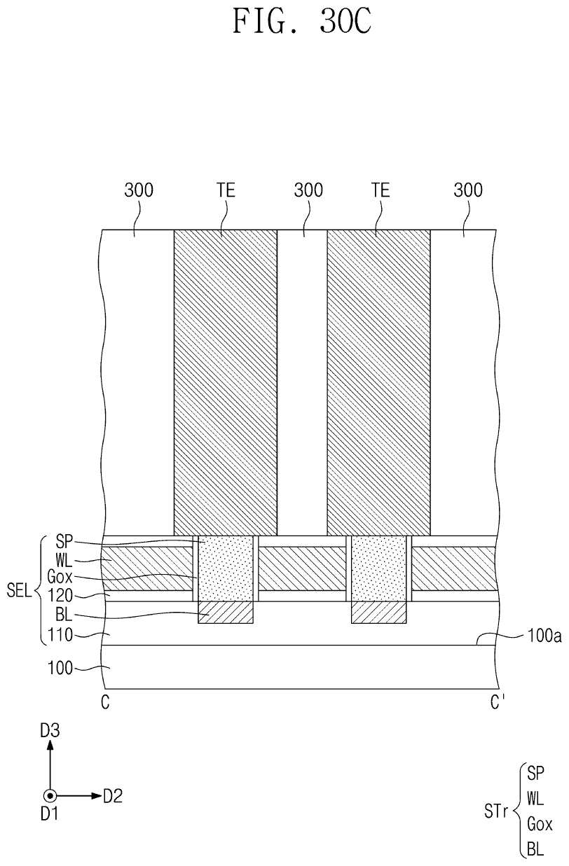

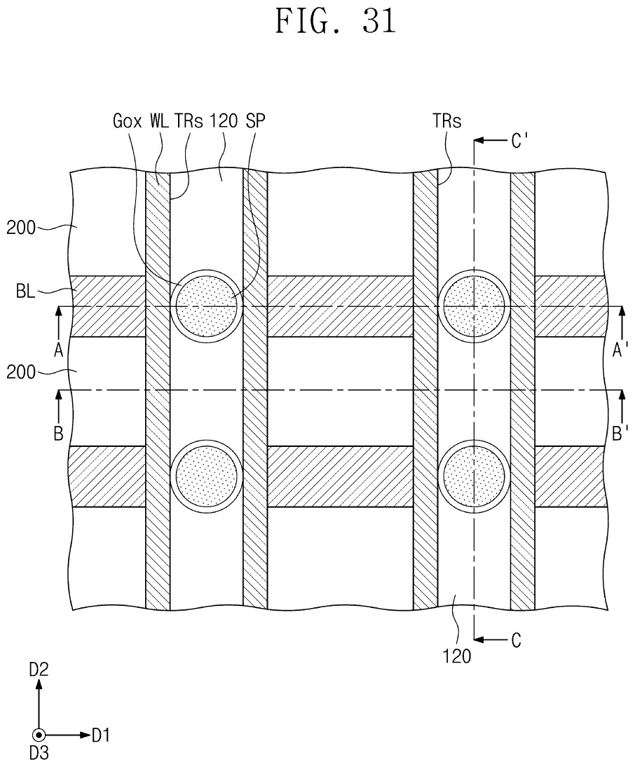

FIG. 29 is a plan view illustrating a semiconductor device according to an embodiment of the disclosure. FIGS. 30A to 30C are sectional views, which are respectively taken along lines A-A′, B-B′, and C-C′ of FIG. 29 to illustrate a semiconductor device according to an embodiment of the disclosure. For concise description, an element described with reference to FIGS. 1 and 2A to 2C may be identified by the same reference number without repeating an overlapping description thereof.

Referring to FIGS. 29 and 30A to 30C, the selection element layer SEL may be disposed on the substrate 100, and the stack ST may be disposed on the selection element layer SEL. The stack ST may include the interlayer insulating layers 200 and the horizontal electrodes PL, which are alternately stacked in the third direction D3.

The insulating separation pattern 300 may be disposed to penetrate the stack ST and to cross the stack ST in the second direction D2. The insulating separation pattern 300 may be provided to penetrate the stack ST in the third direction D3 and may extend in the second direction D2. The insulating separation pattern 300 may be formed of or include at least one from among silicon oxide, silicon nitride, and silicon oxynitride, and may be provided to have a single-or multi-layered structure.

The stack ST may be divided into the first stack ST1 and the second stack ST2 by the insulating separation pattern 300. The first stack ST1 and the second stack ST2 may be spaced apart from each other in the first direction D1 with the insulating separation pattern 300 interposed therebetween. Thus, the horizontal electrodes PL constituting the stack ST may be divided into the first horizontal electrodes PL1 and the second horizontal electrodes PL2. In addition, the interlayer insulating layers 200 may also be divided into the first interlayer insulating layers 201 and the second interlayer insulating layers 202. The first stack ST1 may include the first horizontal electrodes PL1 and the first interlayer insulating layers 201. The second stack ST2 may include the second horizontal electrodes PL2 and the second interlayer insulating layers 202. In other words, the first horizontal electrodes PL1 and the second horizontal electrodes PL2 may be spaced apart from each other in the first direction D1 with the insulating separation pattern 300 interposed therebetween. The first interlayer insulating layers 201 and the second interlayer insulating layers 202 may be spaced apart from each other in the first direction D1 with the insulating separation pattern 300 interposed therebetween.

Each of the first horizontal electrodes PL1 may have a shape extending in the second direction D2. Each of the first horizontal electrodes PL1 may include the first bottom electrode BE1 and the second bottom electrode BE2. The first bottom electrode BE1 may include the first protruding portion 251 and the second protruding portion 252, which extend in the first direction D1, and the supporting portion 250, which is provided to connect the first protruding portion 251 and the second protruding portion 252 to each other. When viewed in a plan view, the first protruding portion 251 and the second protruding portion 252 and the supporting portion 250 may have a line shape extending in the second direction D2.

Each of the second horizontal electrodes PL2 may have a shape extending in the second direction D2. Each of the second horizontal electrodes PL2 may include the first bottom electrode BE1 and the second bottom electrode BE2. The first bottom electrode BE1 may include the first protruding portion 251 and the second protruding portion 252, which extend in the first direction D1 and the opposite direction thereof, and the supporting portion 250, which is provided to connect the first protruding portion 251 and the second protruding portion 252 to each other. When viewed in a plan view, the first protruding portion 251, the second protruding portion 252, and the supporting portion 250 may have a line shape extending in the second direction D2.

In other words, the first horizontal electrodes PL1 and the second horizontal electrodes PL2 may include the first protruding portion 251 and the second protruding portion 252 protruding toward each other.

The top electrode TE may be provided to penetrate the insulating separation pattern 300, between the first stack ST1 and the second stack ST2. In an embodiment, the top electrodes TE may be spaced apart from each other in the second direction D2, and each of the top electrodes TE may be provided to penetrate the insulating separation pattern 300 in the third direction D3. The top electrode TE may include the horizontal protruding portions 270, which extend into regions between the first protruding portion 251 and the second protruding portion 252 of the first bottom electrode BE1 of the first horizontal electrode PL1 and between the first protruding portion 251 and the second protruding portion 252 of the first bottom electrode BE1 of the second horizontal electrode PL2. The top electrode TE may include the interlayer protruding portions 265, which extend into regions between the first horizontal electrodes PL1, which are adjacent to each other in the third direction D3, and between the second horizontal electrodes PL2, which are adjacent to each other in the third direction D3. In addition, The top electrode TE may include the vertical portion 260 connecting the horizontal protruding portions 270 to the interlayer protruding portions 265. The horizontal protruding portions 270 and the interlayer protruding portions 265 of the top electrode TE may have a line shape extending in the second direction D2.

The dielectric layer 230 may be interposed between the stack ST and the insulating separation pattern 300. The dielectric layer 230 may extend into a region between the top electrode TE and the stack ST. That is, the dielectric layer 230 may be interposed between the insulating separation pattern 300 and the stack ST, and between the top electrode TE and the stack ST.

According to an embodiment of the disclosure, due to the presence of the insulating separation pattern 300, the horizontal electrodes PL may be divided into the first horizontal electrodes PL1 and the second horizontal electrodes PL2. In this case, it may be possible to separately or independently use the capacitors, which are formed by the first horizontal electrode PL1 and the second horizontal electrode PL2.

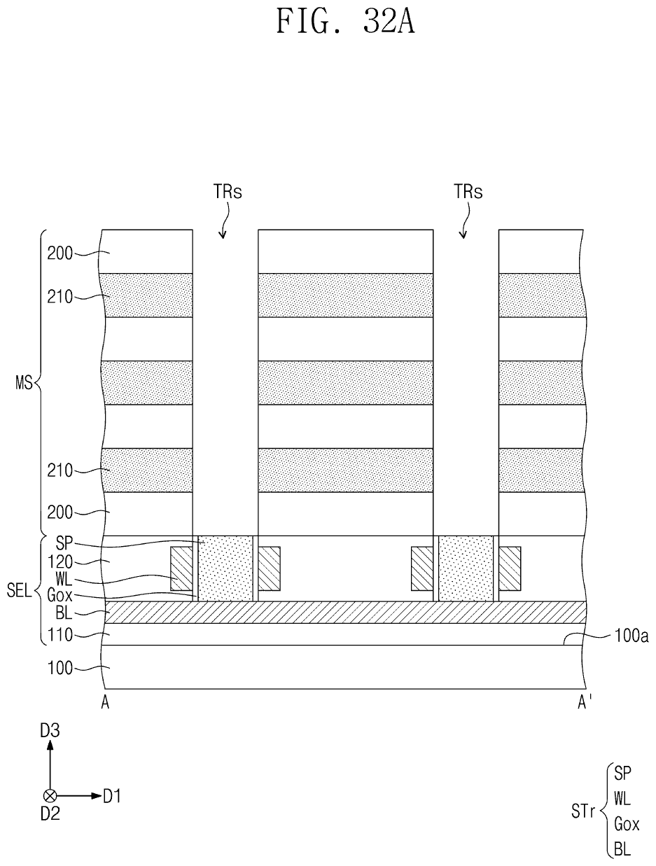

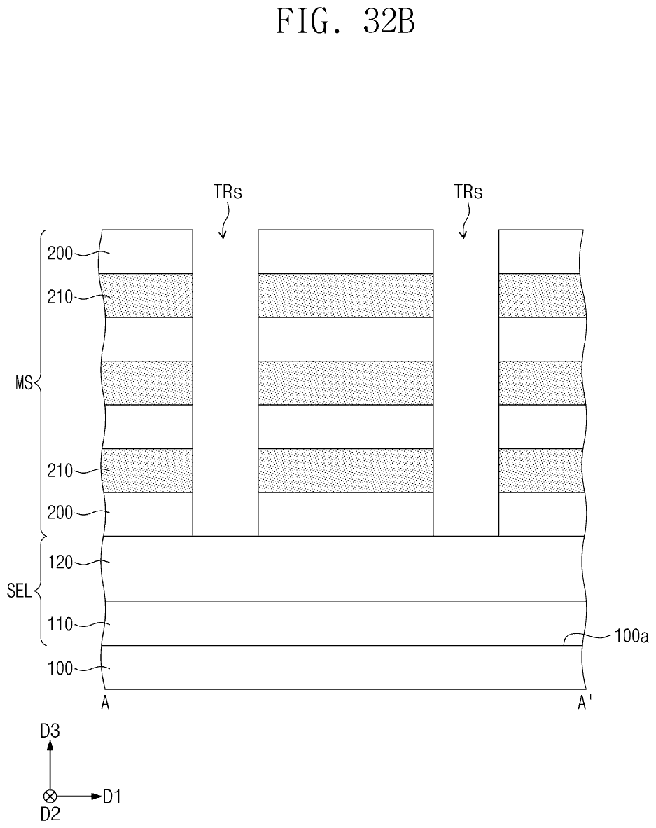

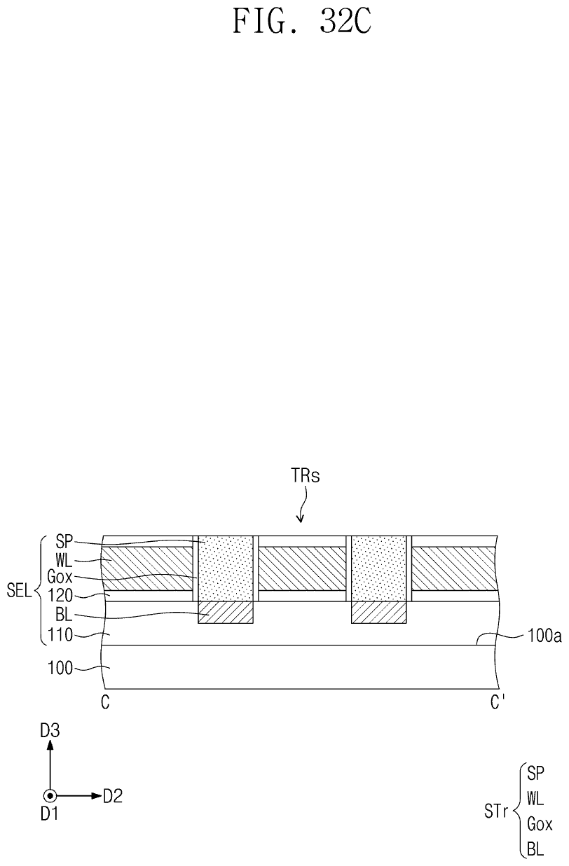

FIGS. 31 to 37C are diagrams illustrating a method of fabricating a semiconductor device, according to an embodiment of the disclosure. In detail, FIGS. 31, 34, and 36 are plan views illustrating a method of fabricating a semiconductor device, according to an embodiment of the disclosure. FIGS. 32A, 33A, 35A, and 37A are sectional views, which are respectively taken along lines A-A′ of the plan views to illustrate a method of fabricating a semiconductor device, according to an embodiment of the disclosure. FIGS. 32B, 33B, 35B, and 37B are sectional views, which are respectively taken along lines B-B′ of the plan views to illustrate a method of fabricating a semiconductor device, according to an embodiment of the disclosure. FIGS. 32C, 33C, 35C, and 37C are sectional views, which are respectively taken along lines C-C′ of the plan views to illustrate a method of fabricating a semiconductor device, according to an embodiment of the disclosure. For concise description, a previously described element may be identified by the same reference number without repeating an overlapping description thereof.

Referring to FIGS. 31 and 32A to 32C, the mold structure MS may be formed on the selection element layer SEL. The mold structure MS may include the interlayer insulating layers 200 and the first sacrificial layers 210, which are alternately stacked in the third direction D3.

Next, separation trenches TRs may be formed to cross the mold structure MS in the second direction D2 and may be spaced apart from each other in the first direction D1. The separation trenches TRs may be formed to expose the top surfaces of the semiconductor patterns SP, respectively. In an embodiment, the formation of the separation trenches TRs may include forming a mask pattern on the mold structure MS, etching the mold structure MS using the mask pattern as an etch mask, and removing the mask pattern.

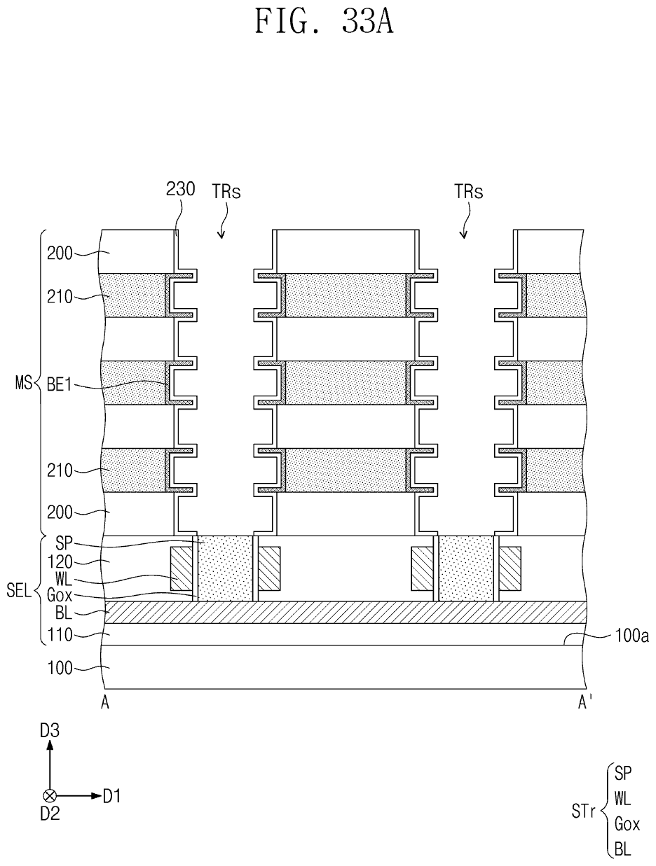

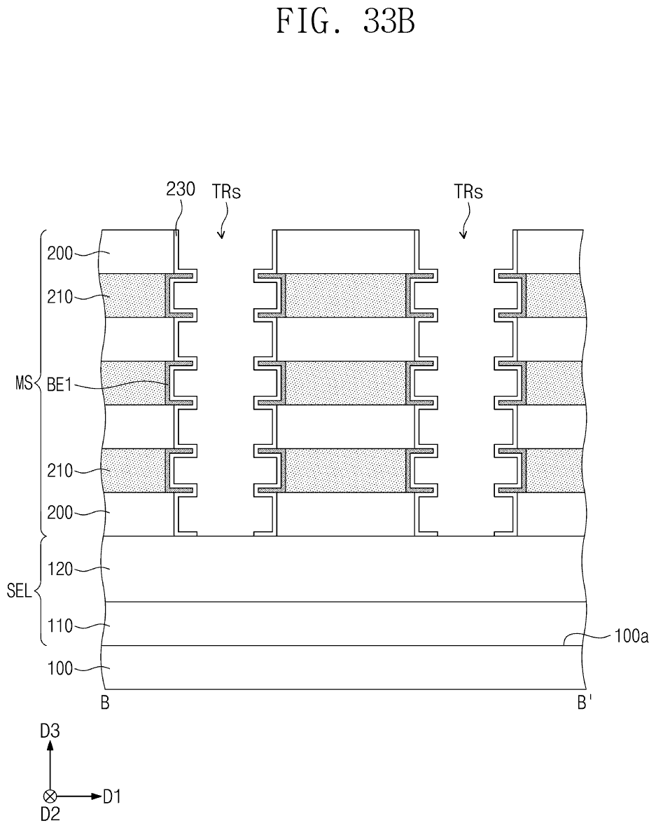

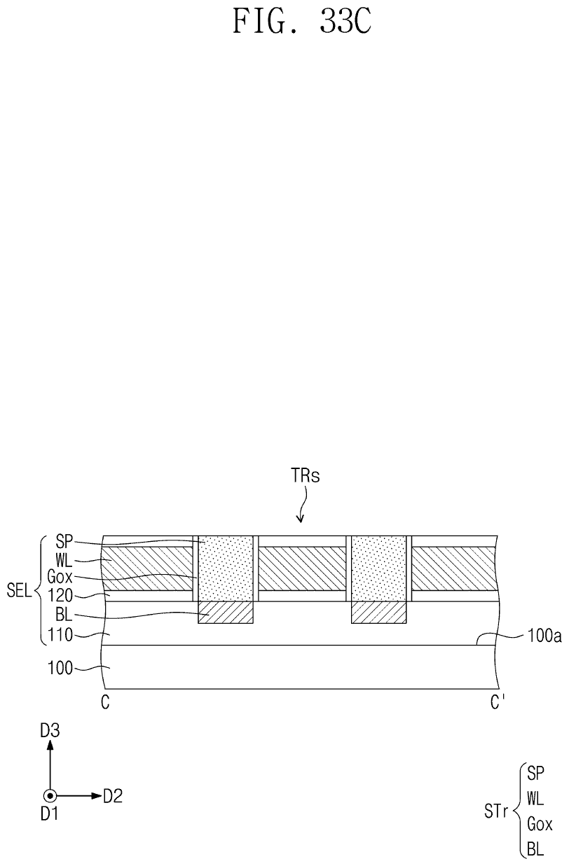

Referring to FIGS. 32 and 33A to 33C, the side surfaces of the first sacrificial layers 210 exposed by the separation trenches TRs may be partially etched. This may be performed by substantially the same method as described with reference to FIGS. 8A to 8C.

Next, the first bottom electrodes BE1 may be formed in empty regions, which are formed by partially etching the side surfaces of the first sacrificial layers 210. The formation of the first bottom electrodes BE1 may be performed using substantially the same method as described with reference to FIGS. 9A to 15C.

Next, the dielectric layer 230 may be formed. The formation of the dielectric layer 230 may be performed using substantially the same method as described with reference to FIGS. 16A to 17C.

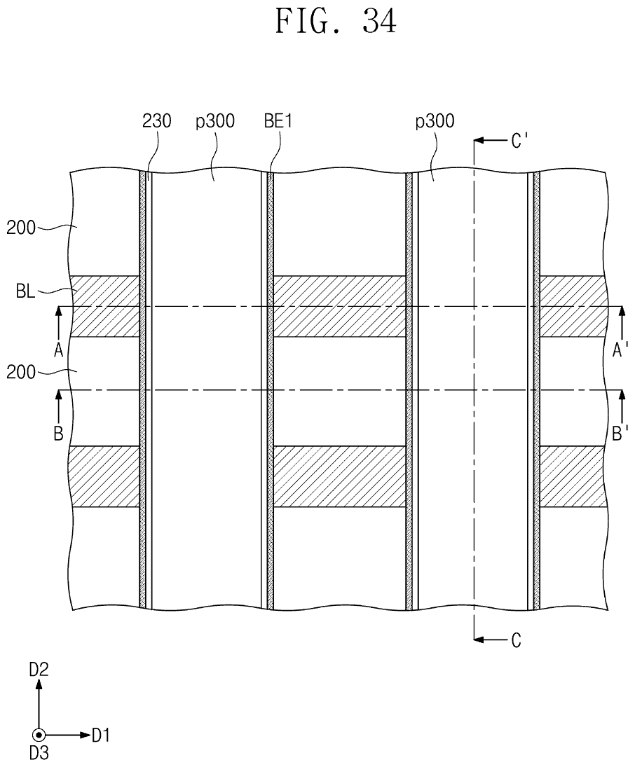

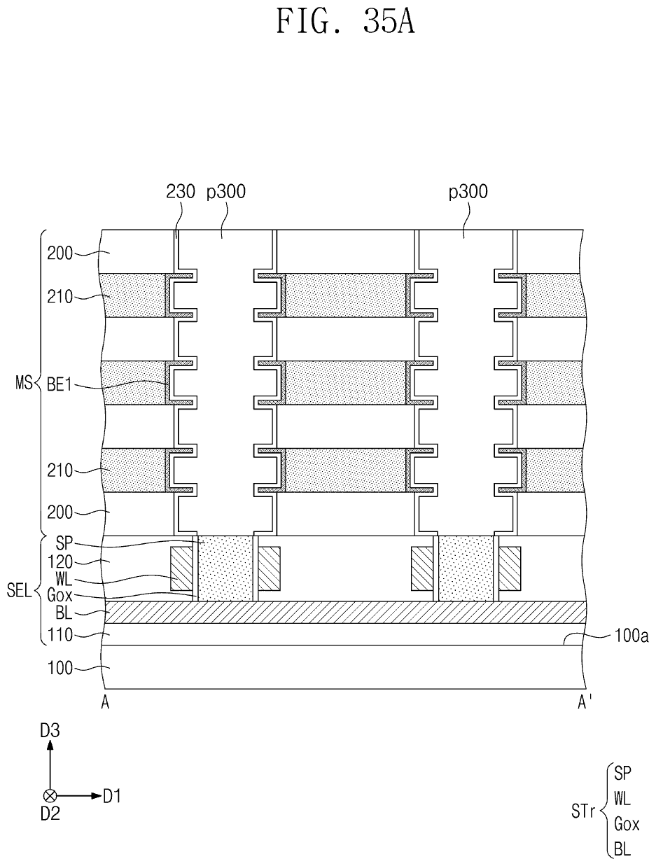

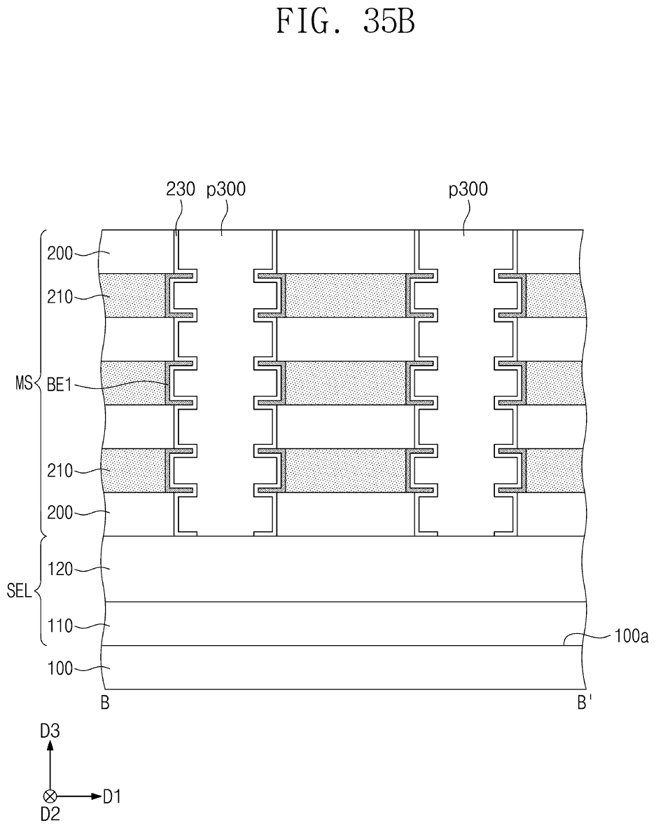

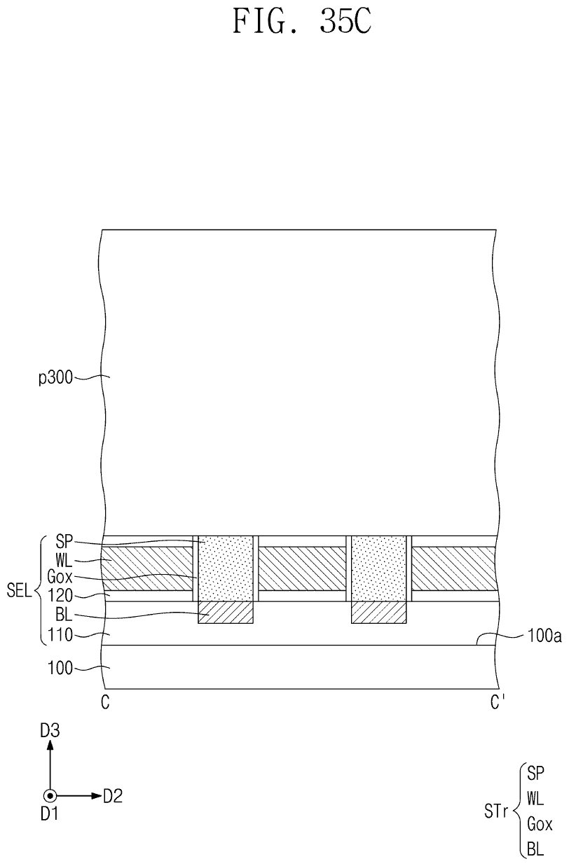

Referring to FIGS. 34 and 35A to 35C, the preliminary insulating separation patterns p300 may be formed to fill remaining portions of the separation trenches TRs. In an embodiment, the formation of the preliminary insulating separation patterns p300 may be formed using a deposition method (e.g., a physical vapor deposition (PVD) method or a chemical vapor deposition (CVD) method). The preliminary insulating separation patterns p300 may be formed of or include at least one from among silicon oxide, silicon nitride, and silicon oxynitride.

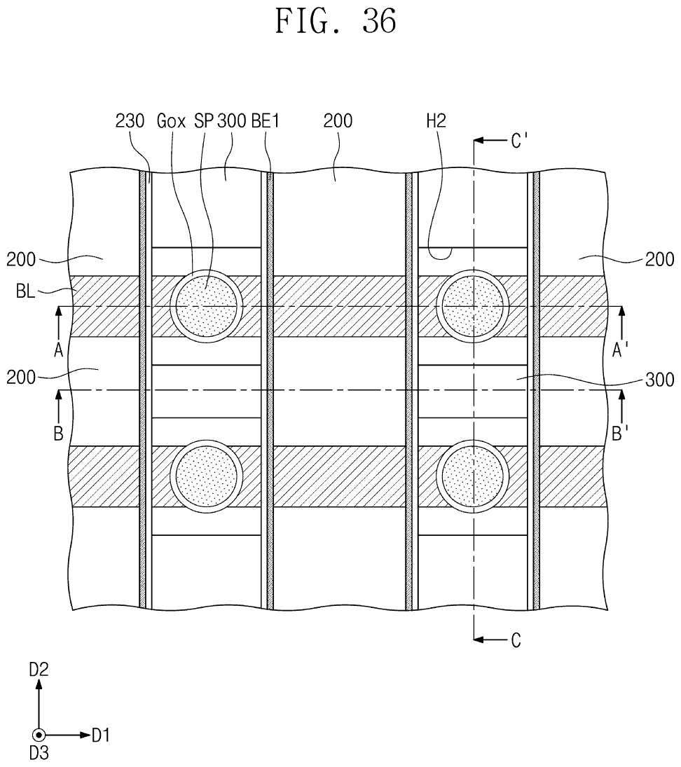

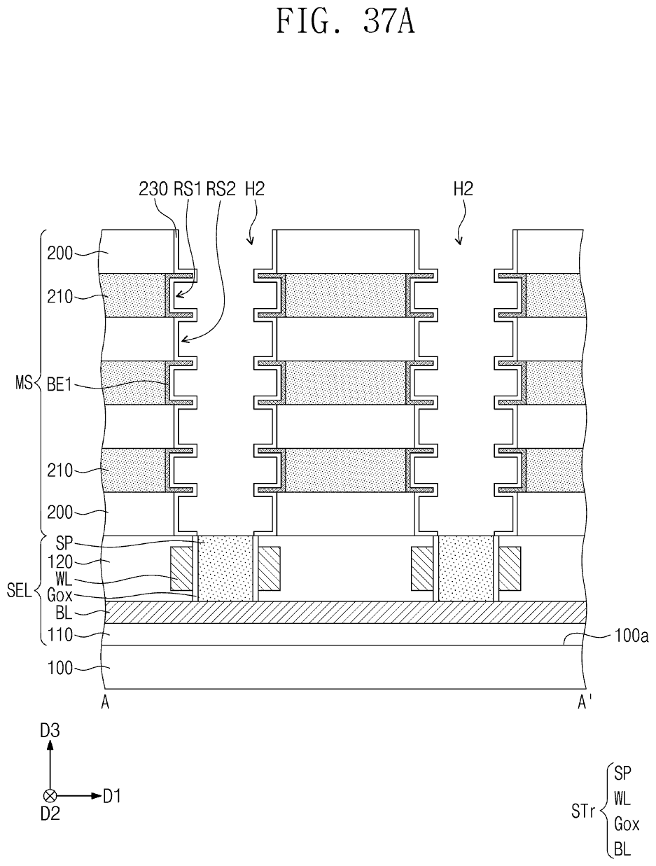

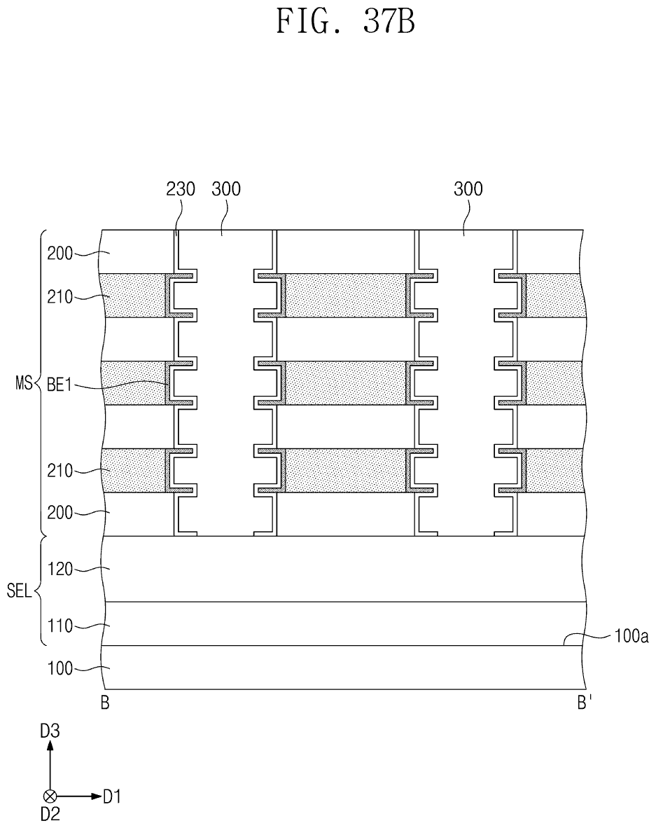

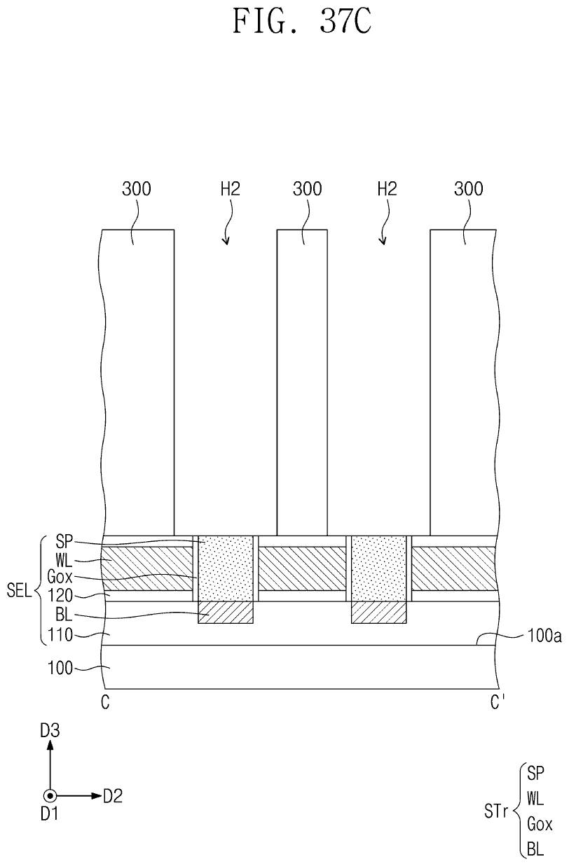

Referring to FIGS. 36 and 37A to 37C, second holes H2 may be formed to penetrate the preliminary insulating separation patterns p300. Thus, the insulating separation patterns 300 may be formed. Each of the second holes H2 may expose the top surface of a corresponding one of the semiconductor patterns SP. The second holes H2 may be spaced apart from each other in the first direction D1 and the second direction D2.

The side surfaces of the insulating separation patterns 300 exposed through the second holes H2 may be partially etched. Thus, the first recess portions RS1 may be formed between protruding portions of the first bottom electrodes BE1. In addition, the second recess portions RS2 may be formed between the first bottom electrodes BE1, which are adjacent to each other in the third direction D3. The first recess portion RS1 and the second recess portions RS2 may have a line shape extending in the second direction D2.

Referring back to FIGS. 29 and 30A to 30C, the top electrode TE, the first trenches TR1, and the horizontal electrodes PL may be formed. In an embodiment, the top electrode TE, the first trenches TR1, and the horizontal electrodes PL may be formed through substantially the same method as described with reference to FIGS. 18 to 22C and FIGS. 1 to 2C.

In a semiconductor device according to an embodiment of the disclosure, not only one horizontal capacitor but also a plurality of vertical capacitors may be provided for each horizontal electrode. In this case, it may be possible to maximize the capacity of the capacitor of the semiconductor device.

In addition, since a dielectric layer includes a ferroelectric layer and a semiconductor layer or electrodes constituting the capacitor may have different work functions, the hysteresis property may be asymmetrically designed, and this may allow for the proper adjustment of the threshold voltage of the semiconductor device.

As a result, it may be possible to easily increase an integration density of the semiconductor device and to improve the electrical and reliability characteristics of the semiconductor device.

While non-limiting example embodiments of the disclosure have been particularly shown and described, it will be understood by one of ordinary skill in the art that variations in form and detail may be made therein without departing from the spirit and scope of the disclosure.

What is claimed is:

1. A semiconductor device, comprising:
a substrate;
a selection element layer on the substrate in a vertical direction perpendicular to a top surface of the substrate;
a stack comprising interlayer insulating layers and horizontal electrodes, wherein the interlayer insulating layers and the horizontal electrodes are alternately stacked on the selection element layer in the vertical direction;
a top electrode penetrating the stack; and
a dielectric layer between the stack and the top electrode,
wherein each of the horizontal electrodes comprises a first bottom electrode and a second bottom electrode,
wherein the first bottom electrode comprises:
a first protruding portion;
a second protruding portion; and
a supporting portion that connects the first protruding portion and the second protruding portion,
wherein the first protruding portion and the second protruding portion extend toward a center of the top electrode, and the first protruding portion and the second protruding are spaced apart from each other in the vertical direction,
wherein the top electrode comprises:
a horizontal protruding portion extending between the first protruding portion and the second protruding portion of the first bottom electrode of one of the horizontal electrodes;
an interlayer protruding portion extending between the first bottom electrode of the one of the horizontal electrodes and the first bottom electrode of another one of the horizontal electrodes, wherein the first bottom electrode of the one of the horizontal electrodes and the first bottom electrode of the another one of the horizontal electrodes are adjacent to each other in the vertical direction; and
a vertical portion connecting the horizontal protruding portion to the interlayer protruding portion.

2. The semiconductor device of claim 1, wherein at least a portion of the first protruding portion and at least a portion of the second protruding portion of the first bottom electrode of the one of the horizontal electrodes are vertically overlapped with the interlayer protruding portion of the top electrode.

3. The semiconductor device of claim 1, wherein at least a portion of the first protruding portion and at least a portion of the second protruding portion of the first bottom electrode of the one of the horizontal electrodes are vertically overlapped with the horizontal protruding portion of the top electrode.

4. The semiconductor device of claim 1, wherein the dielectric layer comprises at least one from among a ferroelectric material and an anti-ferroelectric material.

5. The semiconductor device of claim 1, wherein the first bottom electrode of the one of the horizontal electrodes further comprises a third protruding portion that is between the first protruding portion and the second protruding portion of the first bottom electrode of the one of the horizontal electrodes, and
wherein the third protruding portion extends from the supporting portion toward the center of the top electrode, and is spaced apart from the first protruding portion and the second protruding portion of the first bottom electrode of the one of the horizontal electrodes in the vertical direction.

6. The semiconductor device of claim 5, wherein the horizontal protruding portion of the top electrode comprises a first horizontal protruding portion and a second horizontal protruding portion,
wherein the first horizontal protruding portion is between the first protruding portion and the third protruding portion of the first bottom electrode of the one of the horizontal electrodes, and
wherein the second horizontal protruding portion is between the second protruding portion and the third protruding portion of the first bottom electrode of the one of the horizontal electrodes.

7. The semiconductor device of claim 6, wherein the horizontal protruding portion of the top electrode is vertically overlapped with at least a portion of each of the first protruding portion, the second protruding portion, and the third protruding portion of the first bottom electrode of the one of the horizontal electrodes.

8. The semiconductor device of claim 1, wherein the dielectric layer comprises a laminated structure that comprises:
stacked ferroelectric layers of two or more types; or
a ferroelectric layer and an insulating layer that are stacked.

9. The semiconductor device of claim 1, further comprising an insulating separation pattern penetrating the stack in the vertical direction,
wherein each of the horizontal electrodes comprises a first horizontal electrode and a second horizontal electrode,
wherein the first horizontal electrode and the second horizontal electrode are spaced apart from each other in a first direction, with the insulating separation pattern being between the first horizontal electrode and the second horizontal electrode in the first direction, and
wherein the first direction is parallel to the top surface of the substrate.

10. The semiconductor device of claim 1, wherein the dielectric layer comprises a ferroelectric material, and
wherein the semiconductor device further comprises a semiconductor material between the dielectric layer and the top electrode.

11. A semiconductor device, comprising:
a substrate;
a selection element layer on the substrate in a vertical direction perpendicular to a top surface of the substrate;
a stack comprising interlayer insulating layers and horizontal electrodes, wherein the interlayer insulating layers and the horizontal electrodes are alternately stacked on the selection element layer in the vertical direction;
an insulating separation pattern penetrating the stack in the vertical direction;
a top electrode penetrating the insulating separation pattern in the vertical direction; and
a dielectric layer between the stack and the insulating separation pattern and between the stack and the top electrode,
wherein each of the horizontal electrodes comprises a first horizontal electrode and a second horizontal electrode,
wherein the first horizontal electrode and the second horizontal electrode are spaced apart from each other in a first direction parallel to the top surface of the substrate, with the insulating separation pattern and the top electrode being between the first horizontal electrode and the second horizontal electrode in the first direction,
wherein the insulating separation pattern crosses the stack in a second direction parallel to the top surface of the substrate, the second direction crossing the first direction;
wherein each of the first horizontal electrode and the second horizontal electrode comprises:
a first bottom electrode comprising:
a first protruding portion;
a second protruding portion, wherein the first protruding portion and the second protruding portion extend in the first direction and are spaced apart from each other in the vertical direction, and
a supporting portion that connects the first protruding portion and the second protruding portion; and
a second bottom electrode spaced apart from the top electrode, wherein the first bottom electrode is between the second bottom electrode and the top electrode, and
wherein the top electrode comprises:
a horizontal protruding portion extending between the first protruding portion and the second protruding portion of the first bottom electrode of the first horizontal electrode of one of the horizontal electrodes;
an interlayer protruding portion extending between the first bottom electrode of the first horizontal electrode of the one of the horizontal electrodes and the first bottom electrode of the first horizontal electrode of another one of the horizontal electrodes, wherein the first bottom electrode of the first horizontal electrode of the one of the horizontal electrodes and the first bottom electrode of the first horizontal electrode of the another one of the horizontal electrodes are adjacent to each other in the vertical direction; and
a vertical portion connecting the horizontal protruding portion to the interlayer protruding portion.

12. The semiconductor device of claim 11, wherein at least a portion of the first protruding portion and at least a portion of the second protruding portion of the first bottom electrode of the first horizontal electrode of the one of the horizontal electrodes are vertically overlapped with the interlayer protruding portion of the top electrode.

13. The semiconductor device of claim 12, wherein at least a portion of the first protruding portion and at least a portion of the second protruding portion of the first bottom electrode of the first horizontal electrode of the one of the horizontal electrodes are vertically overlapped with the horizontal protruding portion of the top electrode.

14. The semiconductor device of claim 11, wherein the first bottom electrode of the first horizontal electrode of the one of the horizontal electrodes further comprises a third protruding portion that is between the first protruding portion and the second protruding portion of the first bottom electrode of the first horizontal electrode of the one of the horizontal electrodes,
wherein the third protruding portion extends from the supporting portion in the first direction, and is spaced apart from the first protruding portion and the second protruding portion in the vertical direction.

15. The semiconductor device of claim 14, wherein the horizontal protruding portion of the top electrode comprises a first horizontal protruding portion and a second horizontal protruding portion,
wherein the first horizontal protruding portion is between the first protruding portion and the third protruding portion of the first bottom electrode of the first horizontal electrode of the one of the horizontal electrodes, and
wherein the second horizontal protruding portion is between the second protruding portion and the third protruding portion of the first bottom electrode of the first horizontal electrode of the one of the horizontal electrodes.

16. The semiconductor device of claim 15, wherein the horizontal protruding portion of the top electrode is vertically overlapped with at least a portion of the first protruding portion, the second protruding portion, and the third protruding portion of the first bottom electrode of the first horizontal electrode of the one of the horizontal electrodes.

17. The semiconductor device of claim 11, wherein the dielectric layer comprises at least one from among a ferroelectric material and an anti-ferroelectric material.

18. A semiconductor device, comprising:
a substrate;
a selection element layer on the substrate in a vertical direction perpendicular to a top surface of the substrate;
a stack comprising interlayer insulating layers and horizontal electrodes, wherein the interlayer insulating layers and the horizontal electrodes are alternately stacked on the selection element layer in the vertical direction;
a top electrode penetrating the stack; and
a dielectric layer between the stack and the top electrode,
wherein the selection element layer comprises:
a bit line extending in a first direction parallel to the top surface of the substrate;
a semiconductor pattern on the bit line;
a word line on a side surface of the semiconductor pattern, the word line extending in a second direction that is parallel to the top surface of the substrate and that crosses the first direction; and
a gate insulating pattern between the word line and the semiconductor pattern,
wherein each of the horizontal electrodes comprises a first bottom electrode and a second bottom electrode,
wherein the first bottom electrode comprises:
a first protruding portion;
a second protruding portion; and
a supporting portion that connects the first protruding portion and the second protruding portion to each other,
wherein the first protruding portion and the second protruding portion extend toward a center of the top electrode, and the first protruding portion and the second protruding portion are spaced apart from each other in the vertical direction,
wherein the top electrode comprises:
a horizontal protruding portion that extends between the first protruding portion and the second protruding portion of the first bottom electrode of one of the horizontal electrodes;
an interlayer protruding portion extending between the first bottom electrode of the one of the horizontal electrodes and the first bottom electrode of another one of the horizontal electrodes, wherein the first bottom electrode of the one of the horizontal electrodes and the first bottom electrode of the another one of the horizontal electrodes are adjacent to each other in the vertical direction; and
a vertical portion connecting the horizontal protruding portion to the interlayer protruding portion.

19. The semiconductor device of claim 18, wherein at least a portion of the first protruding portion and at least a portion of the second protruding portion of the first bottom electrode of the one of the horizontal electrodes are vertically overlapped with the interlayer protruding portion of the top electrode.

20. The semiconductor device of claim 18, further comprising an insulating separation pattern that penetrates the stack in the vertical direction and crosses the stack in the second direction,
wherein each of the horizontal electrodes comprises a first horizontal electrode and a second horizontal electrode,
wherein the first horizontal electrode and the second horizontal electrode are spaced apart from each other in the first direction, and the insulating separation pattern is between the first horizontal electrode and the second horizontal electrode in the first direction.
